(19) United States
(12) Patent Application Publication
(10) Pub. No.: US 2025/0366251 A1
(43) Pub. Date: Nov. 27, 2025

(54) PHOTODETECTION ELEMENT AND METHOD OF MANUFACTURING PHOTODETECTION ELEMENT

(71) Applicant: SONY SEMICONDUCTOR SOLUTIONS CORPORATION, KANAGAWA (JP)

(72) Inventors: Junichiro FUJIMAGARI, KANAGAWA (JP); Masaya NAGATA, KANAGAWA (JP); Tatsumasa HIRATSUKA, KANAGAWA (JP); Naoki KOMAI, KANAGAWA (JP)

(21) Appl. No.: 18/874,330

(22) PCT Filed: Jun. 19, 2023
(86) PCT No.: PCT/JP2023/022581

§ 371 Date: Dec. 12, 2024

(30) Foreign Application Priority Data
Jun. 20, 2022 (JP) 2022-098979

(51) Int. Cl. H10F 39/00; H10F 39/12

(52) U.S. Cl. CPC H10F 39/811; H10F 39/018; H10F 39/199; H10F 39/809; H10F 39/8053; H10F 39/8063

(57) ABSTRACT

The restriction of the arrangement position of a through electrode connected to an external terminal of a packaged photodetection element is alleviated.

A photodetection element includes: a first chip on which a first wiring layer is formed; a second chip that is laminated on the first chip and on which a second wiring layer is formed; a third chip that is arranged side by side with the second chip at an interval and laminated on the first chip, a third wiring layer being formed on the third chip; an embedding layer that is laminated on the first chip so that the second chip and the third chip are embedded in the embedding layer; and a through electrode that is located between the second chip and the third chip, penetrates the embedding layer, and is connected to the first wiring layer. The first wiring layer may be directly bonded to the second wiring layer and the third wiring layer.

### TECHNICAL FIELD

The present technology relates to a photodetection element and a method of manufacturing a photodetection element. Specifically, the present technology relates to a wiring structure of a photodetection element.

### BACKGROUND ART

In packaging of a semiconductor chip, a three-dimensional integrated structure in which singulated semiconductor chips are laminated may be used in order to curb an increase in the mounting area. As such a three-dimensional integrated structure, for example, there is a structure in which singulated memory circuits and logic circuits are laid out in the horizontal direction, embedded with an oxide film and planarized, and then laminated so as to be included in a planar direction under a solid-state imaging device (see Patent Documents 1 and 3). In addition, there is a structure in which a first connection via connects first and second substrate structures, penetrates a first substrate and a first interlayer insulating layer, extends to a second interlayer insulating layer of the second substrate structure, and is connected to a second wiring layer of the second interlayer insulating layer and a first wiring layer of the first interlayer insulating layer (see, for example, Patent Document 2).

### CITATION LIST

### Patent Document

Patent Document 1: WO 2019/087764 A
Patent Document 2: Japanese Patent Application Laid-Open No. 2019-68049
Patent Document 3: WO 2020/129686 A

### SUMMARY OF THE INVENTION

### Problems to be Solved by the Invention

However, in the above-described conventional technology, since the restriction of the arrangement position of a through electrode connected to an external terminal of the package is large, there is a possibility that the path length from the laminated chip to the external terminal increases or the limitation of the number of external terminals to be arranged increases.

The present technology has been made in view of such a situation, and an object of the present technology is to alleviate the restriction of the arrangement position of a through electrode connected to an external terminal of a packaged photodetection element.

### Solutions to Problems

The present technology has been made to solve the above-described problems, and a first aspect of the present technology provides a photodetection element including: a first chip on which a first wiring layer is formed; a second chip that is laminated on the first chip and on which a second wiring layer is formed; a third chip that is arranged side by side with the second chip at an interval and laminated on the first chip, a third wiring layer being formed on the third chip; an embedding layer that is laminated on the first chip so that the second chip and the third chip are embedded in the embedding layer; and a through electrode that is located between the second chip and the third chip, penetrates the embedding layer, and is connected to the first wiring layer. This brings about an effect that the restriction on the arrangement position of the through electrode connected to the external terminal of the packaged photodetection element is alleviated.

In addition, according to the first aspect, the first wiring layer may be directly bonded to the second wiring layer and the third wiring layer. This brings about an effect of achieving miniaturization of a connection portion between wiring layers formed on different chips.

Furthermore, according to the first aspect, a support substrate provided on the embedding layer may be further included, and the through electrode may penetrate the support substrate and the embedding layer and be connected to the first wiring layer. This brings about an effect that the strength of the packaged photodetection element is secured while coping with thinning of the chip.

Furthermore, according to the first aspect, a sensor chip on which the first chip is laminated, and having a fourth wiring layer formed on a front surface side and a pixel formed on a back surface side may be further included. This brings about an effect that a data processing function, a memory function, or the like is added to the imaging function while curbing an increase in the mounting area of the packaged photodetection element.

In addition, according to the first aspect, the first wiring layer may include a front surface wiring layer formed on a front surface side of the first chip, and a back surface wiring layer formed on a back surface side of the first chip; the front surface wiring layer may be directly bonded to the fourth wiring layer; the back surface wiring layer may be directly bonded to the second wiring layer and the third wiring layer; and the through electrode may penetrate the embedding layer and be connected to the back surface wiring layer. This brings about an effect that the restriction on the arrangement position of the through electrode connected to the external terminal of the packaged photodetection element is alleviated.

Furthermore, according to the first aspect, a transparent substrate provided on the sensor chip may be further included. This brings about an effect that the strength of the packaged photodetection element is secured while coping with thinning of the sensor chip.

Furthermore, according to the first aspect, a cavity that separates an imaging region of the sensor chip from the transparent substrate may be further included. This brings about an effect that the strength of the packaged photodetection element is secured without affecting the optical function of the sensor chip.

In addition, a second aspect provides a photodetection element including: a first chip on which a first wiring layer is formed; a second chip that is laminated on the first chip and on which a second wiring layer is formed; an embedding layer that is laminated on the first chip so that the second chip is embedded in the embedding layer; a redistribution layer that is formed on the embedding layer; and a through electrode that penetrates the embedding layer and connects the redistribution layer and the first wiring layer. This brings about an effect that the restriction on the arrangement position of the through electrode connected to the external terminal of the packaged photodetection element is alleviated.

In addition, a third aspect provides a photodetection element including: a first chip on which a first wiring layer is formed; a second chip that is mounted face down on the first wiring layer and on which a second wiring layer is formed; an embedding layer that is laminated on the first chip so that the second chip is embedded in the embedding layer; and a first through electrode that penetrates the embedding layer and is connected to the second wiring layer via the first wiring layer. This brings about an effect that the first through electrode connected to the second wiring layer on the semiconductor layer of the second chip is extended to the outside without penetrating the semiconductor layer of the second chip.

In addition, according to the third aspect, a second through electrode that penetrates the embedding layer and is connected to the first wiring layer without interposing the second wiring layer may be further included. This brings about an effect that the second through electrode connected to the first wiring layer of the first chip is extended to the outside without penetrating the semiconductor layer of the second chip.

In addition, according to the third aspect, the first wiring layer may be directly bonded to the second wiring layer. This brings about an effect of achieving miniaturization of a connection portion between wiring layers formed on different chips.

In addition, according to the third aspect, a sensor chip on which the first chip is laminated, and having a third wiring layer formed on a front surface side and a pixel formed on a back surface side may be further included. This brings about an effect that a data processing function, a memory function, or the like is added to the imaging function while curbing an increase in the mounting area of the packaged photodetection element.

In addition, according to the third aspect, the first wiring layer may include a front surface wiring layer formed on a front surface side of the first chip, and a back surface wiring layer formed on a back surface side of the first chip; the front surface wiring layer may be directly bonded to the third wiring layer; the back surface wiring layer may be directly bonded to the second wiring layer; and the first through electrode may penetrate the embedding layer and be connected to the second wiring layer via the back surface wiring layer. This brings about an effect that the restriction on the arrangement position of the through electrode connected to the external terminal of the packaged photodetection element is alleviated.

In addition, according to the third aspect, a fourth chip that is laminated between the sensor chip and the first chip and on which a fourth wiring layer is formed may be further included. This brings about an effect that the data processing function, the memory function, or the like associated with the imaging function is expanded while curbing an increase in the mounting area of the packaged photodetection element.

In addition, a fourth aspect provides a photodetection element including: a first chip on which a first wiring layer is formed; a second chip that forms a laminated structure with the first chip and on which a second wiring layer is formed; a third chip that forms a laminated structure with the first chip and the second chip and on which a third wiring layer is formed; an embedding layer that forms a laminated structure with the first chip and the second chip so that the third chip is embedded in the embedding layer; and a first through electrode that penetrates the embedding layer and is connected to the second wiring layer. This brings about an effect that the restriction on the arrangement position of the through electrode connected to the external terminal of the packaged photodetection element is alleviated while supporting the laminated structure of three or more layers of chips.

Further, according to the fourth aspect, the first chip may be located in a first layer, the second chip may be located in a second layer, and the third chip may be located in a third layer; and the photodetection element may further include a second through electrode that penetrates the embedding layer, is connected to the third wiring layer, and is shorter in length than the first through electrode. This brings about an effect that through electrodes connected to chips of different layers are extended to the outside.

In addition, according to a fourth aspect, the first chip may be located in a first layer, the second chip may be located in a third layer, and the third chip may be located in a second layer; the photodetection element may further include a second through electrode that penetrates a semiconductor layer of the second chip, is connected to the second wiring layer, and is shorter in length than the first through electrode; and the first through electrode may penetrate the semiconductor layer of the second chip and the embedding layer and be connected to the second wiring layer. This makes it possible to improve the strength of the packaged photodetection element without using the support substrate, and brings about an effect that the through electrodes connected to chips of different layers are extended to the outside.

In addition, according to the fourth aspect, at least a part of the first through electrode may include a pillar electrode. This brings about an effect that the first through electrode penetrating the embedding layer is formed while reducing the depth of the through hole in which the first through electrode is embedded.

Furthermore, according to the fourth aspect, the second chip may include a semiconductor layer on which the second wiring layer is formed, and a through via that penetrates the semiconductor layer and is connected to the second wiring layer; and the first through electrode may penetrate the embedding layer and be connected to the second wiring layer via the through via. This brings about an effect of being electrically connected to the second wiring layer formed on the second chip while reducing the depth of the through hole in which the first through electrode is embedded.

In addition, according to the fourth aspect, a dummy chip embedded in the embedding layer may be further included, and the first through electrode may penetrate the embedding layer and the dummy chip, and be connected to the second wiring layer. This brings about an effect that the through electrode is connected to the second wiring layer of the second chip laminated on the embedding layer while reducing the depth of the through hole formed in the embedding layer.

In addition, according to the fourth aspect, the second chip may include a semiconductor layer on which the second wiring layer is formed, and the first through electrode may penetrate the embedding layer, the dummy chip, and the semiconductor layer and be connected to the second wiring layer. This brings about an effect that the through electrode is connected to the second wiring layer of the second chip laminated on the embedding layer while reducing the depth of the through hole formed in the embedding layer.

Furthermore, according to the fourth aspect, the second chip may include a semiconductor layer on which the second wiring layer is formed, and a through via that penetrates the semiconductor layer and is connected to the second wiring layer; and the first through electrode may penetrate the embedding layer and the dummy chip and be connected to the second wiring layer via the through via. This brings about an effect that, while reducing the depth of the through hole in which the through electrode is embedded, the through electrode is electrically connected to the second wiring layer of the second chip laminated on the embedding layer, and formation of the through hole in the embedding layer is unnecessary.

Furthermore, according to the fourth aspect, a dummy chip embedded in the embedding layer and having a dummy wiring layer formed on a dummy substrate may be further included, and the first through electrode may penetrate the embedding layer and the dummy substrate, and be connected to the second wiring layer via the dummy wiring layer. This brings about an effect of being electrically connected to the second wiring layer formed on the second chip while reducing the depth of the through hole in which the through electrode is embedded.

In addition, according to the fourth aspect, a support substrate that supports the embedding layer in which the third chip is embedded may be further included, and the through electrode may penetrate the support substrate. This brings about an effect that the strength of the packaged photodetection element is secured while coping with thinning of the chip embedded in the embedding layer.

In addition, a fifth aspect provides a photodetection element including: a first chip in which a first wiring layer is formed on a first semiconductor substrate; an embedding layer in which the first chip is embedded; a through electrode that penetrates the embedding layer; and an embedded member that is embedded in the first semiconductor substrate at a position insulated from the first wiring layer. This brings about an effect that the restriction on the arrangement position of the through electrode connected to the external terminal of the photodetection element is alleviated while the non-uniformity of the stress applied to the first chip due to the through electrode is alleviated.

In addition, according to the fifth aspect, a second chip that forms a laminated structure with the first chip, and on which a second wiring layer extending onto the embedding layer is formed may be further included, and the embedding layer may form a laminated structure with the second chip so that the first chip is embedded in the embedding layer. This brings about an effect that the restriction on the arrangement position of the through electrode connected to the external terminal of the packaged photodetection element is alleviated while supporting the laminated structure of three or more layers of chips.

In addition, according to the fifth aspect, a support substrate that supports the embedding layer in which the first chip is embedded may be further included, and the through electrode may penetrate the support substrate. This brings about an effect that the through electrode is extended to the outside while coping with the thinning of the first chip.

In addition, according to the fifth aspect, in the first semiconductor substrate, an area density of the embedded member in a region close to the through electrode may be smaller than an area density of the embedded member in a region far from the through electrode. This brings about an effect that stress applied to the first chip is alleviated while it is not necessary to set a keep-out zone between the first chip and the through electrode.

In addition, according to the fifth aspect, an area density of the embedded member in a region up to 200 μm from an end of the first semiconductor substrate on the through electrode side may be smaller than an area density of the embedded member in a region exceeding 200 μm from the end of the first semiconductor substrate. This brings about an effect that stress applied to the first chip is alleviated while it is not necessary to set a keep-out zone between the first chip and the through electrode.

In addition, according to the fifth aspect, any one of a heat dissipation film, a protective film, a warpage correction film, and a laminated film obtained by combining these films may be formed on the back surface side of the first chip. This brings about an effect of improving the characteristics and reliability of the first chip while curbing complication of the manufacturing process.

In addition, a sixth aspect provides a method of manufacturing a photodetection element, the method including: a step of forming a laminated wafer in which a second wafer to be divided into second chips is laminated on a first wafer to be divided into first chips; a step of laminating a third chip on the laminated wafer; a step of forming an embedding layer laminated on the laminated wafer so that the third chip is embedded in the embedding layer; a step of forming a through electrode electrically connected to the second chip via the embedding layer; and a step of forming a photodetection element in which the laminated wafer is singulated together with the embedding layer in which the third chip is embedded. This brings about an effect that a plurality of photodetection elements is integrally formed while alleviating the restriction of the arrangement position of the through electrode connected to the external terminal of the photodetection element having a laminated structure of three or more layers of chips.

Furthermore, according to the sixth aspect, a step of laminating a support substrate wafer on the embedding layer may be further included, the through electrode may penetrate the support substrate wafer, and the laminated wafer and the support substrate wafer may be singulated along the same cut surface together with the embedding layer in which the third chip is embedded. This brings about an effect that the support substrate is collectively attached to the plurality of photodetection elements.

Furthermore, according to the sixth aspect, the first chip may include a sensor chip having a wiring layer formed on a front surface side and a pixel formed on a back surface side; the method may further include a step of laminating a transparent substrate wafer on the side of the pixel formation surface; and the laminated wafer and the transparent substrate wafer may be singulated along the same cut surface together with the embedding layer in which the third chip is embedded. This brings about an effect that the transparent substrate is collectively attached to the plurality of photodetection elements.

### BRIEF DESCRIPTION OF DRAWINGS

FIG. 1 is a cross-sectional view illustrating a first example of a configuration of a photodetection element according to a first embodiment.

FIG. 2 is a cross-sectional view illustrating a second example of the configuration of the photodetection element according to the first embodiment.

FIG. 3 is a first cross-sectional view illustrating an example of a method of manufacturing the photodetection element according to the first embodiment.

FIG. 4 is a second cross-sectional view illustrating an example of the method of manufacturing the photodetection element according to the first embodiment.

FIG. 5 is a third cross-sectional view illustrating an example of the method of manufacturing the photodetection element according to the first embodiment.

FIG. 6 is a fourth cross-sectional view illustrating an example of the method of manufacturing the photodetection element according to the first embodiment.

FIG. 7 is a fifth cross-sectional view illustrating an example of the method of manufacturing the photodetection element according to the first embodiment.

FIG. 8 is a sixth cross-sectional view illustrating an example of the method of manufacturing the photodetection element according to the first embodiment.

FIG. 9 is a seventh cross-sectional view illustrating an example of the method of manufacturing the photodetection element according to the first embodiment.

FIG. 10 is an eighth cross-sectional view illustrating an example of the method of manufacturing the photodetection element according to the first embodiment.

FIG. 11 is a ninth cross-sectional view illustrating an example of the method of manufacturing the photodetection element according to the first embodiment.

FIG. 12 is a 10th cross-sectional view illustrating an example of the method of manufacturing the photodetection element according to the first embodiment.

FIG. 13 is a cross-sectional view illustrating a first example of a configuration of a photodetection element according to a second embodiment.

FIG. 14 is a cross-sectional view illustrating a second example of the configuration of the photodetection element according to the second embodiment.

FIG. 15 is a plan view illustrating arrangement examples of external terminals of the photodetection element according to the second embodiment.

FIG. 16 is a cross-sectional view illustrating a first example of a configuration of a photodetection element according to a third embodiment.

FIG. 17 is a cross-sectional view illustrating a second example of the configuration of the photodetection element according to the third embodiment.

FIG. 18 is a cross-sectional view illustrating a third example of the configuration of the photodetection element according to the third embodiment.

FIG. 19 is a plan view illustrating arrangement examples of external terminals and redistribution lines of the photodetection element according to the third embodiment.

FIG. 20 is a cross-sectional view illustrating a first example of a configuration of a photodetection element according to a fourth embodiment.

FIG. 21 is a cross-sectional view illustrating a second example of the configuration of the photodetection element according to the fourth embodiment.

FIG. 22 is a cross-sectional view illustrating a third example of the configuration of the photodetection element according to the fourth embodiment.

FIG. 23 is a cross-sectional view illustrating a configuration example of a photodetection element according to a fifth embodiment.

FIG. 24 is a first cross-sectional view and a plan view illustrating an example of a method of manufacturing the photodetection element according to the fifth embodiment.

FIG. 25 is a second cross-sectional view illustrating an example of the method of manufacturing the photodetection element according to the fifth embodiment.

FIG. 26 is a third cross-sectional view illustrating an example of the method of manufacturing the photodetection element according to the fifth embodiment.

FIG. 27 is a fourth cross-sectional view illustrating an example of the method of manufacturing the photodetection element according to the fifth embodiment.

FIG. 28 is a cross-sectional view illustrating a configuration example of a photodetection element according to a sixth embodiment.

FIG. 29 is a cross-sectional view illustrating a configuration example of a photodetection element according to a seventh embodiment.

FIG. 30 is a cross-sectional view illustrating a configuration example of a photodetection element according to an eighth embodiment.

FIG. 31 is a cross-sectional view illustrating a configuration example of a photodetection element according to a ninth embodiment.

FIG. 32 is a cross-sectional view illustrating a configuration example of a photodetection element according to a 10th embodiment.

FIG. 33 is a cross-sectional view illustrating a configuration example of a photodetection element according to an 11th embodiment.

FIG. 34 is a diagram illustrating a configuration example of a photodetection element according to a 12th embodiment.

FIG. 35 is a diagram illustrating a relationship between a horizontal position and stress in the photodetection element according to the 12th embodiment.

FIG. 36 is a diagram illustrating another configuration example of the photodetection element according to the 12th embodiment.

FIG. 37 is a diagram illustrating still another configuration example of the photodetection element according to the 12th embodiment.

FIG. 38 is a diagram illustrating a configuration example of a photodetection element according to a 13th embodiment.

FIG. 39 is a cross-sectional view illustrating a configuration example of a photodetection element according to a 14th embodiment.

FIG. 40 is a cross-sectional view illustrating a configuration example of a photodetection element according to a 15th embodiment.

FIG. 41 is a cross-sectional view illustrating a configuration example of a photodetection element according to a 16th embodiment.

FIG. 42 is a cross-sectional view illustrating a configuration example of a photodetection element according to a 17th embodiment.

FIG. 43 is a cross-sectional view illustrating a configuration example of a photodetection element according to an 18th embodiment.

FIG. 44 is a first cross-sectional view illustrating an example of a method of manufacturing a photodetection element according to a 19th embodiment.

FIG. 45 is a second cross-sectional view illustrating an example of the method of manufacturing the photodetection element according to the 19th embodiment.

FIG. 46 is a third cross-sectional view illustrating an example of the method of manufacturing the photodetection element according to the 19th embodiment.

FIG. 47 is a fourth cross-sectional view illustrating an example of the method of manufacturing the photodetection element according to the 19th embodiment.

FIG. 48 is a fifth cross-sectional view illustrating an example of the method of manufacturing the photodetection element according to the 19th embodiment.

FIG. 49 is a cross-sectional view illustrating a configuration example of a photodetection element according to a 20th embodiment.

FIG. 50 is a first cross-sectional view illustrating an example of a method of manufacturing the photodetection element according to the 20th embodiment.

FIG. 51 is a second cross-sectional view illustrating an example of the method of manufacturing the photodetection element according to the 20th embodiment.

FIG. 52 is a third cross-sectional view illustrating an example of the method of manufacturing the photodetection element according to the 20th embodiment.

FIG. 53 is a fourth cross-sectional view illustrating an example of the method of manufacturing the photodetection element according to the 20th embodiment.

FIG. 54 is a fifth cross-sectional view illustrating an example of the method of manufacturing the photodetection element according to the 20th embodiment.

FIG. 55 is a sixth cross-sectional view illustrating an example of the method of manufacturing the photodetection element according to the 20th embodiment.

FIG. 56 is a seventh cross-sectional view illustrating an example of the method of manufacturing the photodetection element according to the 20th embodiment.

FIG. 57 is an eighth cross-sectional view illustrating an example of the method of manufacturing the photodetection element according to the 20th embodiment.

FIG. 58 is a ninth cross-sectional view illustrating an example of the method of manufacturing the photodetection element according to the 20th embodiment.

FIG. 59 is a flowchart illustrating an example of the method of manufacturing the photodetection element according to the 20th embodiment.

FIG. 60 is a cross-sectional view illustrating a configuration example of a photodetection element according to a 21st embodiment.

FIG. 61 is a flowchart illustrating an example of a method of manufacturing the photodetection element according to the 21st embodiment.

FIG. 62 is a cross-sectional view illustrating a configuration example of a photodetection element according to a 22nd embodiment.

FIG. 63 is a flowchart illustrating an example of a method of manufacturing the photodetection element according to the 22nd embodiment.

FIG. 64 is a cross-sectional view illustrating a configuration example of a photodetection element according to a 23rd embodiment.

FIG. 65 is a flowchart illustrating an example of a method of manufacturing the photodetection element according to the 23rd embodiment.

FIG. 66 is a cross-sectional view illustrating a configuration example of a photodetection element according to a 24th embodiment.

FIG. 67 is a flowchart illustrating an example of a method of manufacturing the photodetection element according to the 24th embodiment.

FIG. 68 is a cross-sectional view illustrating a configuration example of a photodetection element according to a 25th embodiment.

FIG. 69 is a block diagram illustrating a schematic configuration example of a vehicle control system.

FIG. 70 is an explanatory diagram illustrating an example of an installation position of an imaging section.

### MODE FOR CARRYING OUT THE INVENTION

Modes for carrying out the present technology (hereinafter referred to as embodiments) will be described below. The description will be given in the following order.
1. First embodiment (example in which through electrode connected to external terminal is provided between lower layer chips embedded in embedding layer laminated on upper layer chip)
2. Second embodiment (example in which through electrode electrically connected to external terminal via embedding layer in which lower layer chip is embedded is connected to upper layer chip or lower layer chip)
3. Third embodiment (example in which through electrode is connected to external terminal via redistribution line formed on embedding layer in which lower layer chip is embedded)
4. Fourth embodiment (example in which through electrode is connected to external terminal via support substrate arranged on embedding layer in which lower layer chip is embedded)
5. Fifth embodiment (example of face down mounting of upper layer chip connected to through electrode electrically connected to external terminal via embedding layer in which lower layer chip is embedded)
6. Sixth embodiment (example in which through electrode electrically connected to external terminal via embedding layer in which lower layer chip mounted face down on an upper layer chip is embedded is connected to lower layer chip via back surface wiring of upper layer chip, and sensor chip is laminated on uppermost layer)
7. Seventh embodiment (example in which through electrode electrically connected to external terminal via embedding layer in which lower layer chip mounted face down on an upper layer chip is embedded is connected to lower layer chip via wiring of upper layer chip, and sensor chip is laminated on uppermost layer)
8. Eighth embodiment (example in which lower layer chip is mounted face down on three-layer laminated chip, and through electrode electrically connected to external terminal via embedding layer in which lower layer chip is embedded is connected to lower layer chip via wiring of upper layer chip)
9. Ninth embodiment (example in which lower layer chip is mounted face down on three-layer laminated chip, and through electrode electrically connected to external terminal via embedding layer in which lower layer chip is embedded is connected to lower layer chip via back surface wiring of upper layer chip)
10. 10th embodiment (example in which lengths of through electrodes that penetrate lower layer chip and are electrically connected to external terminal are made different)
11. 11th Embodiment (example in which through electrode electrically connected to external terminal via embedding layer in which lower layer chip mounted face down on upper layer chip is embedded is connected to lower layer chip via wiring of upper layer chip)
12. 12th embodiment (example in which embedded member is embedded in semiconductor substrate of chip embedded in embedding layer in which through electrode is embedded)
13. 13th embodiment (example in which position of embedded member embedded in semiconductor substrate of chip is made different according to arrangement position of through electrode)
14. 14th embodiment (example in which stress alleviating film is formed on bottom surface and side surface of embedded member embedded in semiconductor substrate of chip)
15. 15th embodiment (example in which embedded member embedded in semiconductor substrate of chip is formed using embedding layer in which chip is embedded)
16. 16th embodiment (example of forming functional film on bottom surface and side surface of embedded member embedded in semiconductor substrate of chip)
17. 17th embodiment (example of forming functional film on back surface side of chip in which embedded member is embedded)
18. 18th embodiment (example in which a part of embedded member embedded in semiconductor substrate of chip embedded in embedding layer penetrates semiconductor substrate)
19. 19th embodiment (example in which different functional films are formed on bottom surface, side surface, and front surface of embedded member embedded in semiconductor substrate of chip embedded in embedding layer)
20. 20th embodiment (example in which a part of through electrode embedded in embedding layer in which chip is embedded is configured by pillar electrode)
21. 21st embodiment (example of providing through electrode penetrating dummy chip having wiring layer embedded in embedding layer in which chip is embedded)
22. 22nd embodiment (example of providing through electrode penetrating dummy chip having no wiring layer embedded in embedding layer in which chip is embedded)
23. 23rd embodiment (example in which through electrode penetrating dummy chip embedded in embedding layer in which chip is embedded also penetrates semiconductor layer of chip laminated on embedding layer and is connected to wiring layer)
24. 24th embodiment (example in which through electrode penetrating dummy chip embedded in embedding layer in which chip is embedded is connected to wiring layer via through via embedded in chip laminated on embedding layer)
25. 25th embodiment (example in which through electrode penetrating embedding layer in which chip is embedded is connected to wiring layer via through via embedded in chip laminated on embedding layer)
26. Example of application to mobile object

### 1. First Embodiment

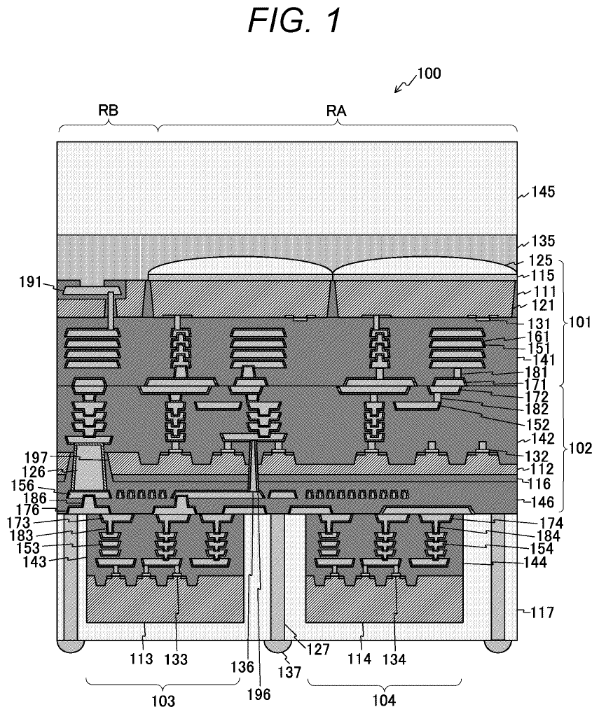

FIG. 1 is a cross-sectional view illustrating a first example of a configuration of a photodetection element according to a first embodiment;

In FIG. 1, a photodetection element 100 includes chips 101 to 104. Each of the chips 101 to 104 may be a semiconductor chip or may include an optical chip. At this time, the optical chip can be used as an uppermost chip provided in the photodetection element 100.

An optical element is formed on the optical chip. The optical element may be a solid-state imaging element such as a charged coupled device (CCD) or a complementary metal-oxide semiconductor (CMOS). The light received by the solid-state imaging element may be visible light, near infrared light (NIR), short wavelength infrared light (SWIR), ultraviolet light, X-ray, or the like. The optical element may be a light receiving element such as a photo diode (PD), or may be a light emitting element such as a laser diode (LD), a light emitting diode (LED), or a vertical cavity surface emitting laser (VCSEL). The optical element may be a micro electro mechanical systems (MEMS) element such as an optical switch or a mirror device. The material used for the base material of the optical chip may be a semiconductor such as Si, GaAS, or InGaAsP, or may be a dielectric such as LiNbO₃, glass, or a transparent resin.

A semiconductor element is formed on the semiconductor chip. The semiconductor element may include a transistor, a resistor, a capacitor, and the like. In the semiconductor chip, a memory may be formed, a processor may be formed, a signal processing circuit may be formed, a data processing circuit may be formed, an interface circuit may be formed, or an optical element may be formed. In the semiconductor chip, for example, a hardware circuit such as a field-programmable gate array (FPGA) or an application specific integrated circuit (ASIC) may be formed. The material used for the base material of the semiconductor chip may be Si, GaAS, SiC, GaN, InGaAsP, or the like.

In the following description, a case where a back-illuminated solid-state imaging element is formed on the chip 101 and a semiconductor element is formed on each of the chips 102 to 104 is taken as an example. At this time, a logic circuit or a semiconductor storage device may be formed in each of the chips 102 to 104. The semiconductor storage device may include a read only memory (ROM), a dynamic random access memory (DRAM), or a NAND flash memory.

The chip 101 includes a semiconductor layer 111 and a wiring layer 141. The chip 101 is provided with an imaging region RA and a non-imaging region RB. The imaging region RA is provided with a pixel array unit in which pixels 121 are arranged in a matrix along the row direction and the column direction. The pixel 121 is provided with a photodiode and a pixel transistor 131. In the non-imaging region RB, a peripheral circuit that drives the pixel transistor 131 and outputs a signal read from the pixel 121 is provided.

The wiring layer 141 is formed on the front surface side of the semiconductor layer 111. At this time, the photodiode can be arranged on the back surface side of the semiconductor layer 111. The wiring layer 141 is provided with a wiring 151 embedded in the insulating layer, a pad electrode 171, and a via 181. The via 181 can be used for interlayer connection of the wiring 151. The pad electrode 171 can be used for direct bonding of the chip 101. A barrier metal film 161 may be formed around the wiring 151, the pad electrode 171, and the via 181.

On the back surface side of the semiconductor layer 111, a color filter 115 is formed for each of the pixels 121. The color filter 115 may form, for example, a Bayer array. An on-chip lens 125 is formed on the color filter 115 for each of the pixels 121. The material of the color filter 115 can be configured by, for example, adding a pigment or the like to a transparent resin such as acrylic or polycarbonate. As the material of the on-chip lens 125, for example, a transparent resin such as acrylic or polycarbonate can be used.

Furthermore, on the back surface side of the semiconductor layer 111, a transparent resin 135 is formed so as to cover the on-chip lens 125. A transparent substrate 145 is arranged on the transparent resin 135. The material of the transparent resin 135 is, for example, silicone, acrylic, or polycarbonate. At this time, the refractive index of the transparent resin 135 can be made smaller than the refractive index of the on-chip lens 125. The material of the transparent substrate 145 may be, for example, quartz, glass, or Al₂O₃, CaF₂, MgF₂, LiF, or the like according to the wavelength of the optical element. The transparent resin 135 may be used as an adhesive layer for bonding the transparent substrate 145. In addition, the transparent substrate 145 can be used as a reinforcing material for reinforcing the photodetection element 100. Note that the chip 101 is an example of a sensor chip described in the claims.

The chip 102 is laminated on the chip 101. The planar size and shape of the chip 102 can be equal to those of the chip 101. The chip 102 includes a semiconductor layer 112, a wiring layer 142, and a back surface wiring layer 146. A MOS transistor 132 can be formed on the semiconductor layer 112. Note that the wiring layer 142 is an example of a front surface wiring layer described in the claims.

The wiring layer 142 is formed on the front surface side of the semiconductor layer 112. The wiring layer 142 is provided with a wiring 152 embedded in the insulating layer, a pad electrode 172, and a via 182. The via 182 can be used for interlayer connection of the wiring 152. The pad electrode 172 can be used for direct bonding of the front surface side of the chip 102. For example, hybrid bonding may be used to directly bond the chip 101 to the chip 102.

In hybrid bonding, the pad electrode 171 is exposed on the surface of the wiring layer 141, the pad electrode 172 is exposed on the surface of the wiring layer 142, and the pad electrodes 171 and 172 are formed at positions facing each other. At this time, Cu can be used as the material of each of the pad electrodes 171 and 172. As the material of the insulating layer of each of the wiring layers 141 and 142, for example, SiO₂, SiN, or SiCN can be used. In addition, each of the pad electrodes 171 and 172 is recessed by about several tens of nanometers from the front surface of each of the wiring layers 141 and 142. At this time, the plane size of each of the pad electrodes 171 and 172 can be set within a range of 0.1 μm to 10 μm. Then, after surface treatment of the insulating layers of the wiring layers 141 and 142 is performed, these insulating layers are brought into facing contact with each other, so that these insulating layers are connected to each other. At this time, a slight gap is formed between the pad electrode 171 and the pad electrode 172. Then, the insulating layers of the wiring layers 141 and 142 are subjected to a heat treatment in a state of being pressure-bonded to each other, whereby the pad electrodes 171 and 172 expand, the pad electrodes 171 and 172 come into contact with each other, and interdiffusion of Cu causes a joint to be formed between the pad electrodes 171 and 172.

In this hybrid bonding, the plane size of each of the pad electrodes 171 and 172 can be set within a range of 0.1 μm to 10 μm. Therefore, as compared with the method of bonding the chips 101 and 102 via solder, the pitch of the bonding electrodes can be narrowed, and an increase in input and output to and from each of the chips 101 and 102 can be accommodated.

On the back surface side of the semiconductor layer 112, the back surface wiring layer 146 is formed via a protective film 116. The back surface wiring layer 146 is provided with a back surface wiring 156 embedded in the insulating layer, a pad electrode 176, and a via 186. The via 186 can be used for interlayer connection of the back surface wiring 156. The pad electrode 176 can be used for direct bonding of the back surface side of the chip 102.

Through vias 126 and 136 are embedded in the semiconductor layer 112. The diameter of the through via 126 can be made larger than the diameter of the through via 136. For example, the diameter of the through via 126 may be set within a range of 1 μmΦ to 20 μmΦ, and the diameter of the through via 136 may be set within a range of 0.1 μmΦ to 1 μmΦ. At this time, the through via 126 may be used for connection of the power supply wiring, and the through via 136 may be used for connection of the signal wiring. Furthermore, each of the through vias 126 and 136 may be arranged in a peripheral portion of the chip 102 or may be arranged in a central portion of the chip 102.

Each of the through vias 126 and 136 penetrates the semiconductor layer 112 of the chip 102 and can establish conduction between the wiring layer 142 and the back surface wiring layer 146. At this time, the insulating layer of the back surface wiring layer 146 may be embedded in a through hole 197 formed in the semiconductor layer 112, and the through via 126 may be insulated from the semiconductor layer 112 via the insulating layer of the back surface wiring layer 146. Furthermore, in order to insulate the through via 136 from the semiconductor layer 112, an insulating layer 196 may be formed around the through via 136.

The chip 103 is laminated on the back surface wiring layer 146 of the chip 102. The planar size of the chip 103 can be made smaller than that of the chip 101. The chip 103 includes a semiconductor layer 113 and a wiring layer 143. A MOS transistor 133 can be formed in the semiconductor layer 113.

The wiring layer 143 is formed on the front surface side of the semiconductor layer 113. The wiring layer 143 is provided with a wiring 153 embedded in the insulating layer, a pad electrode 173, and a via 183. The via 183 can be used for interlayer connection of the wiring 153. The pad electrode 173 can be used for direct bonding of the front surface side of the chip 103. For example, the chip 103 may be directly bonded to the chip 102 by hybrid bonding.

The chip 104 is laminated on the back surface wiring layer 146 of the chip 102. At this time, the chip 104 is arranged on the back surface wiring layer 146 side by side at an interval from the chip 103. The planar size of the chip 104 can be made smaller than that of the chip 101. The chip 104 includes a semiconductor layer 114 and a wiring layer 144. A MOS transistor 134 can be formed in the semiconductor layer 114.

The wiring layer 144 is formed on the front surface side of the semiconductor layer 114. The wiring layer 144 is provided with a wiring 154 embedded in the insulating layer, a pad electrode 174, and a via 184. The via 184 can be used for interlayer connection of the wiring 154. The pad electrode 174 can be used for direct bonding of the front surface side of the chip 104. For example, the chip 104 may be directly bonded to the chip 102 by hybrid bonding.

Further, on the back surface wiring layer 146, an embedding layer 117 is laminated so that the chips 103 and 104 are embedded therein. The front surface of the embedding layer 117 may be planarized. A through electrode 127 is embedded in the embedding layer 117. At this time, the through electrode 127 penetrates the embedding layer 117, is connected to the back surface wiring layer 146, and is extended to the front surface of the embedding layer 117. The through electrode 127 can be located between the chip 103 and the chip 104. The through electrode 127 may be arranged around each of the chips 103 and 104.

A bump electrode 137 is formed on the embedding layer 117 and connected to the through electrode 127. The bump electrode 137 can be used as an external terminal for electrically connecting the photodetection element 100 to the outside. Note that the bump electrode 137 may be a solder ball or a pillar electrode.

Here, the photodetection element 100 can be divided into individual photodetection elements 100 from a state in which the plurality of photodetection elements 100 is integrated in a wafer shape. In this singulation, for example, the photodetection element 100 integrated in a wafer shape may be cut along a dicing line partitioning the photodetection element 100. At this time, the position of the cut surface of the embedding layer 117, the position of the cut surface of each of the chips 101 and 102, and the position of the cut surface of the transparent substrate 145 can coincide with each other.

Each of the semiconductor layers 111 to 114 may be a semiconductor substrate, a thinned semiconductor substrate, or a semiconductor layer used for a silicon on insulator (SOI) substrate.

As the materials of the insulating layer used for each of the wiring layers 141 to 144, the protective film 116, and the insulating layer 196, for example, SiO₂, SiN, or SiCN can be used. As the materials of the wirings 151 to 154, the pad electrodes 171 to 174, the vias 181 to 184, and the through vias 126 and 136, for example, a metal such as Al, Cu, AlCu, AlSiCu, or Co can be used. As the material of the through electrode 127, for example, a metal such as Cu, Ti, Ta, Al, W, Ni, Ru, or Co can be used, and a laminated structure of a plurality of materials may be used. As the material of the barrier metal film 161, for example, a metal such as Ta or TaN can be used.

The material of the embedding layer 117 includes an insulating layer of an inorganic or organic material, and a plurality of films may be laminated. For example, in the case of an inorganic film, SiO₂, SiON, SiN, SiOC, and SiCN are used, and in the case of an organic film, a resin having a skeleton such as silicone, polyimide, acrylic, epoxy, polymer, or PEEK material, or a material containing a filler such as SiO₂, Al₂O₃, AlN, or BN is used. The material of the embedding layer 117 may be a molding material. Furthermore, the embedding layer 117 preferably includes a material having heat resistance within a range of 100 degrees to 500 degrees.

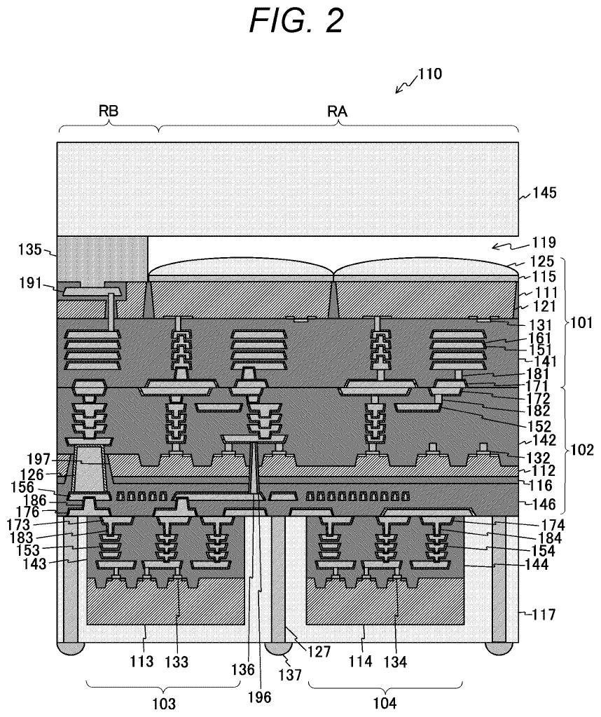

FIG. 2 is a cross-sectional view illustrating a second example of the configuration of the photodetection element according to the first embodiment.

In FIG. 2, in a photodetection element 110, a cavity 119 is added to the photodetection element 100 of the first example of the first embodiment described above. Other configurations of the photodetection element 110 of the second example of the first embodiment are similar to the configurations of the photodetection element 100 of the first example of the first embodiment described above.

The cavity 119 separates an imaging region RA of a chip 101 from a transparent resin 135 and a transparent substrate 145. At this time, the transparent resin 135 can be prevented from contacting the on-chip lens 125. The cavity 119 can be provided by forming the transparent resin 135 only on a non-imaging region RB. The cavity 119 may be formed in the transparent substrate 145. Here, by providing the cavity 119 on the imaging region RA, the photodetection element 110 can be reinforced without affecting the optical function of the chip 101. Note that an antireflection film or a light shielding film that prevents flare, stray light, or the like may be formed on the transparent substrate 145.

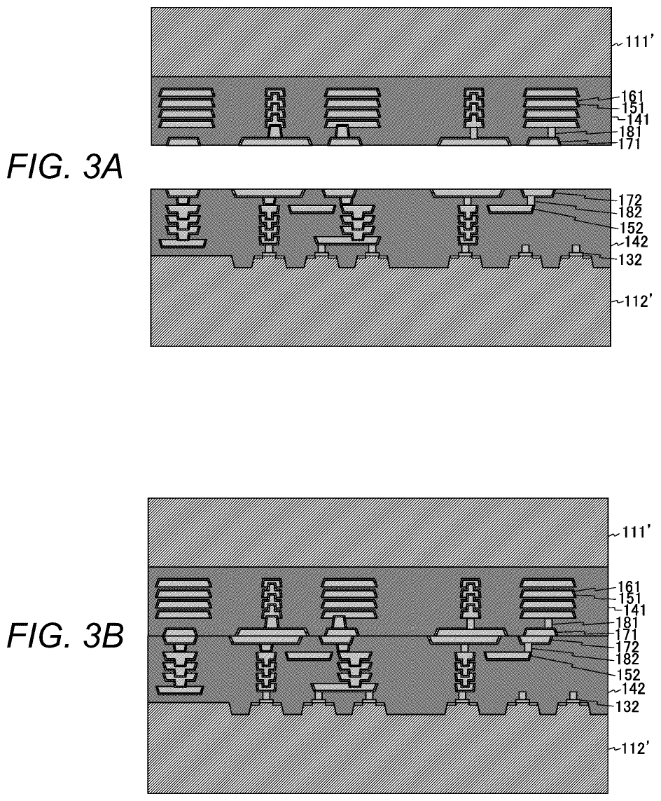

FIGS. 3 to 12 are cross-sectional views illustrating an example of a method of manufacturing the photodetection element according to the first embodiment.

In a of FIG. 3, the pixel array unit and the peripheral circuits are formed on a semiconductor wafer 111′ for each section into which the chip 101 is cut out. Next, the wiring layer 141 provided with the wiring 151, the pad electrode 171, and the via 181 is formed on the semiconductor wafer 111′. The insulating layer of the wiring layer 141 can be formed by, for example, chemical vapor deposition (CVD) or physical vapor deposition (PVD). In addition, the front surface of the wiring layer 141 can be planarized by a method such as chemical mechanical polishing (CMP) so that the pad electrode 171 is exposed. The planar size of the pad electrode 171 can be set within a range of 0.1×0.1 μm to 10×10 μm. A plurality of chips 101 used for a plurality of photodetection elements 100 can be cut out from the semiconductor wafer 111′. For example, the semiconductor wafer 111′ can be partitioned along a dicing line used for the singulation of the photodetection element 100.

In addition, a semiconductor element such as the transistor 132 is formed on a semiconductor wafer 112′ for each section into which the chip 102 is cut out. Next, the wiring layer 142 provided with the wiring 152, the pad electrode 172, and the via 182 is formed on the semiconductor wafer 112′. The insulating layer of the wiring layer 142 can be formed by, for example, CVD or PVD. In addition, the front surface of the wiring layer 142 can be planarized by a method such as CMP so that the pad electrode 172 is exposed. The planar size of the pad electrode 172 can be set within a range of 0.1×0.1 μm to 10×10 μm. A plurality of chips 102 used for a plurality of photodetection elements 100 can be cut out from the semiconductor wafer 112′. For example, the semiconductor wafer 112′ can be partitioned along a dicing line used for the singulation of the photodetection element 100.

Next, as illustrated in b of FIG. 3, the wiring layer 141 and the wiring layer 142 are directly bonded so that the wiring layers 141 and 142 face each other. At this time, the pad electrode 171 of the wiring layer 141 and the pad electrode 172 of the wiring layer 142 may be Cu—Cu bonded. In order to improve the bonding strength, the surfaces of the wiring layers 141 and 142 may be subjected to plasma treatment or wet treatment. In order to obtain sufficient bonding strength and good contact of the Cu bonding portion, the laminated wafer on which the semiconductor wafers 111′ and 112′ are laminated may be heat treated at 200 degrees to 400 degrees.

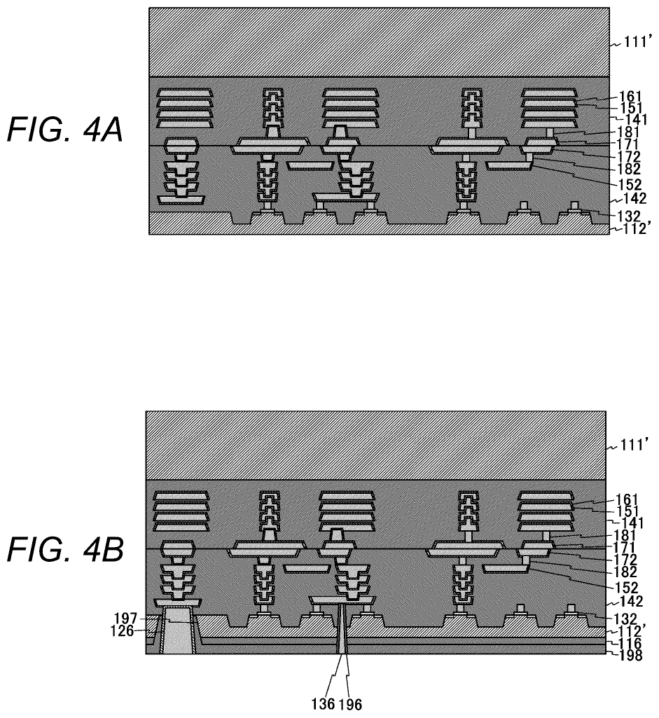

Next, as illustrated in a of FIG. 4, the semiconductor wafer 112′ is thinned from the back surface side. In thinning the semiconductor wafer 112′, a grinder, CMP, or etch back may be used. At this time, the thickness of the semiconductor wafer 112′ can be set within a range of 1 μm to 20 μm.

Next, as illustrated in b of FIG. 4, the protective film 116 is formed on the back surface side of the semiconductor wafer 112′ by a method such as CVD. Next, the through hole 197 is formed in the semiconductor layer 112 by using a photolithography technique and a dry etching technique. Next, an insulating layer 198 is formed on the protective film 116 so that the through hole 197 is embedded by a method such as CVD. Next, the insulating film at the connection position of each of the through vias 126 and 136 is removed, and each of the through vias 126 and 136 is embedded so as to be electrically connected to the wiring 152. Electroplating may be used to embed the through vias 126 and 136, for example. The top surface of each of the through vias 126 and 136 can be exposed from the insulating layer 198. At this time, a damascene method using CMP or the like may be used. The insulating layer 198 may cover the periphery of the through via 126 to insulate the through via 126 from the semiconductor wafer 112′. Additionally, the insulating layer 196 may be formed around the through via 136 to insulate the through via 136 from the semiconductor wafer 112′. In addition, a barrier metal film such as Ti or TiN may be formed on the side surface and the bottom surface of each of the through vias 126 and 136.

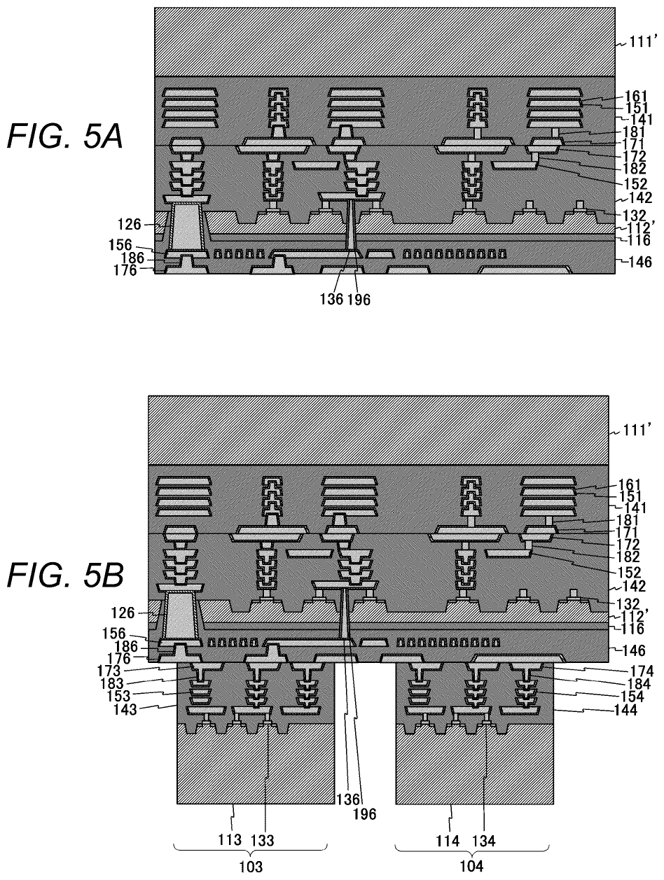

Next, as illustrated in a of FIG. 5, the back surface wiring layer 146 provided with the back surface wiring 156, the pad electrode 176, and the via 186 is formed on the protective film 116. At this time, the through vias 126 and 136 can be electrically connected to the back surface wiring 156. The insulating layer of the back surface wiring layer 146 can be formed by, for example, CVD or PVD. In addition, the front surface of the back surface wiring layer 146 can be planarized by a method such as CMP so that the pad electrode 176 is exposed. The planar size of the pad electrode 176 can be set within a range of 0.1×0.1 μm to 10×10 μm.

Next, as illustrated in b of FIG. 5, singulated chips 103 and 104 are prepared. Then, the wiring layers 143 and 144 are directly bonded to the back surface wiring layer 146 such that the wiring layers 143 and 144 face the back surface wiring layer 146. At this time, the pad electrode 173 of the wiring layer 143 and the pad electrode 174 of the wiring layer 144 may be Cu—Cu bonded to the pad electrode 176 of the back surface wiring layer 146. In order to improve the bonding strength, the surfaces of the wiring layers 143 and 144 and the back surface wiring layer 146 may be subjected to plasma treatment or wet treatment. In order to obtain sufficient bonding strength and good contact of the Cu bonding portion, the laminated structure in which the chips 103 and 104 are laminated on the laminated wafer in which the semiconductor wafers 111′ and 112′ are laminated may be heat treated at 200 degrees to 400 degrees. Each chip 103 and 104 can be arranged side by side on the laminated wafer in which the semiconductor wafers 111′ and 112′ are bonded to each other, for each section into which the photodetection element 100 is cut out.

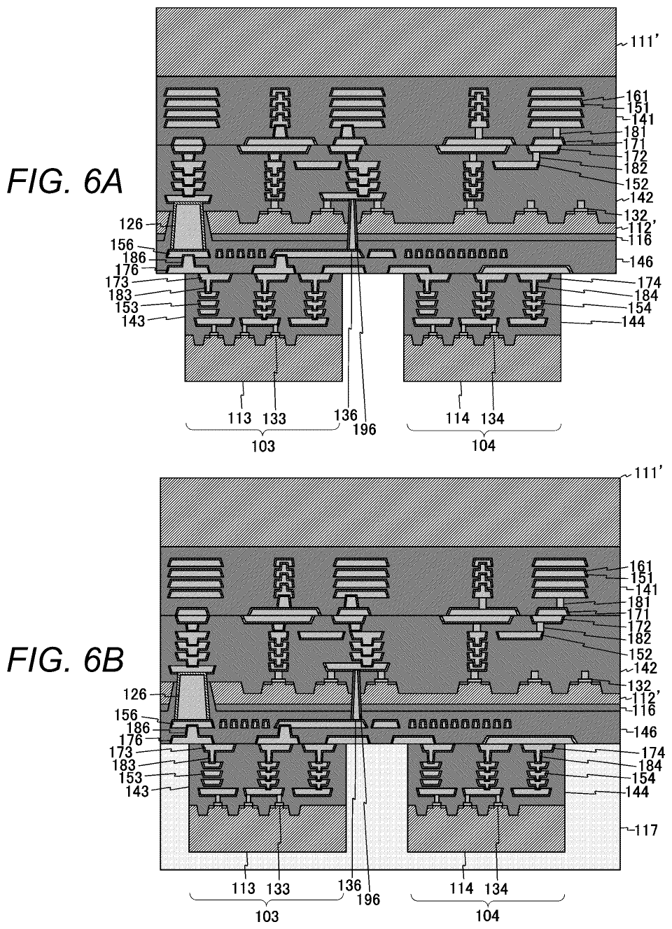

Next, as illustrated in a of FIG. 6, the semiconductor layers 113 and 114 are thinned from the back surface side. In thinning the semiconductor layers 113 and 114, a grinder or CMP may be used. At this time, the thickness of each of the semiconductor layers 113 and 114 can be set within a range of 0.5 μm to 50 μm.

Next, as illustrated in b of FIG. 6, the embedding layer 117 is laminated on the back surface wiring layer 146 so that the chips 103 and 104 are embedded therein. For lamination of the embedding layer 117, CVD, atomic layer deposition (ALD), vapor deposition, sputtering, or the like may be used in the case of an inorganic material, and coating, dipping, spray coating, or the like may be used in the case of an organic material. The embedding layer 117 may be planarized. In the planarization of the embedding layer 117, a grinder or CMP may be used.

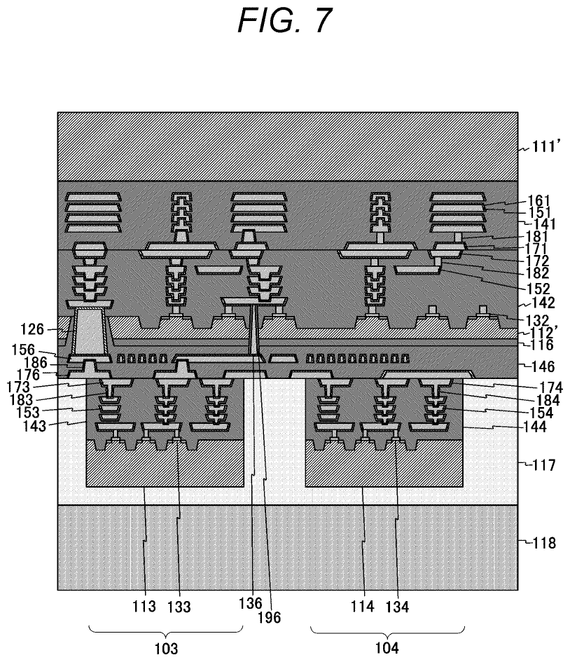

Next, as illustrated in FIG. 7, a temporary substrate 118 is bonded onto the embedding layer 117. The planar size and shape of the temporary substrate 118 can be equal to the planar size and shape of the semiconductor wafer 111′. The thickness of the temporary substrate 118 can be set within a range of 300 μm to 800 μm. The temporary substrate 118 may be a Si substrate or a glass substrate. In the bonding of the temporary substrate 118, an adhesive or oxide film bonding may be used. Note that the process may proceed to the next step without bonding the temporary substrate 118 onto the embedding layer 117.

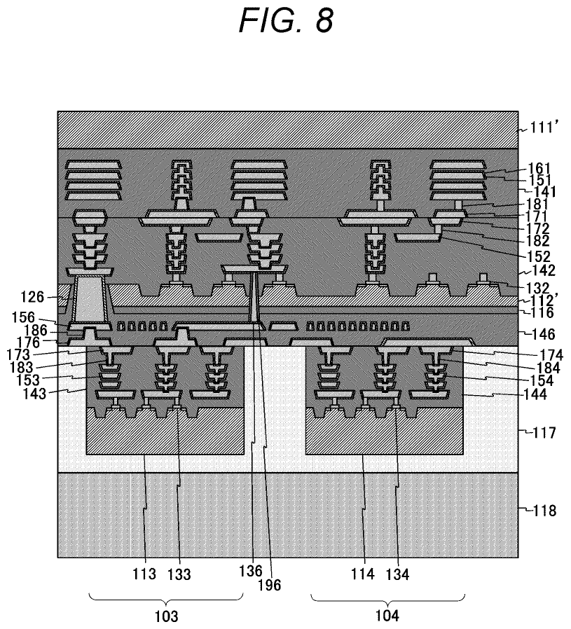

Next, as illustrated in FIG. 8, the semiconductor wafer 111′ is thinned from the back surface side. In this thinning, for example, a grinder, CMP, dry etching, or wet etching may be used. In a case where a back-illuminated individual imaging element is formed on the semiconductor wafer 111′, the rear surface side of the thinned semiconductor wafer 111′ becomes the light receiving surface.

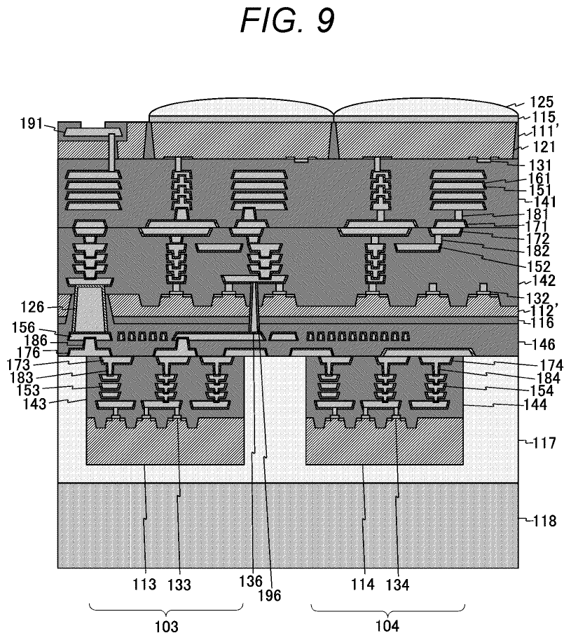

Next, as illustrated in FIG. 9, the color filter 115 is formed for each pixel 121 on the back surface side of the semiconductor layer 111. Moreover, the on-chip lens 125 is formed on the color filter 115 for each pixel 121. A pad electrode 191 for connection test evaluation may be formed on the back surface side of the semiconductor layer 111.

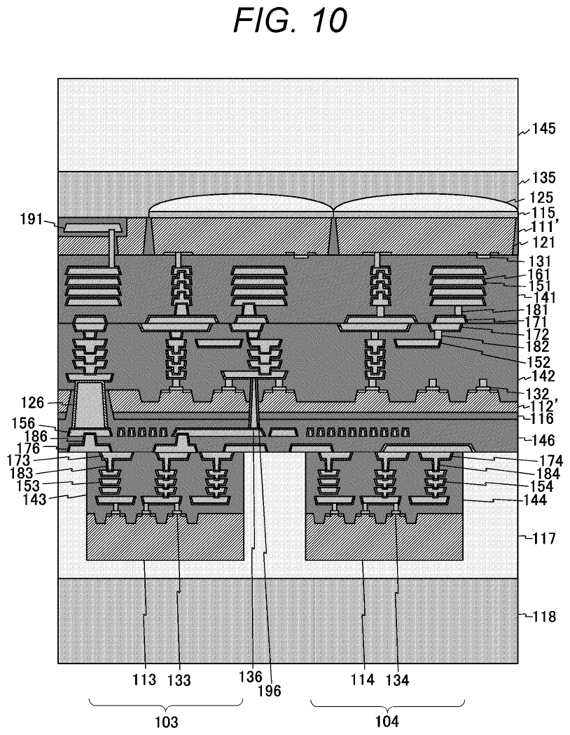

Next, as illustrated in FIG. 10, the transparent substrate 145 is arranged on the back surface side of the semiconductor wafer 111′ via the transparent resin 135 formed to cover the on-chip lenses 125. Note that in a case where the cavity 119 in FIG. 2 is formed, the transparent resin 135 may be patterned before the transparent substrate 145 is arranged on the back surface side of the semiconductor wafer 111′. The thickness of the transparent resin 135 can be set within a range of 100 μm to 775 μm.

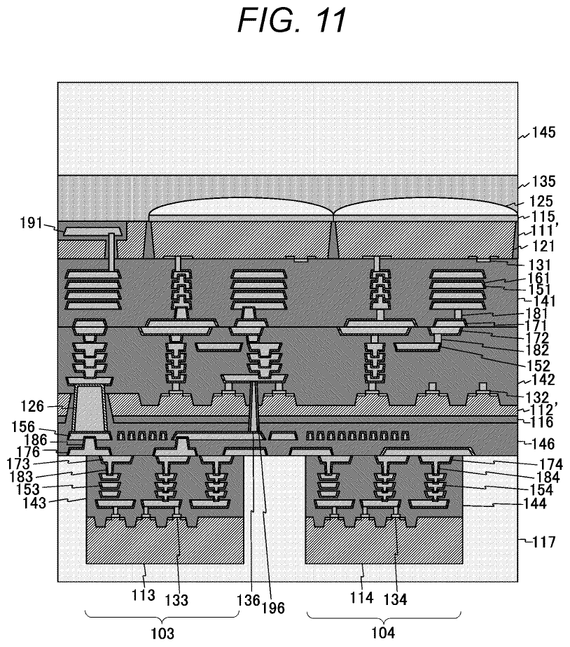

Next, as illustrated in FIG. 11, the temporary substrate 118 on the embedding layer 117 is peeled off. As the method for peeling the temporary substrate 118, in a case where the temporary substrate 118 is a resin, a chemical solution for dissolving the temporary substrate 118 may be used, the temporary substrate 118 may be mechanically scraped, or the adhesiveness of the peeling surface may be reduced on the basis of ultraviolet irradiation. In the case of oxide film peeling, Si may be cut with a grinder, Si may be dissolved by wet treatment, or a combination thereof may be used.

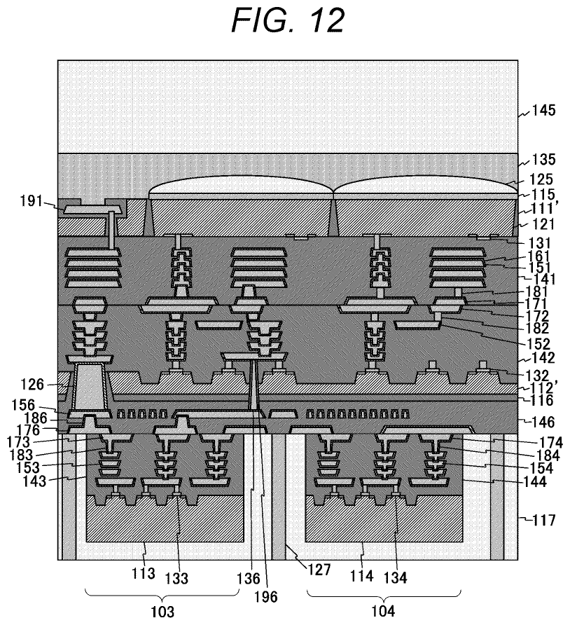

Next, as illustrated in FIG. 12, the through electrode 127 penetrating the embedding layer 117 and connected to the back surface wiring layer 146 is formed. Note that in order to connect the through electrode 127 to the back surface wiring layer 146, a pad electrode to which the through electrode 127 is connected may be formed on the back surface wiring layer 146. The diameter of the through electrode 127 can be set according to the number of IOs extracted outside the photodetection element 100, and can be set within a range of 3 μmΦ to 100 μmΦ, for example. An insulating film such as SiO₂ or SiN may be formed on the side wall of the through electrode 127. Note, however, that in a case where the embedding layer 117 includes an insulator, it is not necessary to separately form an insulating film on the side wall of the through electrode 127. Furthermore, a barrier metal film such as Ti or TiN may be formed on the side wall of the through electrode 127. The through electrode 127 may be formed by, for example, electrolytic plating using Cu as a filling material. As a method of forming the through hole in which the through electrode 127 is embedded in the embedding layer 117, dry etching, wet etching, or laser processing may be used.

Next, as illustrated in FIG. 1, the bump electrode 137 connected to the through electrode 127 is formed on the embedding layer 117. The bump electrode 137 can be used as an external terminal for connection with a mounting substrate on which the photodetection element 100 is mounted. The bump electrode 137 may be a solder ball. At this time, a solder mask may be formed in order to determine the solder diameter. The solder diameter can be set within a range of 50 μmΦ to 400 μmΦ, and SnAgCu, SnCu, SnBi, or the like may be used as the solder material. As a metal pad for receiving solder, a Ti/Cu laminated film may be formed below the solder mask. TiN, Ni, Co, Ta, or TaN may be used instead of Ti, or a combination thereof may be used. In addition to the structure in which the metal pad for receiving solder is formed, solder may be formed by erecting a Cu pillar. At this time, for example, a laminated structure of Cu/Ni/solder may be used. Next, the laminated wafer of the semiconductor wafers 111′ and 112′ is then singulated together with the embedding layer 117 in which the chips 103 and 104 are embedded to form the photodetection element 100. In this singulation, blade dicing may be used.

As described above, in the first embodiment described above, the through electrode 127 is arranged between the chip 103 and the chip 104 embedded in the embedding layer 117, and the through electrode 127 is connected to the bump electrode 137 used as an external terminal of the photodetection element 100. As a result, the through electrode 127 connected to the external terminal of the photodetection element 100 can be arranged not only in the periphery of the photodetection element 100 but also in the central portion thereof, and the restriction on the arrangement position of the through electrode 127 can be alleviated. For example, power can be supplied not only to the periphery of the photodetection element 100 but also to the chip 101 via the through electrode 127 in the central portion, and the IR drop caused by the wiring resistance of the chip 101 can be made uniform between the periphery and the central portion of the chip 101. Therefore, the potential difference of the power supply between the periphery and the central portion of the pixel array unit formed in the chip 101 can be reduced, and deterioration in image quality such as shading can be curbed.

In addition, in order to connect the through electrode 127 to the back surface wiring layer 146, the through electrode 127 is embedded in the embedding layer 117. As a result, it is not necessary to form the through electrode 127 in the chips 103 and 104, and it is possible to increase the occupied area of the semiconductor element formed on the chips 103 and 104.

In addition, by providing the back surface wiring layer 146 on the chip 102, it is possible to directly bond the chip 102 to the chip 101 via the wiring layer 141 on the front surface side of the chip 102 and directly bond the chip 102 to the chips 103 and 104 via the back surface wiring layer 146 on the back surface side of the chip 102. As a result, it is possible to form a laminated structure of three-layer chips without using solder bonding, and it is possible to increase the number of IOs of connection between chips while speeding up signal transmission between the chips.

In addition, by providing the through vias 126 and 136 penetrating the semiconductor layer 112 of the chip 102, the through electrode 127 can be electrically connected to the wiring layer 141 of the chip 101. Therefore, it is not necessary to use a bonding wire in order to extend the wiring 151 of the chip 101 to the outside of the photodetection element 100, it is not necessary to provide a bonding region in the chip 101, and delay of signal transmission via the bonding wire can be prevented.

In addition, the photodetection element 100 can be reinforced by bonding the transparent substrate 145 to the back surface side of the chip 101. Therefore, it is possible to reduce the thickness of each of the chips 101 to 104 while avoiding difficulty in handling the photodetection element 100, to improve the efficiency of interlayer connection, and to increase the speed of signal transmission by reducing the parasitic capacitance.

Note that in the first embodiment described above, the laminated structure in which the chip 101 on which the solid-state imaging element is formed is arranged on the uppermost layer is taken as an example, but the chip 101 on which the solid-state imaging element is formed may be omitted. In addition, the direct bonding based on Cu—Cu bonding is taken as an example of the bonding of the chips 101 to 104, but solder bonding may be used, or direct bonding and solder bonding may be combined.

### 2. Second Embodiment

In the first embodiment described above, the through electrode 127 penetrates the embedding layer 117 and is connected to the back surface wiring layer 146 of the chip 102. In a first example of a second embodiment, a through electrode penetrates an embedding layer 117 and a chip 102 and is connected to a wiring layer 141 of a chip 101.

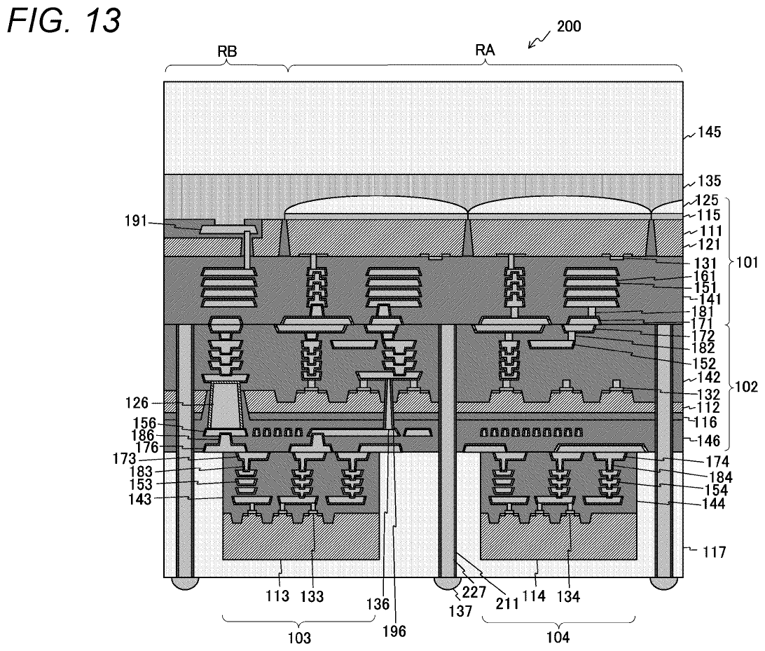

FIG. 13 is a cross-sectional view illustrating the first example of the configuration of the photodetection element according to the second embodiment.

In FIG. 13, a photodetection element 200 includes a through electrode 227 instead of the through electrode 127 of the first embodiment described above. In addition, in the photodetection element 200, an insulating film 211 is added to the photodetection element 100 of the first embodiment described above. Other configurations of the photodetection element 200 of the second embodiment are similar to the configurations of the photodetection element 100 of the first embodiment described above.

The through electrode 227 penetrates the embedding layer 117, a back surface wiring layer 146, a protective film 116, a semiconductor layer 112, and a wiring layer 142, and is connected to the wiring layer 141. At this time, the through electrode 227 may be connected to a Cu wiring formed in the wiring layer 141 or may be connected to an Al pad electrode. Other configurations of the through electrode 227 are similar to the configurations of the through electrode 127 of the first embodiment described above.

The insulating film 211 is formed so as to surround the outer periphery of the through electrode 227. The insulating film 211 can insulate the through electrode 227 from the semiconductor layer 112. As the material of the insulating film 211, for example, SiO₂, SiN, or the like can be used.

As described above, in the first example of the second embodiment described above, the through electrode 227 connected to a bump electrode 137 is extended to the position of the wiring layer 141 and connected to the wiring layer 141. As a result, it is not necessary to cause the wiring 151 of the chip 101 to pass through the wiring 152 and the back surface wiring 156 of the chip 102 in order to extend the wiring 151 of the chip 101 to the outside of the photodetection element 200, and it is possible to increase the speed of signal transmission to and from the chip 101.

In the first example of the second embodiment described above, the through electrode 227 penetrates the embedding layer 117 and the chip 102 and is connected to the wiring layer 141 of the chip 101. In a second example of the second embodiment, through electrodes penetrate an embedding layer 117 and chips 103 and 104, and are connected to wiring layers 143 and 144 of the chips 103 and 104, respectively.

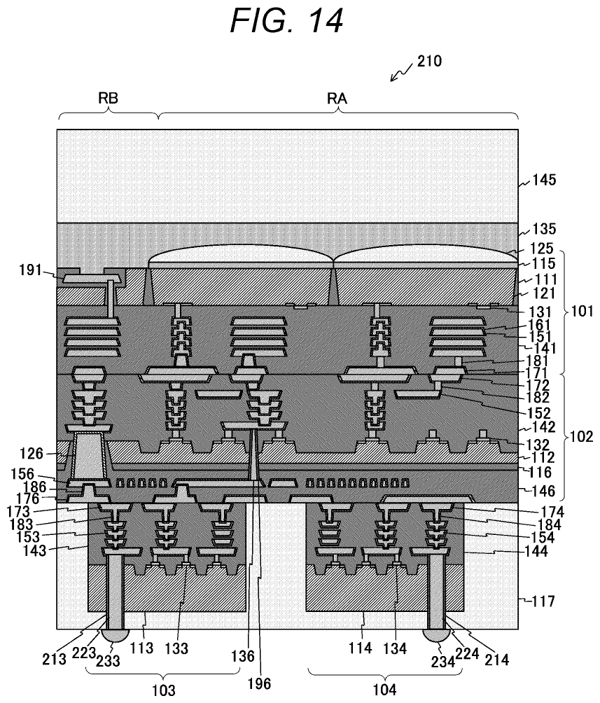

FIG. 14 is a cross-sectional view illustrating the second example of the configuration of the photodetection element according to the second embodiment.

In FIG. 14, a photodetection element 210 includes through electrodes 223 and 224 and bump electrodes 233 and 234 instead of the through electrode 127 and the bump electrode 137 of the first embodiment described above. In addition, in the photodetection element 210, insulating films 213 and 214 are added to the photodetection element 100 of the first embodiment described above. Other configurations of the photodetection element 210 of the second embodiment are similar to the configurations of the photodetection element 100 of the first embodiment described above.

Each of the through electrodes 223 and 224 penetrates the embedding layer 117 and each of semiconductor layers 113 and 114, and is connected to the wiring layers 143 and 144, respectively. At this time, the through electrode 223 may be connected to a Cu wiring formed in the wiring layer 143 or may be connected to an Al pad electrode. In addition, the through electrode 224 may be connected to a Cu wiring formed in the wiring layer 144 or may be connected to an Al pad electrode. Other configurations of the through electrodes 223 and 224 are similar to the configurations of the through electrode 127 of the first embodiment described above.

Insulating films 213 and 214 are formed so as to surround the outer peripheries of the through electrodes 223 and 224. Each of the insulating films 213 and 214 can insulate each of the through electrodes 223 and 224 from the semiconductor layers 113 and 114. As the material of each of the insulating films 213 and 214, for example, SiO₂, SiN, or the like can be used.

Note that through electrodes having different lengths may be formed in the photodetection element. For example, the through electrode 127 in FIG. 1 and the through electrode 227 in FIG. 13 may be formed in one photodetection element, or the through electrode 127 in FIG. 1 and the through electrodes 223 and 224 in FIG. 14 may be formed in one photodetection element. In addition, the through electrode 227 of FIG. 13 and the through electrodes 223 and 224 of FIG. 14 may be formed in one photodetection element, or the through electrode 127 of FIG. 1, the through electrode 227 of FIG. 13, and the through electrodes 223 and 224 of FIG. 14 may be formed in one photodetection element.

As described above, in the second example of the second embodiment described above, the through electrodes 223 and 224 are formed so as to penetrate the semiconductor layers 113 and 114. As a result, it is not necessary to cause the wirings 153 and 154 of the chips 103 and 104 to pass through the back surface wiring layer 146 of the chip 102 in order to extend the wirings 153 and 154 of the chips 103 and 104 to the outside of the photodetection element 210, and it is possible to increase the speed of signal transmission between the chips 103 and 104.

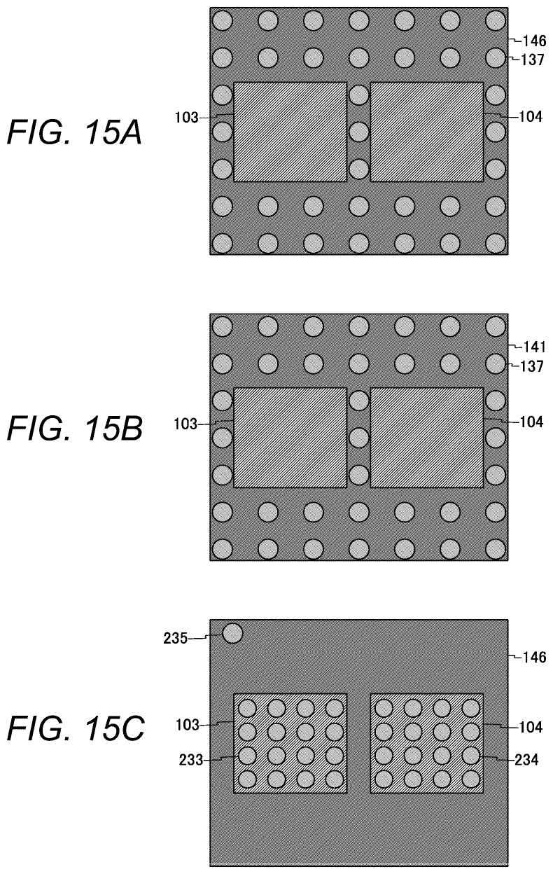

FIG. 15 is a plan view illustrating arrangement examples of external terminals of the photodetection element according to the second embodiment. Note that a in FIG. 15 can be applied to the arrangement of the external terminals of the photodetection element 100 of FIG. 1 or the photodetection element 110 of FIG. 2. In FIG. 15, b can be applied to the arrangement of the external terminals of the photodetection element 200 of FIG. 13. In FIG. 15, c can be applied to the arrangement of the external terminals of the photodetection element 210 of FIG. 14.

In a of FIG. 15, in each of the photodetection elements 100 and 110, the bump electrode 137 is connected to the back surface wiring layer 146 via the through electrode 127. At this time, the bump electrode 137 can be arranged at a position other than the mounting region of each of the chips 103 and 104. The bump electrodes 137 may be arranged in a lattice shape at positions other than the mounting region of each of the chips 103 and 104.

In b of FIG. 15, in the photodetection element 200, the bump electrode 137 is connected to the wiring layer 141 via the through electrode 227. At this time, the bump electrode 137 can be arranged at a position other than the mounting region of each of the chips 103 and 104. The bump electrodes 137 may be arranged in a lattice shape at positions other than the mounting region of each of the chips 103 and 104.

In c of FIG. 15, in the photodetection element 210, the bump electrodes 233 and 234 are connected to the wiring layers 143 and 144 via the through electrodes 223 and 224, respectively. At this time, the bump electrodes 233 and 234 can be arranged on the mounting region of the chips 103 and 104. The bump electrodes 233 and 234 may be arranged in a lattice pattern.

### 3. Third Embodiment

In the first embodiment described above, the bump electrode 137 is arranged so as to be connected to the extended position of the through electrode 127. In a third embodiment, a redistribution line connected to an extended position of a through electrode is provided on an embedding layer, and a bump electrode is connected to the through electrode via the redistribution line.

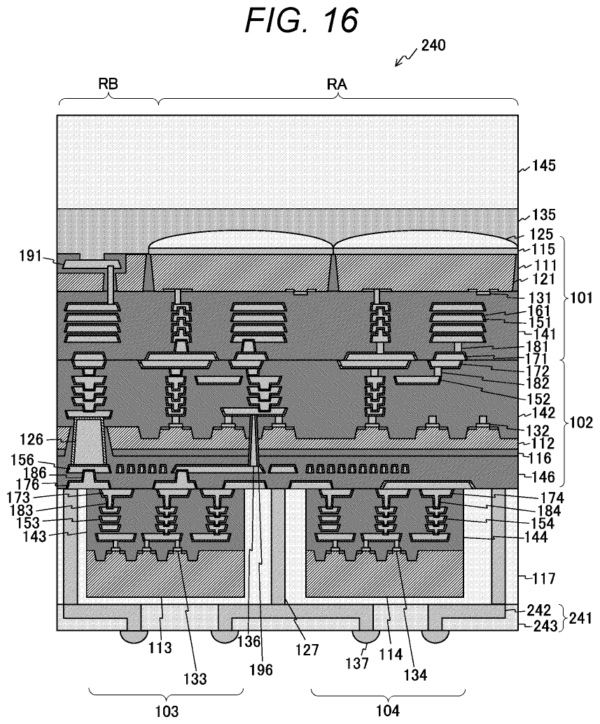

FIG. 16 is a cross-sectional view illustrating a first example of a configuration of a photodetection element according to the third embodiment.

In FIG. 16, in a photodetection element 240, a redistribution layer 241 is added to the photodetection element 100 of the first embodiment described above. Other configurations of the photodetection element 240 of the first example of the third embodiment are similar to the configurations of the photodetection element 100 of the first embodiment described above.

The redistribution layer 241 is formed on an embedding layer 117. The redistribution layer 241 includes a redistribution line 242 and an insulating layer 243. The redistribution line 242 is embedded in the insulating layer 243. A bump electrode 137 is formed on the redistribution layer 241. A through electrode 127 is connected to the bump electrode 137 via the redistribution line 242.

As the material of the redistribution line 242, for example, SiO₂, SiN, or SiCN can be used. As the material of the insulating layer 243, for example, a metal such as Al, Cu, AlCu, AlSiCu, or Co can be used.

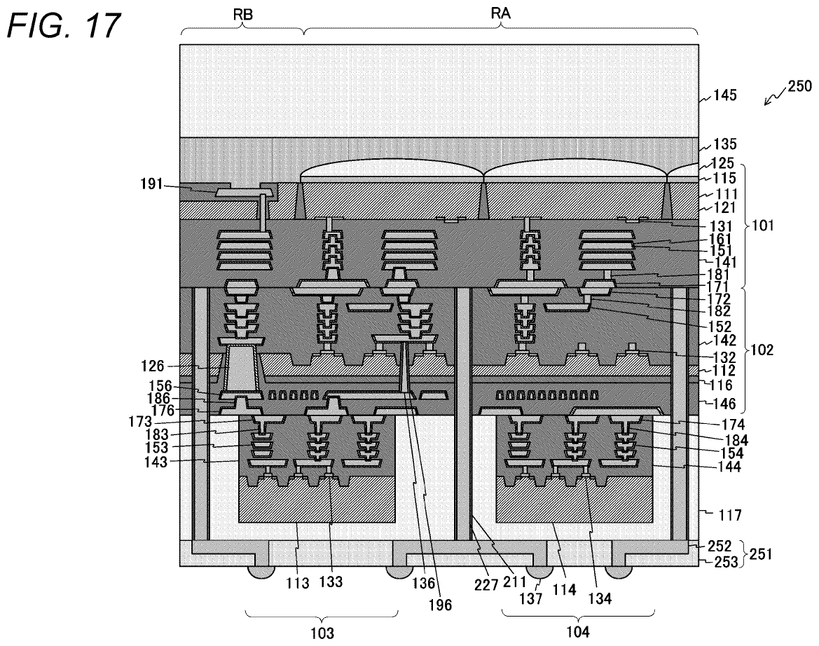

FIG. 17 is a cross-sectional view illustrating a second example of the configuration of the photodetection element according to the third embodiment.

In FIG. 17, in a photodetection element 250, a redistribution layer 251 is added to the photodetection element 200 of the first example of the second embodiment described above. Other configurations of the photodetection element 250 of the second example of the third embodiment are similar to the configurations of the photodetection element 200 of the first example of the second embodiment described above.

The redistribution layer 251 is formed on an embedding layer 117. The redistribution layer 251 includes a redistribution line 252 and an insulating layer 253. The redistribution line 252 is embedded in the insulating layer 253. A bump electrode 137 is formed on the redistribution layer 251. A through electrode 227 is connected to the bump electrode 137 via the redistribution line 252. Other configurations of the redistribution layer 251 are similar to the configurations of the redistribution layer 241 of the third embodiment described above.

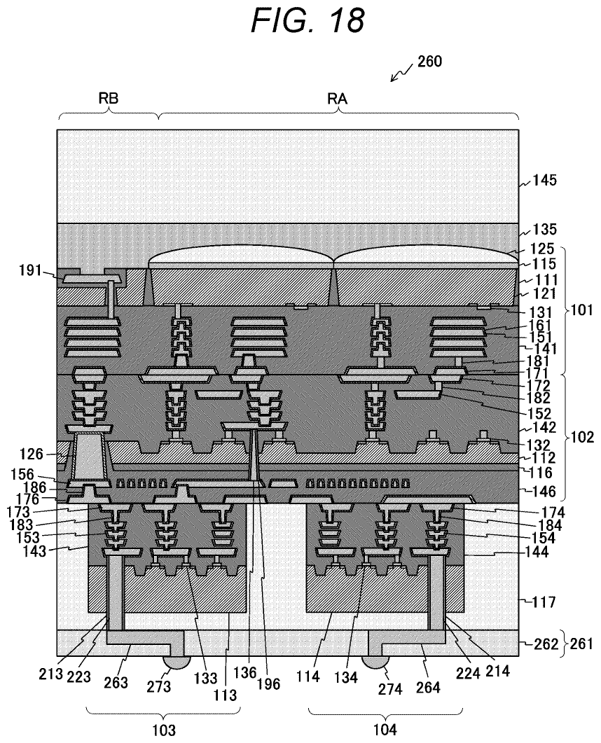

FIG. 18 is a cross-sectional view illustrating a third example of the configuration of the photodetection element according to the third embodiment.

In FIG. 18, in a photodetection element 260, a redistribution layer 261 is added to the photodetection element 210 of the second example of the second embodiment described above. Other configurations of the photodetection element 260 of the third example of the third embodiment are similar to the configurations of the photodetection element 210 of the second example of the second embodiment described above.

The redistribution layer 261 is formed on an embedding layer 117. The redistribution layer 261 includes redistribution lines 263 and 264 and an insulating layer 262. Each of the redistribution lines 263 and 264 is embedded in the insulating layer 262. Bump electrodes 273 and 274 are formed on the redistribution layer 261. Each of through electrodes 223 and 224 is connected to the bump electrodes 273 and 274 via each of the redistribution lines 263 and 264, respectively. Other configurations of the redistribution layer 261 are similar to the configurations of the redistribution layer 241 of the third embodiment described above.

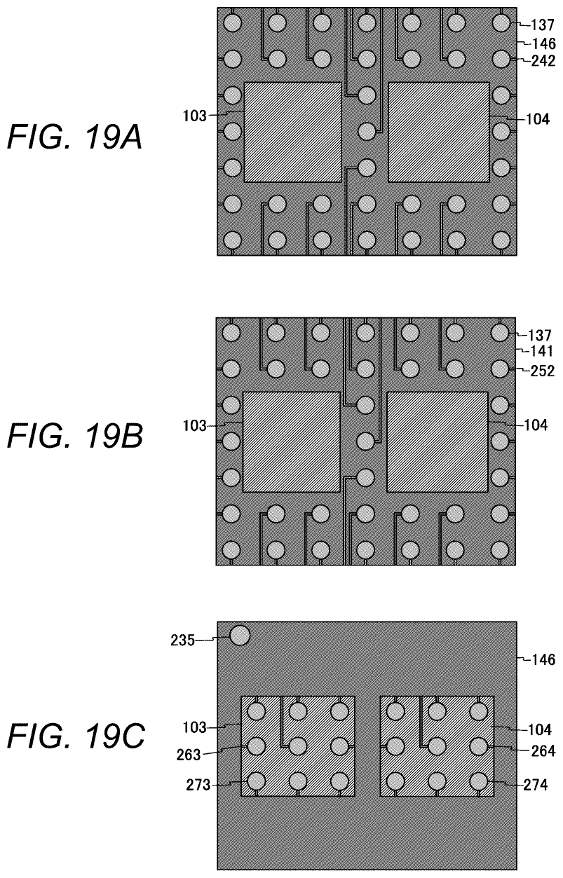

FIG. 19 is a plan view illustrating arrangement examples of external terminals and redistribution lines of the photodetection element according to the third embodiment. Note that the arrangement example of a in FIG. 19 may be applied to the arrangement of the external terminal and the redistribution line of the photodetection element 240 in FIG. 16. The arrangement example of b in FIG. 19 may be applied to the arrangement of the external terminal and the redistribution line of the photodetection element 250 in FIG. 17. The arrangement example of c in FIG. 19 may be applied to the arrangement of the external terminal and the redistribution line of the photodetection element 260 in FIG. 18.

In a of FIG. 19, in the photodetection element 240, the bump electrode 137 is connected to a back surface wiring layer 146 via the redistribution line 242 and the through electrode 127. At this time, the redistribution line 242 and the bump electrode 137 can be arranged at positions other than the mounting region of each of the chips 103 and 104.

In b of FIG. 19, in the photodetection element 250, the bump electrode 137 is connected to a wiring layer 141 via the redistribution line 252 and the through electrode 227. At this time, the redistribution line 252 and the bump electrode 137 can be arranged at positions other than the mounting region of each of the chips 103 and 104.

In c of FIG. 19, in the photodetection element 260, the bump electrodes 273 and 274 are connected to wiring layers 143 and 144 via the redistribution lines 263 and 264 and the through electrodes 223 and 224, respectively. At this time, the redistribution line 263 and the bump electrode 273 can be arranged on the mounting region of the chip 103, and the redistribution line 264 and the bump electrode 274 can be arranged on the mounting region of the chip 104. Note that a dummy external terminal 235 may be formed on the redistribution layer 261.

As described above, in the third embodiment described above, the redistribution line connected to the extended position of the through electrode is provided on the embedding layer, and the bump electrode is connected to the through electrode via the redistribution line. As a result, the arrangement position of the through electrode can be set without being restricted by the arrangement position of the bump electrode, and the restriction of the arrangement position of the through electrode can be alleviated.

### 4. Fourth Embodiment

In the first embodiment described above, the transparent substrate 145 is bonded to the back surface side of the chip 101 in order to reinforce the photodetection element 100. In a fourth embodiment, in order to reinforce a photodetection element, a support substrate is bonded onto an embedding layer 117, and a through electrode is extended to the outside of the photodetection element by penetrating the embedding layer 117 and the support substrate.

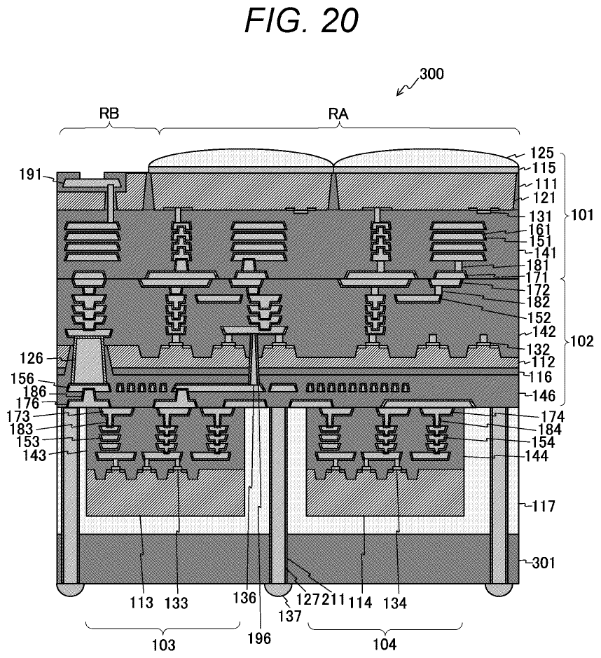

FIG. 20 is a cross-sectional view illustrating a first example of a configuration of a photodetection element according to the fourth embodiment.

In FIG. 20, in a photodetection element 300, a support substrate 301 is added to the photodetection element 100 of the first embodiment described above. Other configurations of the photodetection element 300 of the first example of the fourth embodiment are similar to the configurations of the photodetection element 100 of the first embodiment described above.

The support substrate 301 is formed on an embedding layer 117. The support substrate 301 may be bonded to the embedding layer 117 via an adhesive layer, or may be bonded to the embedding layer 117 on the basis of oxide film bonding. The support substrate 301 may be a Si substrate, a ceramic substrate, or a resin substrate. A bump electrode 137 is formed on the support substrate 301. A through electrode 127 penetrates the support substrate 301 and an embedding layer 117 and is connected to a back surface wiring layer 146. An insulating film 211 is formed so as to surround the outer periphery of the through electrode 127.

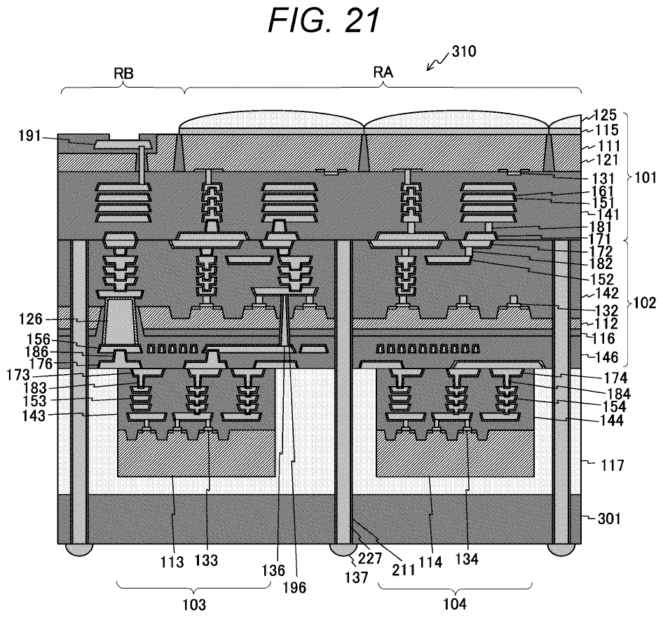

FIG. 21 is a cross-sectional view illustrating a second example of the configuration of the photodetection element according to the fourth embodiment.

In FIG. 21, in a photodetection element 310, a support substrate 301 is added to the photodetection element 200 of the second embodiment described above. Other configurations of the photodetection element 310 of the second example of the fourth embodiment are similar to the configurations of the photodetection element 200 of the second embodiment described above.

The support substrate 301 is formed on an embedding layer 117. A bump electrode 137 is formed on the support substrate 301. The through electrode 227 penetrates the embedding layer 117, a back surface wiring layer 146, a protective film 116, a semiconductor layer 112, and a wiring layer 142, and is connected to the wiring layer 141. The insulating film 211 is formed so as to surround the outer periphery of the through electrode 227.

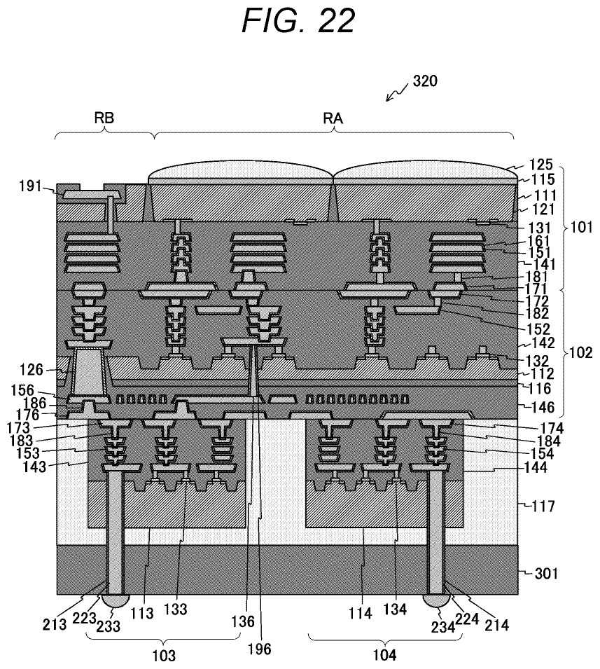

FIG. 22 is a cross-sectional view illustrating a third example of the configuration of the photodetection element according to the fourth embodiment.

In FIG. 22, in a photodetection element 320, a support substrate 301 is added to the photodetection element 210 of the second embodiment described above. Other configurations of the photodetection element 320 of the third example of the fourth embodiment are similar to the configurations of the photodetection element 210 of the second embodiment described above.

The support substrate 301 is formed on an embedding layer 117. Bump electrodes 233 and 234 are formed on the support substrate 301. Each of the through electrodes 223 and 224 penetrates the embedding layer 117 and each of semiconductor layers 113 and 114, and is connected to the wiring layers 143 and 144, respectively. Insulating films 213 and 214 are formed so as to surround the outer peripheries of the through electrodes 223 and 224.

As described above, in the fourth embodiment described above, the support substrate 301 is bonded onto the embedding layer 117, and the through electrode is extended to the outside of the photodetection element by penetrating the embedding layer 117 and the support substrate 301. Accordingly, the photodetection element can be electrically connected to the outside without using wire bonding, and the photodetection element can be reinforced.

Note that the redistribution layer 241 in FIG. 16 may be formed on the support substrate 301 of the photodetection element 300, the redistribution layer 251 in FIG. 17 may be formed on the support substrate 301 of the photodetection element 310, or the redistribution layer 261 in FIG. 18 may be formed on the support substrate 301 of the photodetection element 320.

### 5. Fifth Embodiment

In the first embodiment described above, the chip 102 is mounted face up in the photodetection element 100. In a fifth embodiment, a chip 102 is mounted face down in a photodetection element.

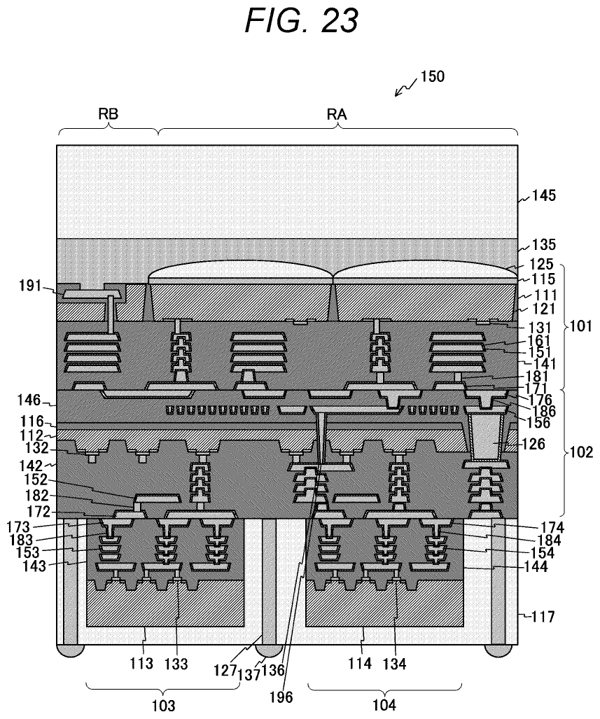

FIG. 23 is a cross-sectional view illustrating a configuration example of a photodetection element according to the fifth embodiment.

In FIG. 23, a photodetection element 150 includes chips 101 to 104 similarly to the photodetection element 100 of the first embodiment described above. Note, however, that in the photodetection element 100 of the first embodiment described above, the chip 102 is mounted face up, but in the photodetection element 150 of the fifth embodiment, the chip 102 is mounted face down.

Here, a back surface wiring layer 146 of the chip 102 is directly bonded to a wiring layer 141 of the chip 101. At this time, a pad electrode 176 of the back surface wiring layer 146 can be bonded to a pad electrode 171 of the wiring layer 141 by Cu—Cu bonding. In addition, a wiring layer 142 of the chip 102 is directly bonded to wiring layers 143 and 144 of the chips 103 and 104. At this time, a pad electrode 172 of the wiring layer 142 can be Cu—Cu bonded to a pad electrode 173 of the wiring layer 143 and Cu—Cu bonded to a pad electrode 174 of the wiring layer 144.

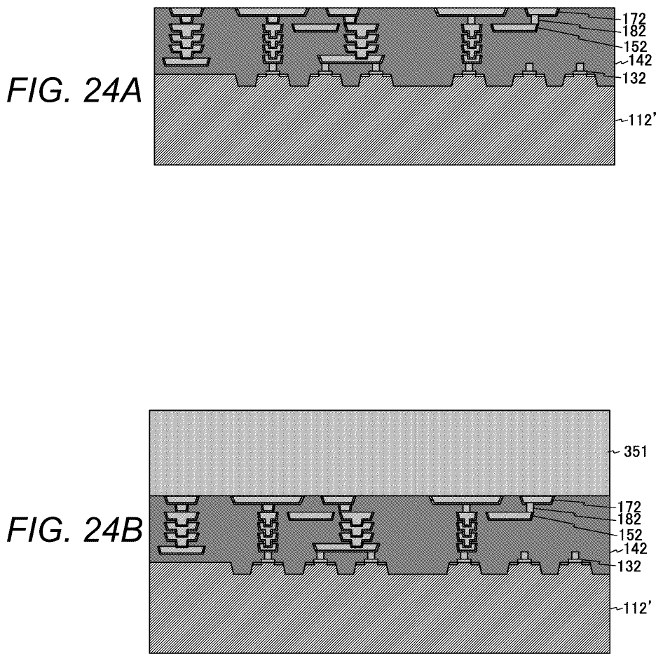

FIGS. 24 to 27 are cross-sectional views illustrating an example of a method of manufacturing the photodetection element according to the fifth embodiment.

In a of FIG. 24, a semiconductor element such as a transistor 132 is formed on a semiconductor wafer 112′ for each section into which the chip 102 is cut out. Next, the wiring layer 142 provided with the wiring 152, the pad electrode 172, and the via 182 is formed on the semiconductor wafer 112′.

Next, as illustrated in b of FIG. 24, a temporary substrate 351 is bonded onto the wiring layer 142. The planar size and shape of the temporary substrate 351 can be equal to the planar size and shape of the semiconductor wafer 112′. The thickness of the temporary substrate 351 can be set within a range of 300 μm to 800 μm. In the bonding of the temporary substrate 351, an adhesive may be used. The heat-resistant temperature of the adhesive is preferably within a range of 200° C. to 500° C. in consideration of the formation of an insulating layer in a later step and the annealing temperature of the Cu—Cu bonding. In addition, when the semiconductor wafer 112′ is thinned from the back surface side in the next step, the thickness thereof is made uniform, so that it is possible to curb variations in the thickness of the adhesive.

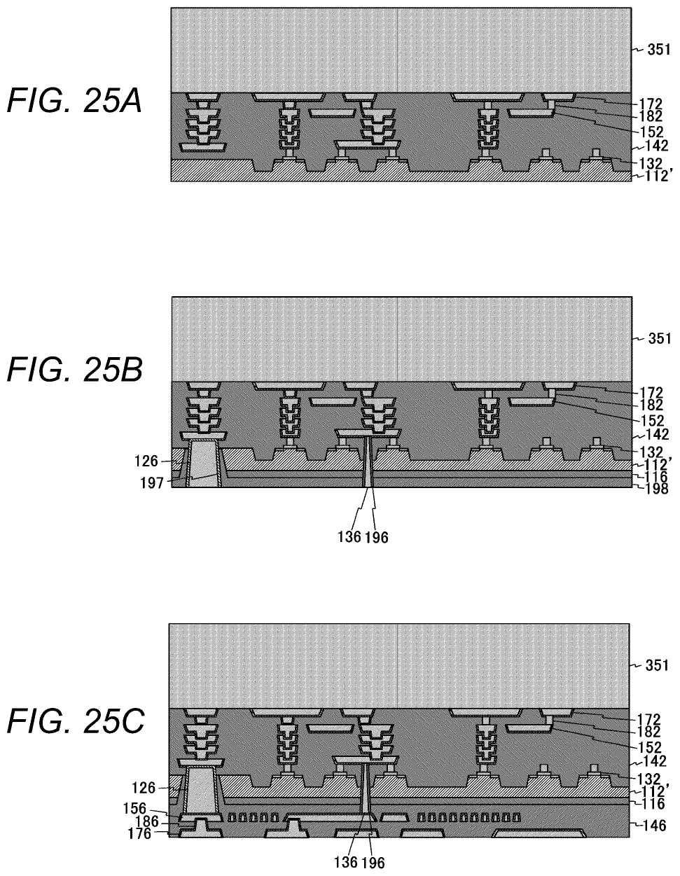

Next, as illustrated in a of FIG. 25, the semiconductor wafer 112′ is thinned from the back surface side. In thinning the semiconductor wafer 112′, a grinder, CMP, or etch back may be used. At this time, the thickness of the semiconductor wafer 112′ can be set within a range of 1 μm to 20 μm.

Next, as illustrated in b of FIG. 25, a protective film 116 is formed on the back surface side of the semiconductor wafer 112′. Next, a through hole 197 is formed in a semiconductor layer 112, and an insulating layer 198 is formed on the protective film 116 so as to be embedded in the through hole 197. Next, the insulating film at the connection position of each of the through vias 126 and 136 is removed, and each of the through vias 126 and 136 is embedded so as to be electrically connected to the wiring 152. At this time, the periphery of the through via 126 can be covered with the insulating layer 198 in order to insulate the through via 126 from the semiconductor wafer 112′. Additionally, the insulating layer 196 may be formed around the through via 136 to insulate the through via 136 from the semiconductor wafer 112′.

Next, as illustrated in c of FIG. 25, the back surface wiring layer 146 provided with a back surface wiring 156, the pad electrode 176, and a via 186 is formed on the protective film 116. At this time, the through vias 126 and 136 can be electrically connected to the back surface wiring 156. In addition, the front surface of the back surface wiring layer 146 can be planarized by a method such as CMP so that the pad electrode 176 is exposed. The planar size of the pad electrode 176 can be set within a range of 0.1×0.1 μm to 10×10 μm.

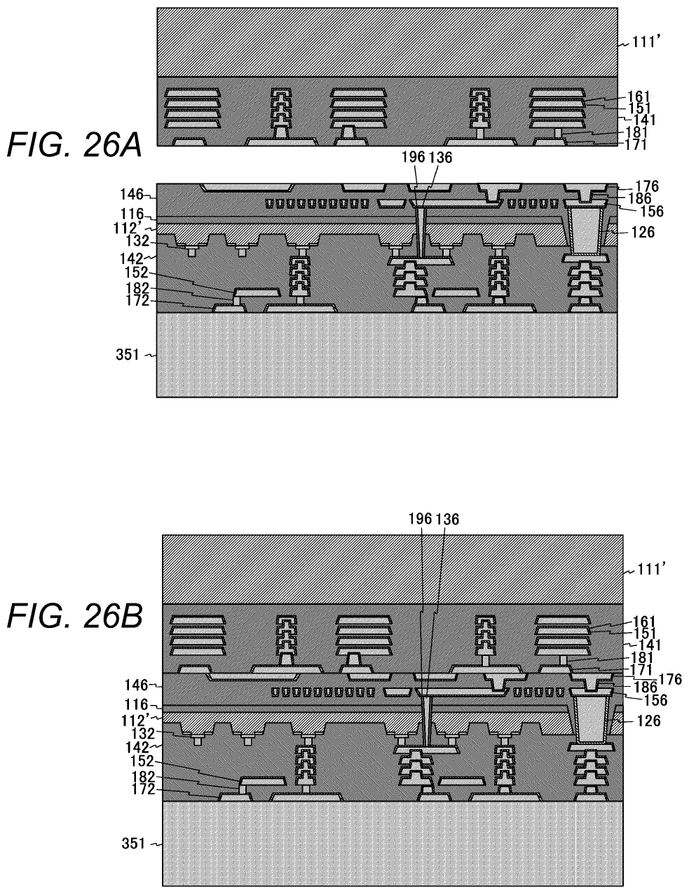

Next, as illustrated in a of FIG. 26, a semiconductor wafer 111′ in which a pixel array unit and peripheral circuits are formed for each section into which the chip 101 is cut out is prepared. On the semiconductor wafer 111′, the wiring layer 141 is formed in which a wiring 151, the pad electrode 171, and a via 181 are provided.

Next, as illustrated in b of FIG. 26, the wiring layer 141 and the back surface wiring layer 146 are directly bonded so that the wiring layer 141 and the back surface wiring layer 146 face each other. At this time, the pad electrode 171 of the wiring layer 141 and the pad electrode 176 of the back surface wiring layer 146 may be Cu—Cu bonded. In order to improve the bonding strength, the surfaces of the wiring layer 141 and the back surface wiring layer 146 may be subjected to plasma treatment or wet treatment. In order to obtain sufficient bonding strength and good contact of the Cu bonding portion, the laminated wafer on which the semiconductor wafers 111′ and 112′ are laminated may be heat treated at 200 degrees to 400 degrees.

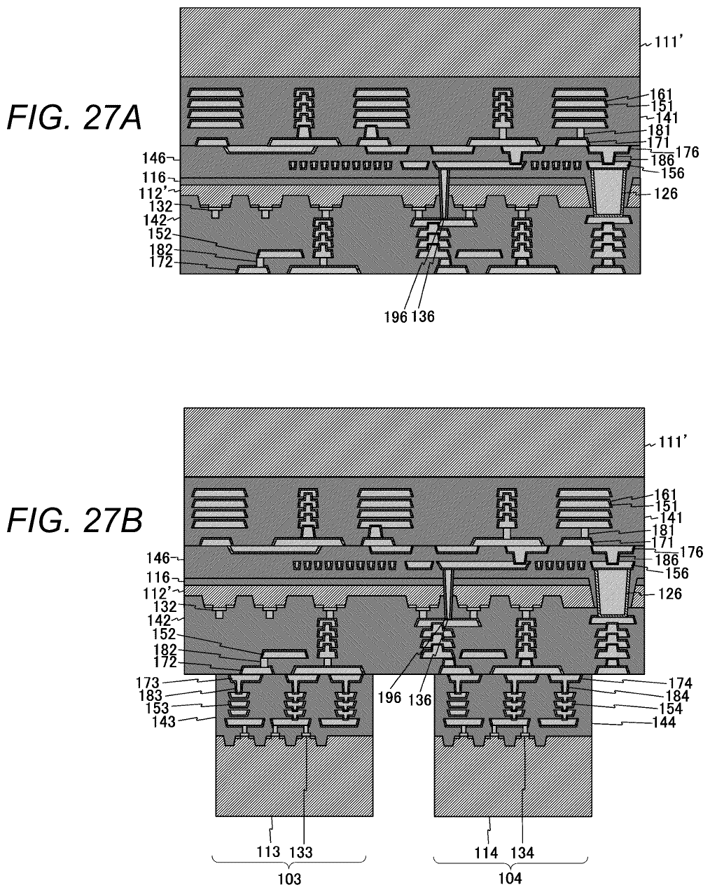

Next, as illustrated in a of FIG. 27, the temporary substrate 351 on the wiring layer 142 is peeled off. As the method for peeling the temporary substrate 351, in a case where the temporary substrate 351 is a resin, a chemical solution for dissolving the temporary substrate 351 may be used, the temporary substrate 351 may be mechanically scraped, or the adhesiveness of the peeling surface may be reduced on the basis of ultraviolet irradiation. In the case of oxide film peeling, Si may be cut with a grinder, Si may be dissolved by wet treatment, or a combination thereof may be used.

Next, as illustrated in b of FIG. 27, singulated chips 103 and 104 are prepared. Then, the wiring layers 143 and 144 are directly bonded to the wiring layer 142 such that the wiring layers 143 and 144 face the wiring layer 142. At this time, the pad electrode 173 of the wiring layer 143 and the pad electrode 174 of the wiring layer 144 may be Cu—Cu bonded to the pad electrode 172 of the wiring layer 142. In order to improve the bonding strength, the surfaces of the wiring layers 143 and 144 and the wiring layer 142 may be subjected to plasma treatment or wet treatment. In order to obtain sufficient bonding strength and good contact of the Cu bonding portion, the laminated structure in which the chips 103 and 104 are laminated on the laminated wafer in which the semiconductor wafers 111′ and 112′ are laminated may be heat treated at 200 degrees to 400 degrees. Each chip 103 and 104 can be arranged side by side on the laminated wafer in which the semiconductor wafers 111′ and 112′ are bonded to each other, for each section into which the chip 101 is cut out.

Next, after the step b of FIG. 6 and the steps in FIGS. 7 to 12 are performed, the photodetection element 150 in FIG. 23 is formed.

As described above, in the fifth embodiment described above, the chip 102 is mounted face down in the photodetection element 150. As a result, each of the chips 103 and 104 can transmit signals to and from the chip 102 without interposing the through vias 126 and 136, and the signal transmission to and from the chip 102 can be speeded up.

Note that the configuration in which the chip 102 is mounted face down in the photodetection element 150 may be applied to the photodetection elements 200 and 210 of the second embodiment described above, or may be applied to the photodetection elements 240, 250, and 260 of the third embodiment described above. In addition, the configuration in which the chip 102 is mounted face down in the photodetection element 150 may be applied to the photodetection elements 300, 310, and 320 of the fourth embodiment described above.

### 6. Sixth Embodiment

In the first embodiment described above, the through electrode 127 that penetrates the embedding layer 117 in which the chips 103 and 104 are embedded and is extended to the outside of the photodetection element 100 is connected to the back surface wiring layer 146 of the chip 102. In a sixth embodiment, a through electrode extended to the outside via an embedding layer in which a lower layer chip mounted face down on an upper layer chip is embedded is electrically connected to the lower layer chip via a back surface wiring of the upper layer chip.

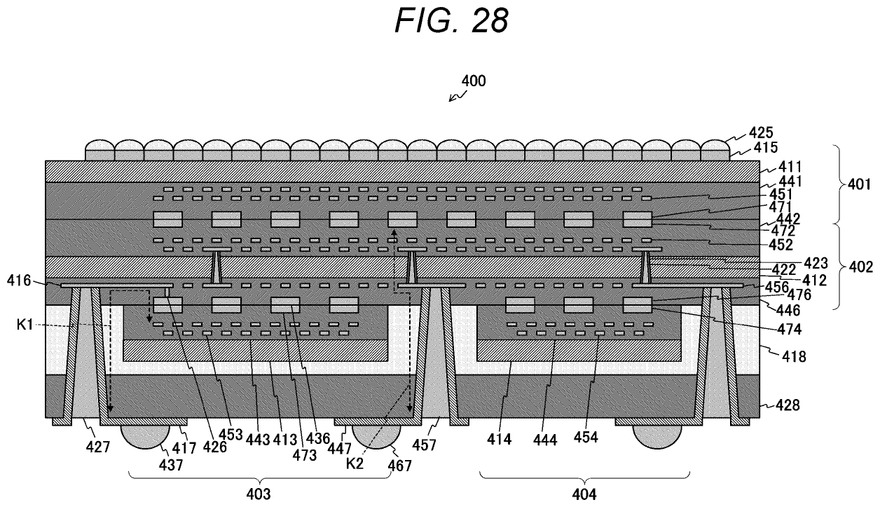

FIG. 28 is a cross-sectional view illustrating a configuration example of a photodetection element according to the sixth embodiment;

In FIG. 28, a photodetection element 400 includes chips 401 to 404. Each of the chips 401 to 404 may be a semiconductor chip or may include an optical chip. At this time, the optical chip can be used as an uppermost chip provided in the photodetection element 400.

An optical element is formed on the optical chip. The optical element may be a solid-state imaging element such as a CCD or a CMOS. The light received by the solid-state imaging element may be visible light, or may be near-infrared light, short-wave infrared light, ultraviolet light, X-ray, or the like. The optical element may be a light receiving element such as a PD, or may be a light emitting element such as an LD, an LED, or a VCSEL. The optical element may be a MEMS element such as an optical switch or a mirror device. The material used for the base material of the optical chip may be a semiconductor such as Si, GaAS, or InGaAsP, or may be a dielectric such as LiNbO₃, glass, or a transparent resin.

A semiconductor element is formed on the semiconductor chip. The semiconductor element may include a transistor, a resistor, a capacitor, and the like. In the semiconductor chip, a memory may be formed, a processor may be formed, a signal processing circuit may be formed, a data processing circuit may be formed, an interface circuit may be formed, or an optical element may be formed. In the semiconductor chip, for example, a hardware circuit such as FPGA or ASIC may be formed. The material used for the base material of the semiconductor chip may be Si, GaAS, SiC, GaN, InGaAsP, or the like.

In the following description, a case where a back-illuminated solid-state imaging element is formed on the chip 401 and a semiconductor element is formed on each of the chips 402 to 404 is taken as an example. At this time, a logic circuit or a semiconductor storage device may be formed in each of the chips 402 to 404. The semiconductor storage device may include a ROM, a DRAM, or a NAND flash memory.

The chip 401 includes a semiconductor layer 411 and a wiring layer 441. The chip 401 is provided with a pixel array unit in which pixels are arranged in a matrix along the row direction and the column direction. Each pixel is provided with a photodiode and a pixel transistor.

The wiring layer 441 is formed on the front surface side of the semiconductor layer 411. At this time, the photodiode can be arranged on the back surface side of the semiconductor layer 411. The wiring layer 441 is provided with a wiring 451 embedded in the insulating layer, and a pad electrode 471. The pad electrode 471 can be used for direct bonding of the chip 401.

On the back surface side of the semiconductor layer 411, a color filter 415 is formed for each of the pixels. An on-chip lens 425 is formed on the color filter 415 for each of the pixels. Note that the chip 401 is an example of a sensor chip described in the claims.

The chip 402 is laminated on the chip 401. The planar size and shape of the chip 402 can be equal to those of the chip 401. The chip 402 includes a semiconductor layer 412, a wiring layer 442, and a back surface wiring layer 446. Note that the wiring layer 442 is an example of a front surface wiring layer described in the claims.

The wiring layer 442 is formed on the front surface side of the semiconductor layer 412. The wiring layer 442 is provided with a wiring 452 embedded in the insulating layer, and a pad electrode 472. The pad electrode 472 can be used for direct bonding of the front surface side of the chip 402. For example, hybrid bonding may be used to directly bond the chip 401 to the chip 402.

The back surface wiring layer 446 is formed on the back surface side of the semiconductor layer 412. The back surface wiring layer 446 is provided with a back surface wiring 456 embedded in the insulating layer, and a pad electrode 476. The pad electrode 476 can be used for direct bonding of the back surface side of the chip 402.

A through via 422 is embedded in the semiconductor layer 412. The through via 422 penetrates the semiconductor layer 412 of the chip 402 and can establish conduction between the wiring layer 442 and the back surface wiring layer 446. In order to insulate the through via 422 from the semiconductor layer 412, an insulating layer 423 may be formed around the through via 422.

The chip 403 is laminated on the back surface wiring layer 446 of the chip 402. Here, the chip 403 can be mounted face down on the back surface wiring layer 446 of the chip 402. The planar size of the chip 403 can be made smaller than that of the chip 401. The chip 403 includes a semiconductor layer 413 and a wiring layer 443.

The wiring layer 443 is formed on the front surface side of the semiconductor layer 413. The wiring layer 443 is provided with a wiring 453 embedded in the insulating layer, and a pad electrode 473. The pad electrode 473 can be used for direct bonding of the front surface side of the chip 403. For example, the chip 403 may be directly bonded to the chip 402 by hybrid bonding.

The chip 404 is laminated on the back surface wiring layer 446 of the chip 402. Here, the chip 404 can be mounted face down on the back surface wiring layer 446 of the chip 402. At this time, the chip 404 is arranged on the back surface wiring layer 446 side by side at an interval from the chip 403. The planar size of the chip 404 can be made smaller than that of the chip 401. The chip 404 includes a semiconductor layer 414 and a wiring layer 444.

The wiring layer 444 is formed on the front surface side of the semiconductor layer 414. The wiring layer 444 is provided with a wiring 454 embedded in the insulating layer, and a pad electrode 474. The pad electrode 474 can be used for direct bonding of the front surface side of the chip 404. For example, the chip 404 may be directly bonded to the chip 402 by hybrid bonding.

Further, on the back surface wiring layer 446, an embedding layer 418 is laminated so that the chips 403 and 404 are embedded therein. The front surface of the embedding layer 418 may be planarized. A support substrate 428 is formed on the embedding layer 418. The support substrate 428 may adhere to the embedding layer 418 via an adhesive layer. Through electrodes 427 and 457 are embedded in the embedding layer 418 and the support substrate 428.

The through electrode 427 penetrates the embedding layer 418 and the support substrate 428, is electrically connected to the wiring layer 443 via the back surface wiring layer 446, and is extended to the front surface of the support substrate 428. At this time, the through electrode 427 can be located on a conduction path K1 that establishes conduction between the external terminal of the photodetection element 400 and the wiring layer 443. Here, a via 426 may be formed in the back surface wiring layer 446, and the through electrode 427 may be electrically connected to the wiring layer 443 via a back surface wiring 416, the via 426, and a pad electrode 436.

The through electrode 457 penetrates the embedding layer 418 and the support substrate 428, is electrically connected to the wiring layer 442 via the back surface wiring layer 446, and is extended to the front surface of the support substrate 428. At this time, the through electrode 457 can be located on a conduction path K2 that establishes conduction between the external terminal of the photodetection element 400 and the wiring layer 442. Here, the wiring layers 443 and 444 can be prevented from being interposed on the conduction path K2.

Wirings 417 and 447 are formed on the support substrate 428. The wiring 417 is connected to the through electrode 427, and the wiring 447 is connected to the through electrode 457. At this time, the wiring 417 may penetrate the embedding layer 418 and the support substrate 428 so as to be in contact with the outer periphery of the through electrode 427, and the wiring 447 may penetrate the embedding layer 418 and the support substrate 428 so as to be in contact with the outer periphery of the through electrode 457. A bump electrode 437 is formed on the wiring 417, and a bump electrode 467 is formed on the wiring 447. Each of the bump electrodes 437 and 467 can be used as an external terminal for electrically connecting the photodetection element 400 to the outside. Note that each of the bump electrodes 437 and 467 may be a solder ball or a pillar electrode.

Here, the photodetection element 400 can be divided into individual photodetection elements 400 from a state in which the plurality of photodetection elements 400 is integrated in a wafer shape. In this singulation, for example, the photodetection element 400 integrated in a wafer shape may be cut along a dicing line partitioning the photodetection element 400. At this time, the position of the cut surface of the embedding layer 418, the position of the cut surface of each of the chips 401 and 402, and the position of the cut surface of the support substrate 428 can coincide with each other.

Each of the semiconductor layers 411 to 414 may be a semiconductor substrate, a thinned semiconductor substrate, or a semiconductor layer used for an SOI substrate.

As the materials of the insulating layer used for each of the wiring layers 441 to 444 and the insulating layer 423 that insulates the through via 422, for example, SiO₂, SiN, or SiCN can be used. As the materials of the wirings 451 to 454, the pad electrodes 471 to 474, and the through via 422, for example, a metal such as Al, Cu, AlCu, AlSiCu, or Co can be used. As the materials of the through electrodes 427 and 457, for example, a metal such as Cu, Ti, Ta, Al, W, Ni, Ru, or Co can be used, and a laminated structure of a plurality of materials may be used.

The material of the embedding layer 418 includes an insulating layer of an inorganic or organic material, and a plurality of films may be laminated. For example, in the case of an inorganic film, SiO₂, SiON, SiN, SiOC, and SiCN are used, and in the case of an organic film, a resin having a skeleton such as silicone, polyimide, acrylic, epoxy, polymer, or PEEK material, or a material containing a filler such as SiO₂, Al₂O₃, AlN, or BN is used. The material of the embedding layer 418 may be a molding material. The support substrate 428 may be a Si substrate, a ceramic substrate, or a resin substrate.

As described above, in the sixth embodiment described above, the through electrode 427 is extended to the outside via the embedding layer 418 in which the chips 403 and 404 mounted face down on the back surface wiring layer 446 of the chip 402 are embedded. Then, the through electrode 427 is electrically connected with the chip 403 via the back surface wiring layer 446 of the chip 402. As a result, it is not necessary to interpose the wiring layer 441 of the chip 401 and the wiring layer 442 of the chip 402 in order to electrically connect the chip 403 to the outside of the photodetection element 400. As a result, it is not necessary to form a through electrode in any of the chips 401 to 403 in order to electrically connect the chip 403 to the outside of the photodetection element 400, and it is possible to prevent a delay in signal transmission due to parasitic capacitance formed between the through electrode and each of the chips 401 to 403.

In addition, the through electrode 457 is extended to the outside via the embedding layer 418 in which the chips 403 and 404 mounted face down on the back surface wiring layer 446 of the chip 402 are embedded. Then, the through electrode 457 is electrically connected with the chip 401 via the back surface wiring layer 446 of the chip 402. At this time, the through electrode 457 can be arranged not only in the periphery of the photodetection element 400 but also in the central portion. As a result, power can be supplied not only to the periphery of the photodetection element 400 but also to the chip 401 via the through electrode 457 in the central portion, and the IR drop caused by the wiring resistance of the chip 401 can be made uniform between the periphery and the central portion of the chip 401. Therefore, the potential difference of the power supply between the periphery and the central portion of the pixel array unit formed in the chip 401 can be reduced, and deterioration in image quality such as shading can be curbed.

In addition, the through electrode 427 penetrates the support substrate 428, and the through electrode 427 is extended to the outside. As a result, it is not necessary to use wire bonding in order to electrically connect the photodetection element 400 to the outside. Therefore, it is not necessary to provide the bonding region in the photodetection element 400, and it is possible to prevent delay of signal transmission via the bonding wire.

### 7. Seventh Embodiment

In the sixth embodiment described above, the chip 402 on which the wiring layer 442 and the back surface wiring layer 446 are formed is mounted face up, and the through electrodes 427 and 457 extended to the outside via the support substrate 428 are connected to the back surface wiring layer 446. In a seventh embodiment, a chip on which a wiring layer and a back surface wiring layer are formed is mounted face down, and through electrodes 427 and 457 extended to the outside via a support substrate 428 are connected to the wiring layer of the chip mounted face down.

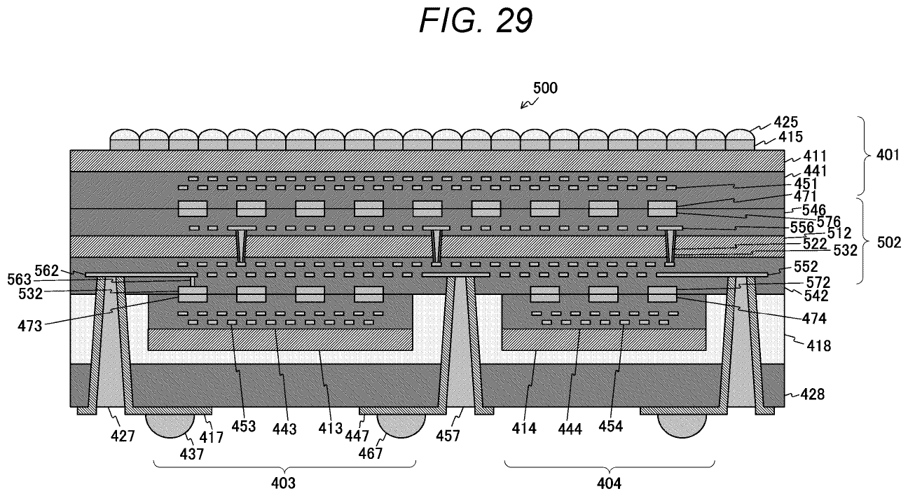

FIG. 29 is a cross-sectional view illustrating a configuration example of a photodetection element according to the seventh embodiment.

In FIG. 29, a photodetection element 500 includes a chip 502 instead of the chip 402 of the sixth embodiment described above. Other configurations of the photodetection element 500 of the sixth embodiment are similar to the configurations of the photodetection element 400 of the sixth embodiment described above.

The chip 502 is laminated on a chip 401. The planar size and shape of the chip 502 can be equal to those of the chip 401. The chip 502 includes a semiconductor layer 512, a wiring layer 542, and a back surface wiring layer 546. Note that the wiring layer 542 is an example of a front surface wiring layer described in the claims.

The wiring layer 542 is formed on the front surface side of the semiconductor layer 512. The wiring layer 542 is provided with a wiring 552 embedded in the insulating layer, and a pad electrode 572. The pad electrode 572 can be used for direct bonding of the front surface side of the chip 502. At this time, the pad electrode 572 of the chip 502 and pad electrodes 473 and 474 of chips 403 and 404 may be Cu—Cu bonded.

The back surface wiring layer 546 is formed on the back surface side of the semiconductor layer 512. The back surface wiring layer 546 is provided with a back surface wiring 556 embedded in the insulating layer, and a pad electrode 576. The pad electrode 576 can be used for direct bonding of the back surface side of the chip 502. At this time, the pad electrode 576 of the chip 502 and a pad electrode 471 of the chip 401 may be Cu—Cu bonded.

A through via 522 is embedded in the semiconductor layer 512. The through via 522 penetrates the semiconductor layer 512 of the chip 502 and can establish conduction between the wiring layer 542 and the back surface wiring layer 546. In order to insulate the through via 522 from the semiconductor layer 512, an insulating layer 532 may be formed around the through via 522.

Each of the chips 403 and 404 is laminated on the wiring layer 542 of the chip 502. Here, each of the chips 403 and 404 can be mounted face down on the back surface wiring layer 542 of the chip 502.

Further, on the wiring layer 542, an embedding layer 418 is laminated so that the chips 403 and 404 are embedded therein. A support substrate 428 is formed on the embedding layer 418.

The through electrode 427 penetrates the embedding layer 418 and the support substrate 428, is electrically connected to a wiring layer 443 via the wiring layer 542, and is extended to the front surface of the support substrate 428. Here, a via 563 may be formed in the wiring layer 542, and the through electrode 427 may be electrically connected to the wiring layer 443 via a wiring 562, the via 563, and a pad electrode 532. Additionally, the through electrode 457 penetrates the embedding layer 418 and the support substrate 428, is electrically connected to the back surface wiring layer 546 via the wiring layer 542, and is extended to the front surface of the support substrate 428.

As described above, in the seventh embodiment described above, the chip 502 on which the wiring layer 542 and the back surface wiring layer 546 are formed is mounted face down, and the through electrodes 427 and 457 extended to the outside via the support substrate 428 are connected to the wiring layer 542. As a result, each of the chips 403 and 404 can transmit signals to and from the chip 502 without interposing the through via 522, and the signal transmission to and from the chip 502 can be speeded up.

### 8. Eighth Embodiment

In the seventh embodiment described above, the chip 502 on which the wiring layer 542 and the back surface wiring layer 546 are formed is mounted face down, and the through electrodes 427 and 457 extended to the outside via the support substrate 428 are connected to the wiring layer 542. In an eighth embodiment, a chip on which a wiring layer and a back surface wiring layer are formed is mounted face down between a chip 401 and a chip 502.

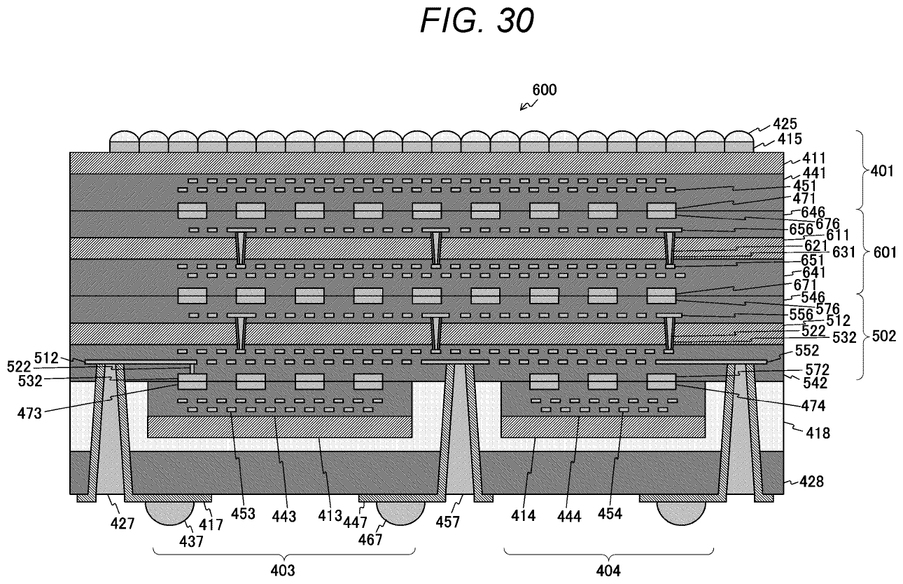

FIG. 30 is a cross-sectional view illustrating a configuration example of a photodetection element according to the eighth embodiment.

In FIG. 30, in a photodetection element 600, a chip 601 is added to the photodetection element 500 of the seventh embodiment described above. Other configurations of the photodetection element 600 of the eighth embodiment are similar to the configurations of the photodetection element 500 of the seventh embodiment described above.

The chip 601 is laminated between the chip 401 and the chip 502. The planar size and shape of the chip 601 can be equal to those of the chip 401. The chip 601 includes a semiconductor layer 611, a wiring layer 641, and a back surface wiring layer 646.

The wiring layer 641 is formed on the front surface side of the semiconductor layer 611. The wiring layer 641 is provided with a wiring 651 embedded in the insulating layer, and a pad electrode 671. The pad electrode 671 can be used for direct bonding of the front surface side of the chip 601. At this time, the pad electrode 671 of the chip 601 and a pad electrode 576 of the chip 502 may be Cu—Cu bonded.

The back surface wiring layer 646 is formed on the back surface side of the semiconductor layer 611. The back surface wiring layer 646 is provided with a back surface wiring 656 embedded in the insulating layer, and a pad electrode 676. The pad electrode 676 can be used for direct bonding of the back surface side of the chip 601. At this time, the pad electrode 676 of the chip 601 and a pad electrode 471 of the chip 401 may be Cu—Cu bonded.

A through via 621 is embedded in the semiconductor layer 611. The through via 621 penetrates the semiconductor layer 611 of the chip 601 and can establish conduction between the wiring layer 641 and the back surface wiring layer 646. In order to insulate the through via 621 from the semiconductor layer 611, an insulating layer 631 may be formed around the through via 621.

As described above, in the eighth embodiment described above, the chip 601 on which the wiring layer 641 and the back surface wiring layer 646 are formed is mounted face down between the chip 401 and the chip 502. As a result, it is possible to expand a data processing function or a memory function associated with an imaging function while curbing a decrease in the signal transmission speed among the chips 401, 601, 502, 403, and 404, and it is possible to curb an increase in the mounting area of the photodetection element 600.

### 9. Ninth Embodiment

In the sixth embodiment described above, the chip 402 on which the wiring layer 442 and the back surface wiring layer 446 are formed is mounted face up, and the through electrodes 427 and 457 extended to the outside via the support substrate 428 are connected to the back surface wiring layer 446. In a ninth embodiment, a chip on which a wiring layer and a back surface wiring layer are formed is mounted face up between a chip 401 and a chip 402.

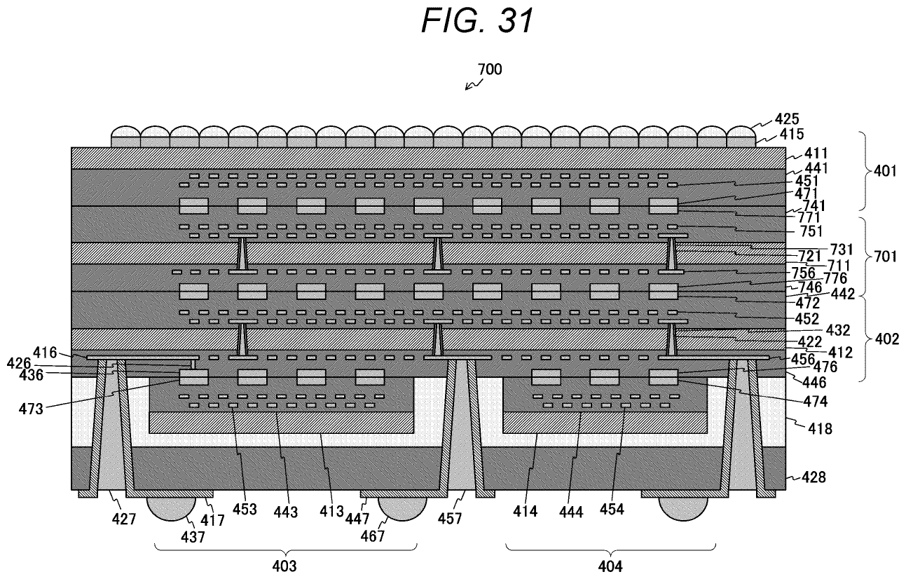

FIG. 31 is a cross-sectional view illustrating a configuration example of a photodetection element according to the ninth embodiment.

In FIG. 31, in a photodetection element 700, a chip 701 is added to the photodetection element 400 of the sixth embodiment described above. Other configurations of the photodetection element 700 of the ninth embodiment are similar to the configurations of the photodetection element 400 of the sixth embodiment described above.

The chip 701 is mounted face up between the chip 401 and the chip 402. The planar size and shape of the chip 701 can be equal to those of the chip 401. The chip 701 includes a semiconductor layer 711, a wiring layer 741, and a back surface wiring layer 746.

The wiring layer 741 is formed on the front surface side of the semiconductor layer 711. The wiring layer 741 is provided with a wiring 751 embedded in the insulating layer, and a pad electrode 771. The pad electrode 771 can be used for direct bonding of the front surface side of the chip 701. At this time, the pad electrode 771 of the chip 701 and a pad electrode 471 of the chip 401 may be Cu—Cu bonded.

The back surface wiring layer 746 is formed on the back surface side of the semiconductor layer 711. The back surface wiring layer 746 is provided with a back surface wiring 756 embedded in the insulating layer, and a pad electrode 776. The pad electrode 776 can be used for direct bonding of the back surface side of the chip 701. At this time, the pad electrode 776 of the chip 701 and a pad electrode 472 of the chip 402 may be Cu—Cu bonded.

A through via 721 is embedded in the semiconductor layer 711. The through via 721 penetrates the semiconductor layer 711 of the chip 701 and can establish conduction between the wiring layer 741 and the back surface wiring layer 746. In order to insulate the through via 721 from the semiconductor layer 711, an insulating layer 731 may be formed around the through via 721.

As described above, in the ninth embodiment described above, the chip 701 on which the wiring layer 741 and the back surface wiring layer 746 are formed is mounted face up between the chip 401 and the chip 402. As a result, it is possible to expand a data processing function or a memory function associated with an imaging function while curbing a decrease in the signal transmission speed among the chips 401 to 404 and 701, and it is possible to curb an increase in the mounting area of the photodetection element 700.

### 10. 10th Embodiment

In the sixth embodiment described above, the through electrode 427 is extended to the outside via the embedding layer 418 in which the chips 403 and 404 mounted face down on an upper layer chip are embedded. In a 10th embodiment, through electrodes having different lengths are extended to the outside via a lower layer chip on which chips 403 and 404 embedded in an embedding layer 418 are mounted face down.

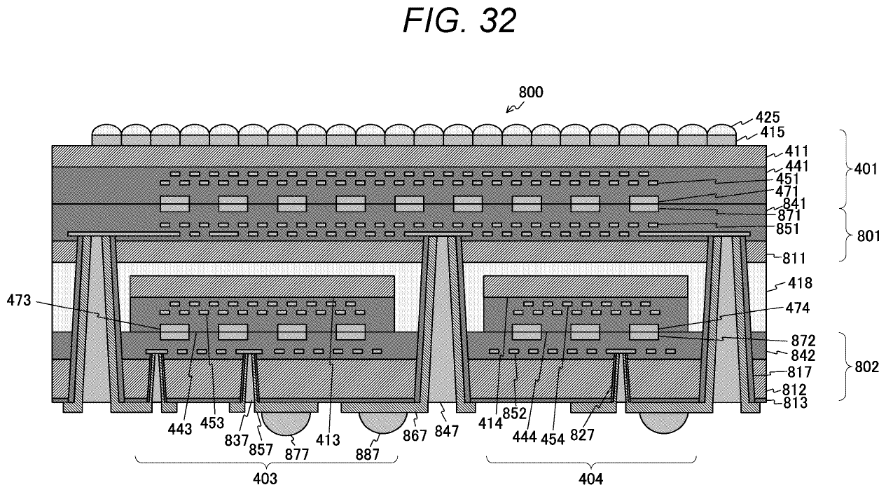

FIG. 32 is a cross-sectional view illustrating a configuration example of a photodetection element according to the 10th embodiment.

In FIG. 32, the photodetection element 800 includes a chip 801 and through electrodes 837 and 847 instead of the chip 402 and the through electrodes 427 and 457 of the sixth embodiment described above. In addition, in the photodetection element 800, a chip 802 is added to the photodetection element 400 of the sixth embodiment described above. Other configurations of the photodetection element 800 of the 10th embodiment are similar to the configurations of the photodetection element 400 of the sixth embodiment described above.

The chip 801 is laminated on a chip 401. The planar size and shape of the chip 801 can be equal to those of the chip 401. The chip 801 includes a semiconductor layer 811 and a wiring layer 841.

The wiring layer 841 is formed on the front surface side of the semiconductor layer 811. The wiring layer 841 is provided with a wiring 851 embedded in the insulating layer, and a pad electrode 871. The pad electrode 871 can be used for direct bonding of the front surface side of the chip 801. At this time, the pad electrode 871 of the chip 801 and a pad electrode 471 of the chip 401 may be Cu—Cu bonded.

The chip 802 is arranged in the lowermost layer of the photodetection element 800. The planar size and shape of the chip 802 can be equal to those of the chip 401. The chip 802 includes a semiconductor layer 812 and a wiring layer 842.

The wiring layer 842 is formed on the front surface side of the semiconductor layer 812. The wiring layer 842 is provided with a wiring 852 embedded in the insulating layer, and a pad electrode 872. The pad electrode 872 can be used for direct bonding of the front surface side of the chip 802. On the wiring layer 842, the chips 403 and 404 are mounted face down. At this time, a pad electrode 872 of the chip 802 may be Cu—Cu bonded to a pad electrode 473 of the chip 403 and a pad electrode 474 of the chip 404.

Further, on the wiring layer 842, the embedding layer 418 is laminated so that the chips 403 and 404 are embedded therein. The chip 801 is laminated on the embedding layer 418.

The through electrode 837 penetrates the semiconductor layer 812, is electrically connected to the wiring layer 842, and is extended to the back surface side of the chip 802. In order to insulate the through electrode 837 from the semiconductor layer 812, an insulating layer 827 may be formed so as to surround the outer periphery of the through electrode 837.

The length of the through electrode 847 is longer than the length of the through electrode 837. At this time, the through electrode 847 penetrates the chip 802, the embedding layer 418, and the semiconductor layer 811, is electrically connected to the wiring layer 841, and is extended to the back surface side of the chip 802. In order to insulate the through electrode 847 from the semiconductor layers 811 and 812, an insulating layer 817 may be formed so as to surround the outer periphery of the through electrode 847.

On the back surface side of the semiconductor layer 812, wirings 857 and 867 are formed via an insulating layer 813. The wiring 857 is connected to the through electrode 837, and the wiring 867 is connected to the through electrode 847. At this time, the wiring 857 may penetrate the semiconductor layer 812 so as to be in contact with the outer periphery of the through electrode 837, and the wiring 867 may penetrate the chip 802, the embedding layer 418, and the semiconductor layer 811 so as to be in contact with the outer periphery of the through electrode 847. A bump electrode 877 is formed on the wiring 857, and a bump electrode 887 is formed on the wiring 867. Each of the bump electrodes 877 and 887 can be used as an external terminal for electrically connecting the photodetection element 800 to the outside.

As described above, in the 10th embodiment described above, the through electrodes 837 and 847 having different lengths are extended to the outside via the chip 802 on which the chips 403 and 404 embedded in the embedding layer 418 are mounted face down. As a result, the through electrode 847 connected to the upper layer chip 801 and the through electrode 837 connected to each of the lower layer chips 403 and 404 can be extended to the mounting surface of the photodetection element 800 while ensuring the strength of the photodetection element 800.

### 11. 11th Embodiment

In the sixth embodiment described above, the through electrodes 427 and 457 are extended to the outside via the embedding layer 418 in which the chips 403 and 404 mounted face down on the back surface wiring layer 446 of the chip 402 laminated on the chip 401 are embedded. In an 11th embodiment, through electrodes 427 and 457 are extended to the outside via an embedding layer 418 in which chips 403 and 404 mounted face down on a wiring layer of the uppermost chip are embedded.

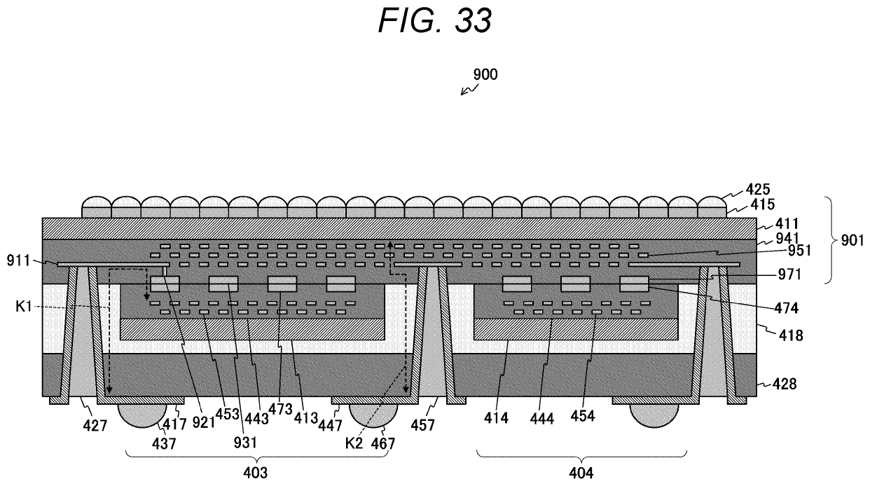

FIG. 33 is a cross-sectional view illustrating a configuration example of a photodetection element according to the 11th embodiment.

In FIG. 33, a photodetection element 900 includes a chip 901 instead of the chip 401 of the sixth embodiment described above. In addition, in the photodetection element 900, the chip 402 is removed from the photodetection element 400 of the sixth embodiment described above. Other configurations of the photodetection element 900 of the 11th embodiment are similar to the configurations of the photodetection element 400 of the sixth embodiment described above.

The chip 901 includes a wiring layer 941 instead of the wiring layer 441 of the sixth embodiment described above. Other configurations of the chip 901 are similar to the configurations of the photodetection element 400 of the sixth embodiment described above.

The wiring layer 941 is formed on the front surface side of a semiconductor layer 411. The wiring layer 941 is provided with a wiring 951 embedded in the insulating layer, and a pad electrode 971. The pad electrode 971 can be used for direct bonding of the front surface side of the chip 901.

On the wiring layer 941, the chips 403 and 404 are mounted face down. At this time, the pad electrode 971 of the chip 901 may be Cu—Cu bonded to a pad electrode 473 of the chip 403 and a pad electrode 474 of the chip 404.

The through electrode 427 penetrates the embedding layer 418 and a support substrate 428, is electrically connected to a wiring layer 443 via the wiring layer 941, and is extended to the front surface of the support substrate 428. At this time, the through electrode 427 can be located on a conduction path K1 that establishes conduction between the external terminal of the photodetection element 900 and the wiring layer 443. Here, a via 921 may be formed in the wiring layer 941, and the through electrode 427 may be electrically connected to the wiring layer 443 via a wiring 911, the via 921, and a pad electrode 931.

The through electrode 457 penetrates the embedding layer 418 and the support substrate 428, is electrically connected to the semiconductor layer 411 via the wiring layer 941, and is extended to the front surface of the support substrate 428. At this time, the through electrode 457 can be located on a conduction path K2 that establishes conduction between the external terminal of the photodetection element 900 and the semiconductor layer 411. Here, the wiring layers 443 and 444 can be prevented from being interposed on the conduction path K2.

As described above, in the 11th embodiment described above, the through electrodes 427 and 457 are extended to the outside via the embedding layer 418 in which the chips 403 and 404 mounted face down on the wiring layer 941 of the uppermost chip 901 are embedded. At this time, the through electrode 427 can be electrically connected to the chip 403 via the wiring layer 941 of the chip 901. As a result, it is not necessary to form a through electrode in the chip 403 in order to electrically connect the chip 403 to the outside of the photodetection element 900, and it is possible to prevent delay of signal transmission due to parasitic capacitance formed between the through electrode and the chip 403. In addition, the through electrode 457 can be arranged not only in the periphery of the photodetection element 900 but also in the central portion. As a result, power can be supplied not only to the periphery of the photodetection element 900 but also to the chip 901 via the through electrode 457 in the central portion, and the IR drop caused by the wiring resistance of the chip 901 can be made uniform between the periphery and the central portion of the chip 901. Therefore, the potential difference of the power supply between the periphery and the central portion of the pixel array unit formed in the chip 901 can be reduced, and deterioration in image quality such as shading can be curbed.

### 12. 12th Embodiment

In the sixth embodiment described above, the through electrodes 427 and 457 are extended to the outside via the embedding layer 418 in which the chips 403 and 404 mounted face down on the back surface wiring layer 446 of the chip 402 laminated on the chip 401 are embedded. In a 12th embodiment, an embedded member is embedded in a semiconductor substrate 413 of the chip 403 embedded in an embedding layer 418 in which a through electrode 427 is embedded.

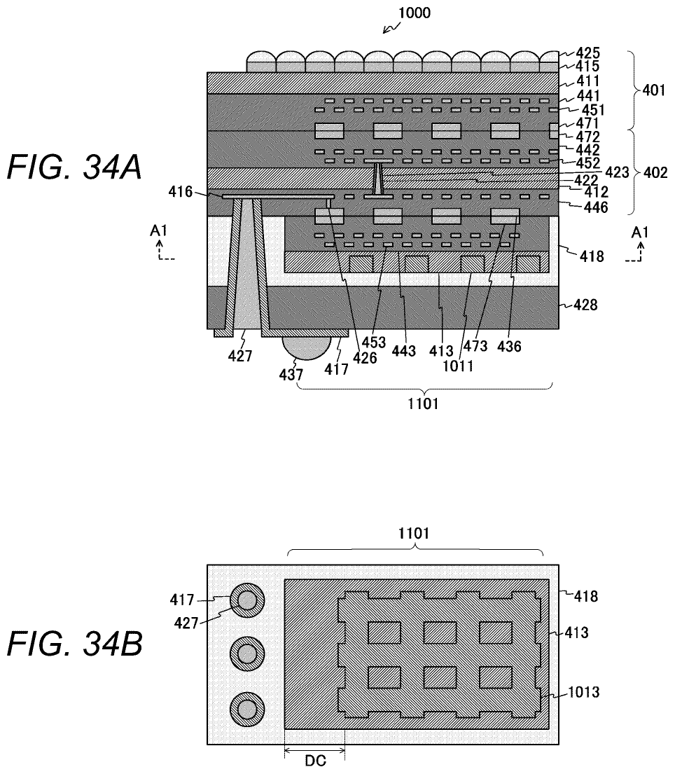

FIG. 34 is a cross-sectional view illustrating a configuration example of a photodetection element according to the 12th embodiment. In FIG. 34, a is a vertical cross-sectional view illustrating the configuration example of the photodetection element according to the 12th embodiment, and b is a horizontal cross-sectional view illustrating the configuration example of the photodetection element according to the 12th embodiment. Note that b of FIG. 34 is cut at the position of line A1-A1 in a of FIG. 34. In addition, a in FIG. 34 omits the chip 404 and the through electrode 457 in FIG. 28.

In FIG. 34, a photodetection element 1000 includes a chip 1101 instead of the chip 403 of the sixth embodiment described above. Other configurations of the photodetection element 1001 of the 12th embodiment are similar to the configurations of the photodetection element 400 of the sixth embodiment described above. Note, however, that an embedded member may also be formed in the chip 404 as in the case of the chip 1101.

In the chip 1101, an embedded member 1011 is added to the chip 403 of the sixth embodiment described above. Other configurations of the chip 1101 are similar to the configurations of the chip 403 of the sixth embodiment described above.

The embedded member 1011 is embedded in the semiconductor layer 413 of the chip 1101 from the back surface side. The embedded member 1011 can be embedded at a position insulated from a wiring layer 443. The embedded member 1011 alleviates non-uniformity of stress applied to the chip 1101 due to the through electrode 427. In the semiconductor layer 413, the arrangement position and area density of the embedded member 1011 can be selected so that stress in a region close to the through electrode 427 and stress in a region far from the through electrode 427 are made uniform. At this time, in the semiconductor layer 413, the area density of the embedded member 1011 in the region close to the through electrode 427 is preferably smaller than the area density of the embedded member 1011 in the region far from the through electrode 427. For example, the area density of the embedded member 1011 in a region from the end of the semiconductor layer 413 on the through electrode 427 side to a distance DC can be made smaller than the area density of the embedded member 1011 in a region exceeding the distance DC from the end of the semiconductor layer 413. The distance DC is, for example, 200 μm. At this time, the embedded member 1011 may be omitted from the region from the end of the semiconductor layer 413 on the through electrode 427 side to the distance DC.

The planar shape of the embedded member 1011 can be selected from a vertical stripe, a horizontal stripe, an oblique stripe, intersecting stripes, a circle, an n-gon (n is an integer of 3 or more), a ring, a solid, and a combination thereof. For example, the planar shape of the embedded member 1011 may be a lattice shape.

The material of the embedded member 1011 can be selected from any one of a metal, a metal oxide, an organic substance, an inorganic substance, and a combination thereof. For example, the material of the embedded member 1011 may be Cu, Al, W, Au, Ag, or the like in the case of a metal, may be Al₂O₃ or the like in the case of a metal oxide, may be SiO₂, SiN, or the like in the case of an inorganic substance, or may be a resin such as polyimide in the case of an organic substance. Note that the material of the embedded member 1101 is preferably a material having a tensile stress larger than that of the material of the semiconductor layer 413 because the above-described stress non-uniformity can be satisfactorily alleviated.

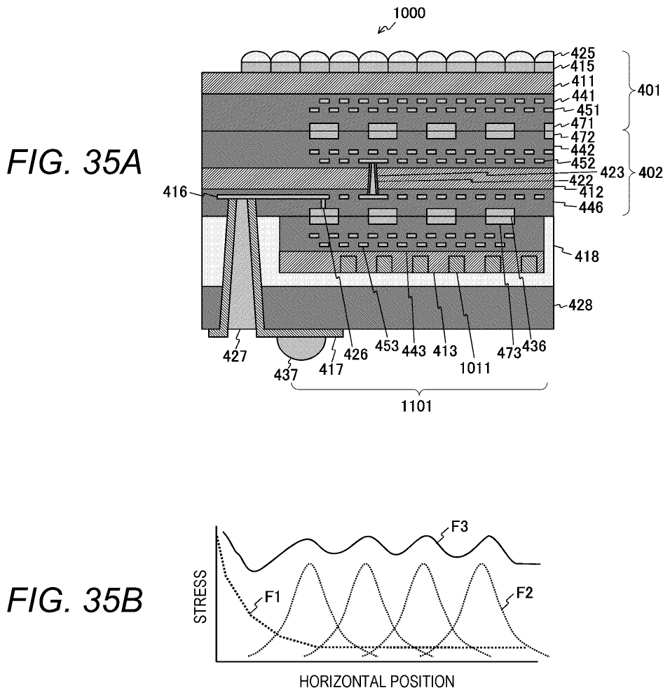

FIG. 35 is a diagram illustrating a relationship between a horizontal position and stress in the photodetection element according to the 12th embodiment. In FIG. 35, a is a vertical cross-sectional view illustrating a configuration example of the photodetection element according to the 12th embodiment, and b is a diagram illustrating a relationship between a horizontal position and stress in the photodetection element according to the 12th embodiment.

In b of FIG. 35, in a case where the embedded member 1011 is not provided, a stress distribution F1 is generated in the chip 1101 due to the through electrode 427. Here, by embedding the embedded member 1011 in the semiconductor layer 413 of the chip 1101 from the back surface side, a stress distribution F2 can be generated in the chip 1101. At this time, a stress distribution F3 obtained by combining the stress distributions F1 and F2 is applied to the chip 1101, and it is possible to improve the uniformity of the stress applied to the chip 1101 while eliminating the need for a keep-out zone between the chip 1101 and the through electrode 427.

Note that in order to improve the uniformity of the stress applied to the chip 1101, at least one of the depth, the planar size, and the planar shape of the embedded member 1011 may be made different according to the position of the semiconductor layer 413.

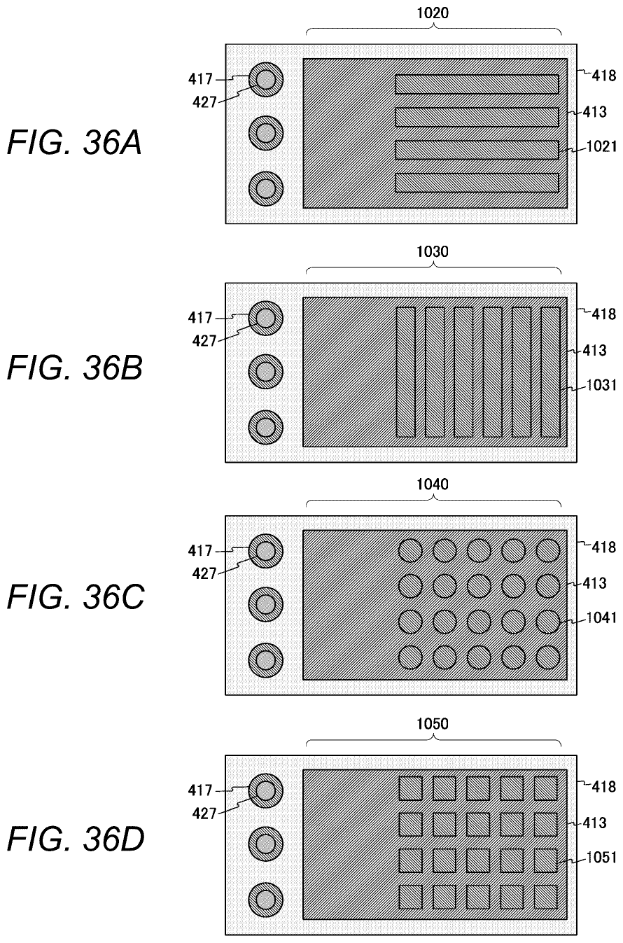

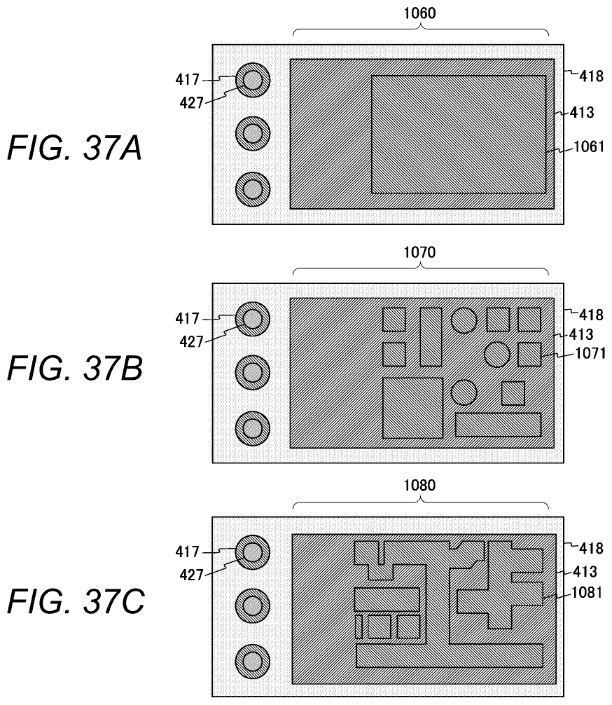

FIGS. 36 and 37 are diagrams illustrating other configuration examples of the photodetection element according to the 12th embodiment.

In a of FIG. 36, the photodetection element may be provided with a chip 1020 instead of the chip 1101. The chip 1020 is provided with an embedded member 1021 instead of the embedded member 1011. The planar shape of the embedded member 1021 can be a horizontal stripe. At this time, the embedded members 1021 can be arranged side by side in the longitudinal direction.

In b of FIG. 36, the photodetection element may be provided with a chip 1030 instead of the chip 1101. The chip 1030 is provided with an embedded member 1031 instead of the embedded member 1011. The planar shape of the embedded member 1031 can be a vertical stripe. At this time, the embedded members 1031 can be arranged side by side in the lateral direction.

In c of FIG. 36, the photodetection element may be provided with a chip 1040 instead of the chip 1101. The chip 1040 is provided with an embedded member 1041 instead of the embedded member 1011. The planar shape of the embedded member 1041 can be circular. At this time, the embedded members 1041 can be arranged side by side in the longitudinal direction and the lateral direction.

In d of FIG. 36, the photodetection element may be provided with a chip 1050 instead of the chip 1101. The chip 1050 is provided with an embedded member 1051 instead of the embedded member 1011. The planar shape of the embedded member 1051 can be an n-gon. At this time, the embedded members 1051 can be arranged side by side in the longitudinal direction and the lateral direction.

In a of FIG. 37, the photodetection element may be provided with a chip 1060 instead of the chip 1101. The chip 1060 is provided with an embedded member 1061 instead of the embedded member 1011. The planar shape of the embedded member 1061 can be a solid pattern.

In b of FIG. 37, the photodetection element may be provided with a chip 1070 instead of the chip 1101. The chip 1070 is provided with an embedded member 1071 instead of the embedded member 1011. The planar shape of the embedded member 1071 can be a combination of a circle, a rectangle, and an n-gon. At this time, the sizes of the circle, the rectangle, and the n-gon may be different from each other.

In c of FIG. 37, the photodetection element may be provided with a chip 1080 instead of the chip 1101. The chip 1080 is provided with an embedded member 1081 instead of the embedded member 1011. The planar shape of the embedded member 1081 can be a combination of a square, a rectangle, and an oblique pattern.

As described above, in the 12th embodiment described above, the embedded member 1011 is embedded in the semiconductor substrate 413 of the chip 1101 embedded in the embedding layer 418 in which the through electrode 427 is embedded. As a result, it is possible to alleviate the restriction on the arrangement position of the through electrode 427 connected to the external terminal of the photodetection element while alleviating the non-uniformity of the stress applied to the chip 1101 due to the through electrode 427.

### 13. 13th Embodiment

In the 12th embodiment described above, the embedded member 1011 is embedded in the semiconductor substrate 413 of the chip 1101 embedded in the embedding layer 418 in which the through electrode 427 is embedded. In a 13th embodiment, the position of an embedded member embedded in a semiconductor substrate 413 of a chip is made different according to the arrangement position of a through electrode 427.

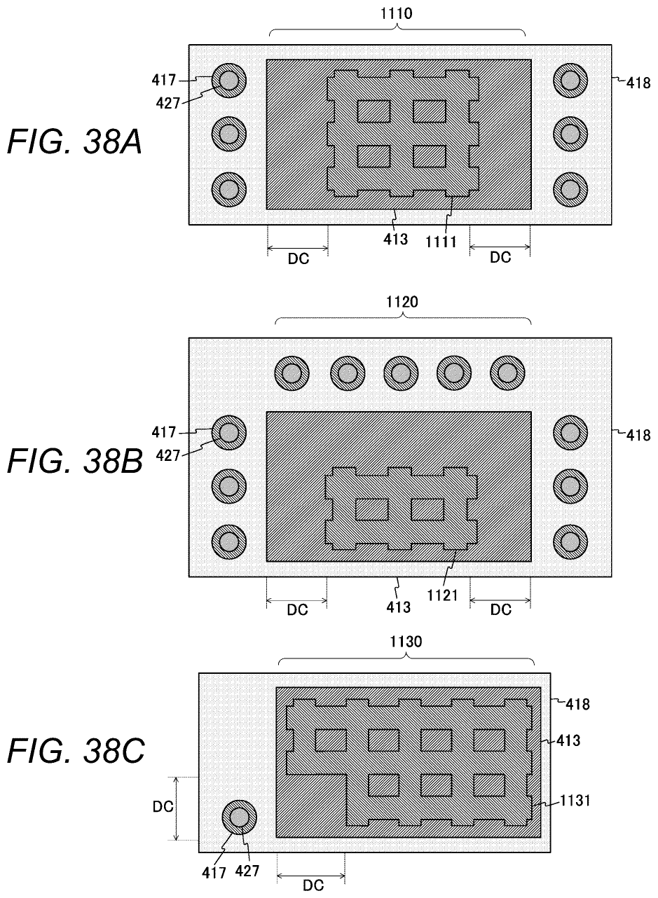

FIG. 38 is a cross-sectional view illustrating configuration examples of a photodetection element according to the 13th embodiment.

In a of FIG. 38, a first example of the photodetection element includes a chip 1110 instead of the chip 1101 of the 12th embodiment described above. The chip 1110 is embedded in an embedding layer 418. In addition, the through electrodes 427 embedded in the embedding layer 418 are located on both sides of the chip 1110. Other configurations of the first example of the photodetection element of the 13th embodiment are similar to the configurations of the photodetection element of the 12th embodiment described above.

The chip 1110 includes an embedded member 1111 instead of the embedded member 1011 of the 12th embodiment described above. Other configurations of the chip 1110 are similar to the configurations of the photodetection element of the 12th embodiment described above.

The embedded member 1111 is embedded in the semiconductor layer 413 of the chip 1110 from the back surface side. The embedded member 1111 alleviates non-uniformity of stress applied to the chip 1110 due to the through electrode 427. At this time, in the semiconductor layer 413, the area density of the embedded member 1111 in a region close to the through electrode 427 can be made smaller than the area density of the embedded member 1111 in a region far from the through electrode 427. For example, the embedded member 1111 may be omitted from regions from both ends of the semiconductor layer 413 adjacent to the through electrode 427 to a distance DC.

In b of FIG. 38, a second example of the photodetection element includes a chip 1120 instead of the chip 1101 of the 12th embodiment described above. The chip 1120 is embedded in the embedding layer 418. In addition, the through electrode 427 embedded in the embedding layer 418 is located adjacent to three sides of the chip 1110. Other configurations of the second example of the photodetection element of the 13th embodiment are similar to the configurations of the photodetection element of the 12th embodiment described above.

The chip 1120 includes an embedded member 1121 instead of the embedded member 1011 of the 12th embodiment described above. Other configurations of the chip 1120 are similar to the configurations of the photodetection element of the 12th embodiment described above.

The embedded member 1121 is embedded in the semiconductor layer 413 of the chip 1120 from the back surface side. The embedded member 1121 alleviates non-uniformity of stress applied to the chip 1120 due to the through electrode 427. At this time, in the semiconductor layer 413, the area density of the embedded member 1121 in a region close to the through electrode 427 can be made smaller than the area density of the embedded member 1121 in a region far from the through electrode 427. For example, the embedded member 1121 may be omitted from a region from each of the three sides of the semiconductor layer 413 adjacent to the through electrode 427 to the distance DC.

In c of FIG. 38, a third example of the photodetection element includes a chip 1130 instead of the chip 1101 of the 12th embodiment described above. The chip 1130 is embedded in the embedding layer 418. In addition, the through electrode 427 embedded in the embedding layer 418 is located at a corner of the chip 1110. Other configurations of the third example of the photodetection element of the 13th embodiment are similar to the configurations of the photodetection element of the 12th embodiment described above.

The chip 1130 includes an embedded member 1131 instead of the embedded member 1011 of the 12th embodiment described above. Other configurations of the chip 1130 are similar to the configurations of the photodetection element of the 12th embodiment described above.

The embedded member 1131 is embedded in the semiconductor layer 413 of the chip 1130 from the back surface side. The embedded member 1131 alleviates non-uniformity of stress applied to the chip 1130 due to the through electrode 427. At this time, in the semiconductor layer 413, the area density of the embedded member 1131 in a region close to the through electrode 427 can be made smaller than the area density of the embedded member 1131 in a region far from the through electrode 427. For example, the embedded member 1131 may be omitted from a region from the corner of the semiconductor layer 413 adjacent to the through electrode 427 to the distance DC.

As described above, in the 13th embodiment described above, the position of the embedded member embedded in the semiconductor substrate 413 of the chip is made different according to the arrangement position of the through electrode 427. As a result, it is possible to improve the uniformity of the stress applied to the chip embedded in the embedding layer 418 while coping with the difference in the arrangement position of the through electrode 427 embedded in the embedding layer 418.

### 14. 14th Embodiment

In the 12th embodiment described above, the embedded member 1011 is embedded in the semiconductor substrate 413 of the chip 1101 embedded in the embedding layer 418 in which the through electrode 427 is embedded. In a 14th embodiment, a stress alleviating film is formed on the bottom surface and the side surface of an embedded member embedded in a semiconductor substrate 413 of a chip.

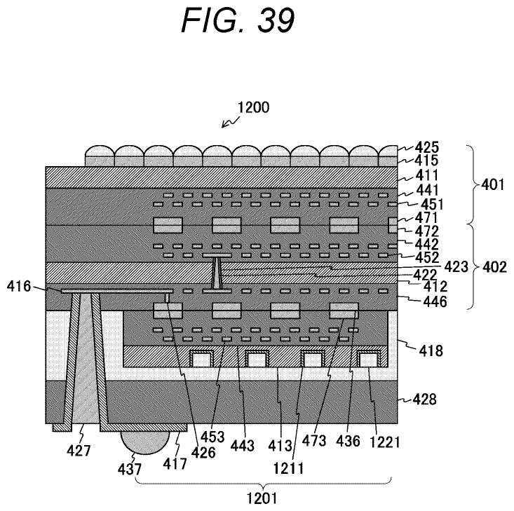

FIG. 39 is a cross-sectional view illustrating a configuration example of a photodetection element according to the 14th embodiment.

In FIG. 39, a photodetection element 1200 includes a chip 1201 instead of the chip 1101 of the 12th embodiment described above. Other configurations of the photodetection element 1200 of the 14th embodiment are similar to the configurations of the photodetection element 1000 of the 12th embodiment described above.

The chip 1201 includes an embedded member 1221 instead of the embedded member 1011 of the 12th embodiment described above. In addition, in the chip 1201, an embedding layer 1211 is added to the chip 1101 of the 12th embodiment described above. Other configurations of the chip 1201 are similar to the configurations of the chip 1101 of the 12th embodiment described above.

The embedded member 1221 is embedded in the semiconductor layer 413 of the chip 1201 from the back surface side. The bottom surface and the side surface of the embedded member 1221 are covered with the embedding layer 1211. The embedding layer 1211 can be embedded in the semiconductor layer 413 of the chip 1201 from the back surface side. The embedding layer 1211 alleviates non-uniformity of stress applied to the chip 1201 due to the through electrode 427. The materials of the embedded member 1221 and the embedding layer 1211 can be different from each other. The materials of the embedded member 1221 and the embedding layer 1211 can be selected from any one of a metal, a metal oxide, an organic substance, an inorganic substance, and a combination thereof. The embedded member 1221 may be hollow.

As described above, in the 14th embodiment described above, the embedding layer 1211 embedded in the semiconductor layer 413 of the chip 1201 from the back surface side is used as a stress alleviating film. As a result, the non-uniformity of the stress applied to the chip 1201 due to the through electrode 427 can be alleviated, and the uniformity of the stress applied to the chip 1201 can be improved by adjusting the film thickness of the embedding layer 1211.

### 15. 15th Embodiment

In the 12th embodiment described above, the embedded member 1011 is embedded in the semiconductor substrate 413 of the chip 403 embedded in the embedding layer 418 in which the through electrode 427 is embedded. In a 15th embodiment, an embedded member embedded in a semiconductor substrate 413 of a chip is formed using an embedding layer 418 in which the chip is embedded.

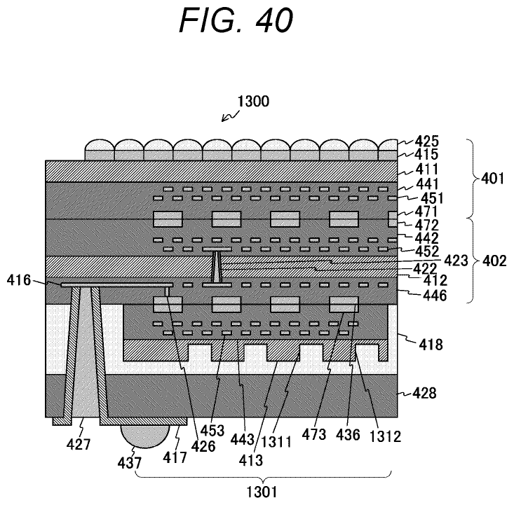

FIG. 40 is a cross-sectional view illustrating a configuration example of a photodetection element according to the 15th embodiment.

In FIG. 40, a photodetection element 1300 includes a chip 1301 instead of the chip 1101 of the 12th embodiment described above. Other configurations of the photodetection element 1300 of the 15th embodiment are similar to the configurations of the photodetection element 1000 of the 12th embodiment described above.

The chip 1301 includes an embedded member 1311 instead of the embedded member 1011 of the 12th embodiment described above. Other configuration of the chip 1301 are similar to the configurations of the chip 1101 of the 12th embodiment described above.

The chip 1301 is embedded in the embedding layer 418. The embedded member 1311 is embedded in the semiconductor layer 413 of the chip 1301 from the back surface side. The embedded member 1311 alleviates non-uniformity of stress applied to the chip 1301 due to a through electrode 427. The embedded member 1311 is formed using the embedding layer 418. Here, when the chip 1301 is embedded in the embedding layer 418, the embedded member 1311 can be embedded in the chip 1301. At this time, before the chip 1301 is embedded in the embedding layer 418, a recess 1312 in which the embedded member 1311 is embedded can be formed on the back surface side of the semiconductor layer 413.

As described above, in the 15th embodiment described above, the embedded member 1311 embedded in the semiconductor substrate 413 of the chip 1301 is formed using the embedding layer 418 in which the chip 1301 is embedded. As a result, it is possible to eliminate the need to provide the step of embedding the embedded member 1311 in the semiconductor substrate 413 of the chip 1301 separately from the step of embedding the chip 1301 in the embedding layer 418. Therefore, it is possible to alleviate non-uniformity of stress applied to the chip 1301 due to the through electrode 427 while curbing an increase in the number of steps.

### 16. 16th Embodiment

In the 12th embodiment described above, the embedded member 1011 is embedded in the semiconductor substrate 413 of the chip 403 embedded in the embedding layer 418 in which the through electrode 427 is embedded. In a 16th embodiment, a functional film is formed on the bottom surface and the side surface of an embedded member embedded in a semiconductor substrate 413 of a chip.

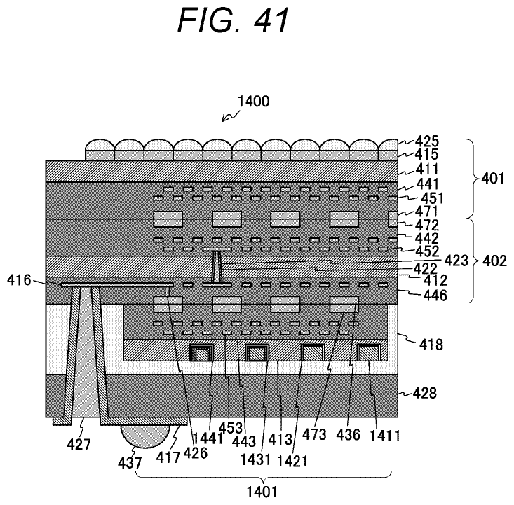

FIG. 41 is a cross-sectional view illustrating a configuration example of a photodetection element according to the 16th embodiment.

In FIG. 41, a photodetection element 1400 includes a chip 1401 instead of the chip 1101 of the 12th embodiment described above. Other configurations of the photodetection element 1400 of the 14th embodiment are similar to the configurations of the photodetection element 1000 of the 12th embodiment described above.

The chip 1401 includes an embedded member 1411 instead of the embedded member 1011 of the 12th embodiment described above. In addition, in the chip 1401, functional films 1421, 1431, and 1441 are added to the chip 1101 of the 12th embodiment described above. Other configurations of the chip 1401 are similar to the configurations of the chip 1101 of the 12th embodiment described above.

The embedded member 1411 is embedded in the semiconductor layer 413 of the chip 1401 from the back surface side. The embedded member 1411 alleviates non-uniformity of stress applied to the chip 1401 due to a through electrode 427. The bottom surface and the side surface of the embedded member 1411 are covered with at least one of the functional films 1421, 1431, and 1441. At this time, the functional films 1421, 1431, and 1441 may be a single layer or may be laminated. The functional films 1421, 1431, and 1441 can be embedded in the semiconductor layer 413 of the chip 1401 from the back surface side. The functional films 1421, 1431, and 1441 may be dielectric films, protective films, or barrier metal films.

As described above, in the 16th embodiment described above, the functional films 1421, 1431, and 1441 are formed on the bottom surface and the side surface of the embedded member 1411 embedded in the semiconductor substrate 413 of the chip. As a result, it is possible to secure the suitability of the embedded member 1411 while alleviating non-uniformity of stress applied to the chip 1401 due to the through electrode 427.

Note that in the 16th embodiment described above, an example has been described in which the embedded member 1411 is embedded in the semiconductor layer 413 from the back surface side at a position insulated from a wiring layer 443. A capacitor may be formed in the embedded member 1411. The capacitor may be configured to reduce noise included in a signal input to the photodetection element. At this time, the capacitor may be connected to the input terminal of the photodetection element via the wiring layer 443.

### 17. 17th Embodiment

In the 12th embodiment described above, the embedded member 1011 is embedded in the semiconductor substrate 413 of the chip 403 embedded in the embedding layer 418 in which the through electrode 427 is embedded. In a 17th embodiment, a functional film is formed on the back surface side of a chip in which an embedded member 1011 is embedded.

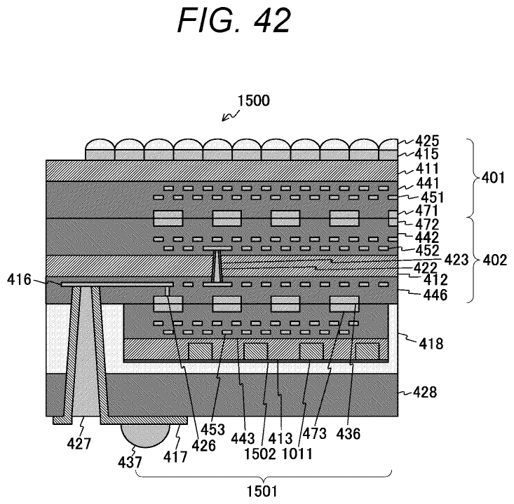

FIG. 42 is a cross-sectional view illustrating a configuration example of a photodetection element according to the 17th embodiment.

In FIG. 42, a photodetection element 1500 includes a chip 1501 instead of the chip 1101 of the 12th embodiment described above. Other configurations of the photodetection element 1500 of the 15th embodiment are similar to the configurations of the photodetection element 1000 of the 12th embodiment described above.

In the chip 1501, a functional film 1502 is added to the chip 1101 of the 12th embodiment described above. Other configurations of the chip 1501 are similar to the configurations of the chip 1101 of the 12th embodiment described above.

The functional film 1502 is formed on the back surface side of a semiconductor substrate 413 so as to cover the front surface of the embedded member 1011. The functional film 1502 may be a heat dissipation film, a protective film, or a warpage correction film. The functional film 1502 may be a single layer, or films having different functions may be laminated.

As described above, in the 17th embodiment described above, the functional film 1502 is formed on the back surface side of the chip 1501 in which the embedded member 1011 is embedded. As a result, it is possible to alleviate non-uniformity of stress applied to the chip 1501 due to a through electrode 427, and it is possible to improve the characteristics and reliability of the chip 1501 while curbing complication of the manufacturing process.

### 18. 18th Embodiment

In the 12th embodiment described above, the embedded member 1011 is embedded in the semiconductor substrate 413 of the chip 403 embedded in the embedding layer 418 in which the through electrode 427 is embedded. In an 18th embodiment, a part of an embedded member embedded in a semiconductor substrate 413 of a chip embedded in an embedding layer 418 is configured to penetrate the semiconductor substrate 413.

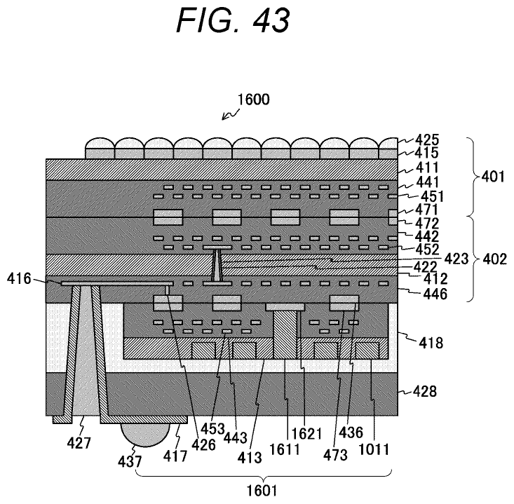

FIG. 43 is a cross-sectional view illustrating a configuration example of a photodetection element according to the 18th embodiment.

In FIG. 43, a photodetection element 1600 includes a chip 1601 instead of the chip 1101 of the 12th embodiment described above. Other configurations of the photodetection element 1600 of the 18th embodiment are similar to the configurations of the photodetection element 1000 of the 12th embodiment described above.

In the chip 1601, an embedded member 1611 and a dummy electrode 1621 are added to the chip 1101 of the 12th embodiment described above. Other configurations of the chip 1601 are similar to the configurations of the chip 1101 of the 12th embodiment described above.

The dummy electrode 1621 is embedded in a wiring layer 443. The dummy electrode 1621 can be formed as an isolated electrode insulated from a wiring 453. The dummy electrode 1621 can be formed in the same layer as a pad electrode 473. At this time, the material of the dummy electrode 1621 can be the same as the material of the pad electrode 473.

The embedded member 1611 is embedded in the semiconductor layer 413 of the chip 1601 from the back surface side. At this time, the embedded member 1611 can penetrate the semiconductor layer 413 and be connected to the dummy electrode 1621. The embedded member 1611 alleviates non-uniformity of stress applied to the chip 1601 due to a through electrode 427. The embedded member 1011 and the embedded member 1611 can have different effects of alleviating non-uniformity of stress applied to the chip 1601. At this time, the arrangement position of the embedded member 1611 can be set so as to improve the uniformity of the stress applied to the chip 1601. The material of the embedded member 1611 can be the same as the material of the embedded member 1011. Note that any of the configurations of the 14th to 16th embodiments described above may also be applied to the embedded member 1611.

As described above, in the 18th embodiment described above, the embedded member 1611 embedded in the semiconductor substrate 413 of the chip 1601 embedded in the embedding layer 418 is configured to penetrate the semiconductor substrate 413. As a result, even when there is specificity in the stress applied to the chip 1601, non-uniformity of the stress applied to the chip 1601 due to the through electrode 427 can be alleviated.

### 19. 19th Embodiment

In the 12th embodiment described above, the embedded member 1011 is embedded in the semiconductor substrate 413 of the chip 403 embedded in the embedding layer 418 in which the through electrode 427 is embedded. In a 19th embodiment, functional films different from each other are formed on the bottom surface, the side surface, and the front surface of an embedded member embedded in a semiconductor substrate 413 of a chip embedded in an embedding layer 418.

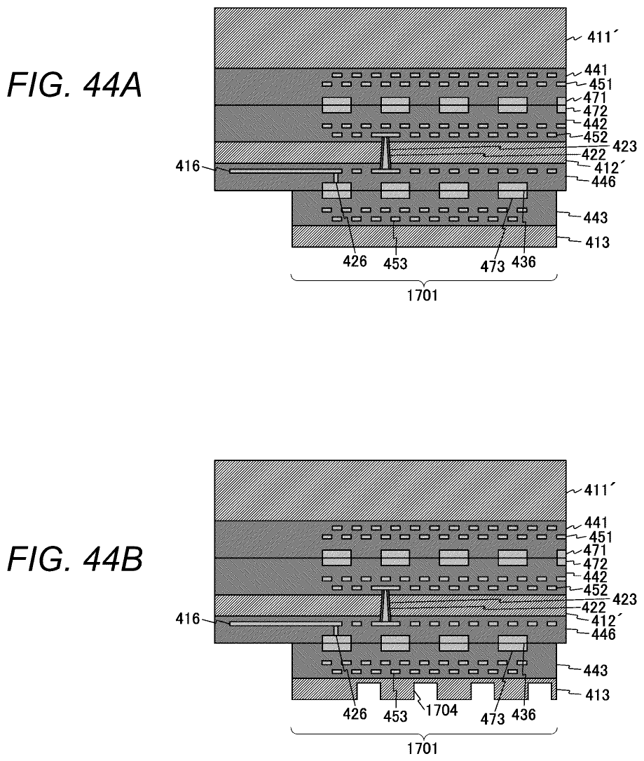

FIGS. 44 to 48 are diagrams illustrating a configuration example of a photodetection element according to the 19th embodiment.

In a of FIG. 44, a pixel array unit and peripheral circuits are formed on a semiconductor wafer 411′ for each section into which a chip 401 is cut out. Next, a wiring layer 441 provided with a wiring 451 and a pad electrode 471 is formed on the semiconductor wafer 411′. A plurality of chips 401 used for a plurality of photodetection elements 1700 can be cut out from the semiconductor wafer 411′. For example, the semiconductor wafer 411′ can be partitioned along a dicing line used for the singulation of the photodetection element.

In addition, a semiconductor element such as a transistor is formed on a semiconductor wafer 412′ for each section into which a chip 402 is cut out. Next, a wiring layer 442 provided with a wiring 452 and a pad electrode 472 is formed on the semiconductor wafer 412′. A plurality of chips 402 used for a plurality of photodetection elements 1700 can be cut out from the semiconductor wafer 412′. For example, the semiconductor wafer 412′ can be partitioned along a dicing line used for the singulation of the photodetection element 1700.

Next, the wiring layer 441 and the wiring layer 442 are directly bonded so that the wiring layers 441 and 442 face each other. At this time, the pad electrode 471 of the wiring layer 441 and the pad electrode 472 of the wiring layer 442 may be Cu—Cu bonded.

Next, the semiconductor wafer 412′ is thinned from the back surface side. Then, a through via 422 is embedded in the semiconductor wafer 412′ so as to be electrically connected to the wiring 452. An insulating layer 423 may cover the periphery of the through via 422 to insulate the through via 422 from the semiconductor wafer 412′.

Next, a back surface wiring layer 446 provided with a back surface wiring 416, a pad electrode 436, and a back surface wiring 416 is formed on the back surface side of the semiconductor wafer 412′. At this time, the through via 422 can be electrically connected to the back surface wiring 416.

Next, singulated chips 1701 are prepared. The chip 1701 is provided with the semiconductor layer 413, and a wiring layer 443 is formed on the front surface side of the semiconductor layer 413. The wiring layer 443 is provided with a wiring 453 embedded in the insulating layer, and a pad electrode 473. Then, the wiring layer 443 is directly bonded to the back surface wiring layer 446 such that the wiring layer 443 faces the back surface wiring layer 446. At this time, the pad electrode 473 of the wiring layer 443 may be bonded to the pad electrode 436 of the back surface wiring layer 446 by Cu—Cu bonding.

Next, as illustrated in b of FIG. 44, a recess 1704 is formed on the back surface side of the semiconductor layer 413 by using a photolithography technique and a dry etching technique. The recess 1704 can be formed at the embedded position of an embedded member 1711.

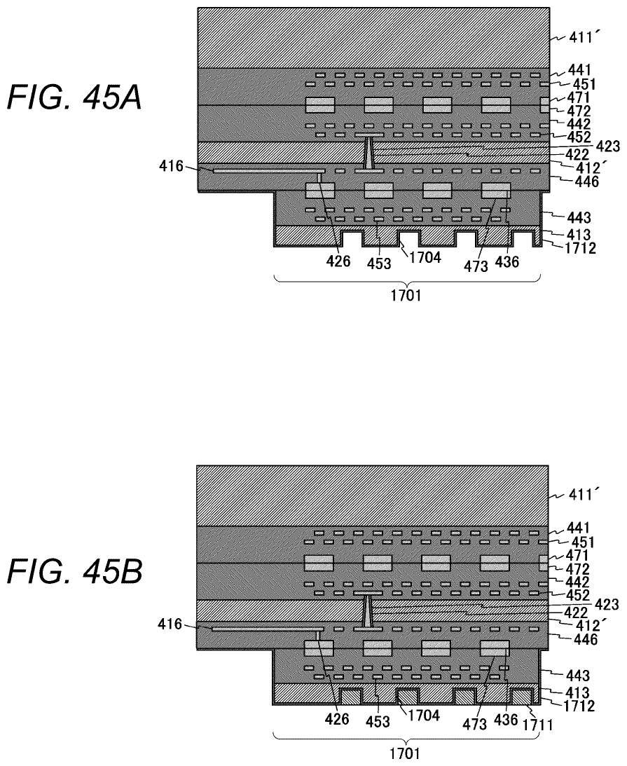

Next, as illustrated in a of FIG. 45, a functional film 1712 is formed on the back surface side of the semiconductor layer 413 so as to cover the bottom surface and the side surface of the recess 1704. The functional film 1712 may be a single layer or may be laminated. The functional film 1712 may be a dielectric film, a protective film, or a barrier metal film. The functional film 1712 may be omitted. For forming the functional film 1712, for example, CVD, PVD, atomic layer deposition (ALD), or plating can be used.

Next, as illustrated in b of FIG. 45, a filling material used for the embedded member 1711 is deposited on the back surface side of the semiconductor layer 413. For example, CVD or plating can be used to deposit the filling material used for the embedded member 1711. Then, by planarizing the filling material used for the embedded member 1711, the embedded member 1711 is embedded in the recess 1704. For planarizing the filling material used for the embedded member 1711, for example, CMP can be used.

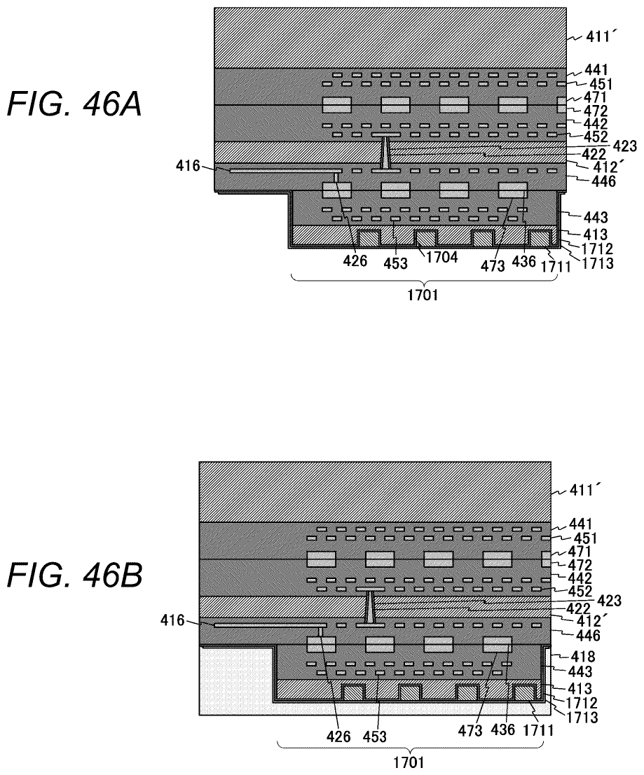

Next, as illustrated in a of FIG. 46, a functional film 1713 is formed on the back surface side of the semiconductor layer 413 so as to cover the front surface of the embedded member 1711. The functional film 1713 may be a single layer or may be laminated. The functional film 1713 may be a heat dissipation film, a protective film, or a warpage correction film. The functional film 1713 may be omitted. For forming the functional film 1713, for example, CVD, PVD, ALD, or plating can be used.

Next, as illustrated in b of FIG. 46, the embedding layer 418 is laminated on the back surface wiring layer 446 so that the chip 1701 is embedded therein. For lamination of the embedding layer 418, CVD, ALD, vapor deposition, sputtering, or the like may be used in the case of an inorganic material, and coating, dipping, spray coating, or the like may be used in the case of an organic material. The embedding layer 418 may be planarized. In the planarization of the embedding layer 418, a grinder or CMP may be used.

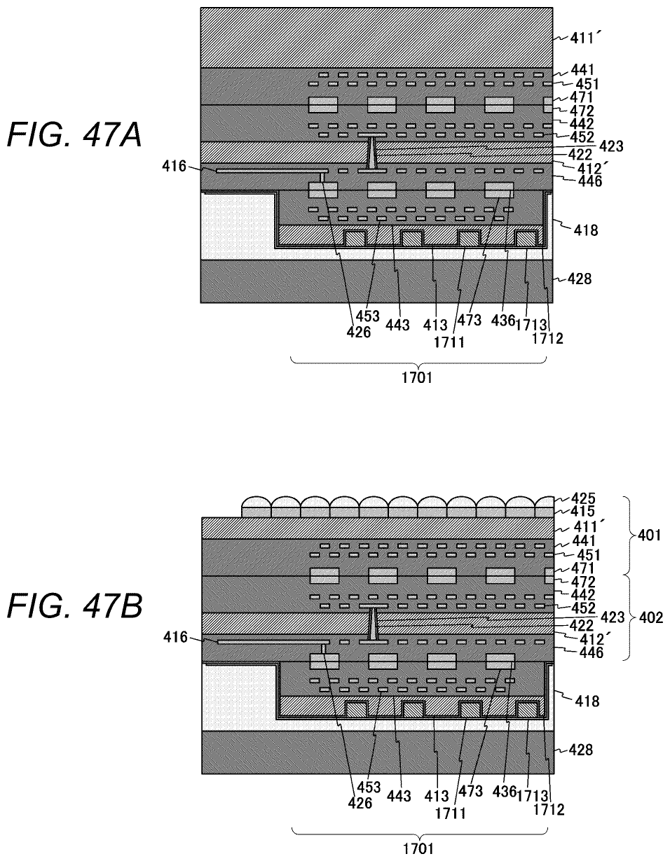

Next, as illustrated in a of FIG. 47, a support substrate 428 is bonded onto the embedding layer 418. The planar size and shape of the support substrate 428 can be equal to the planar size and shape of the semiconductor wafer 411′.

Next, as illustrated in b of FIG. 47, the conductor wafer 411′ is thinned from the back surface side. In this thinning, for example, a grinder, CMP, dry etching, or wet etching may be used. In a case where a back-illuminated individual imaging element is formed on the semiconductor wafer 411′, the rear surface side of the thinned semiconductor wafer 411′ becomes the light receiving surface.

Next, a color filter 415 is formed for each pixel on the back surface side of the semiconductor wafer 411′. Moreover, an on-chip lens 425 is formed on the color filter 415 for each pixel.

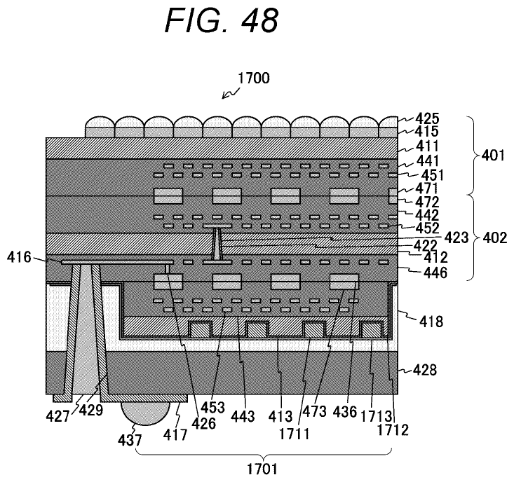

Next, as illustrated in FIG. 48, a through hole 429 reaching the back surface wiring layer 446 is formed in the support substrate 428, the embedding layer 418, and the functional films 1712 and 1713. The through hole 429 can be formed at a position where a through electrode 427 is embedded. Then, a wiring 417 is formed on the support substrate 428 so as to cover the side surface of the through hole 429.

Next, the through electrode 427 that penetrates the embedding layer 418 and is connected to the back surface wiring layer 446 is formed in the through hole 429. The diameter of the through electrode 427 can be set according to the number of IOs extracted outside the photodetection element 1700, and can be set within a range of 3 μmΦ to 100 μmΦ, for example. An insulating film such as SiO₂ or SiN may be formed on the side wall of the through electrode 427.

Next, a bump electrode 437 connected to the wiring 417 is formed on the support substrate 428. The bump electrode 437 can be used as an external terminal for connection with a mounting substrate on which the photodetection element 1700 is mounted. The bump electrode 437 may be a solder ball.

Next, the laminated wafer of the semiconductor wafers 411′ and 412′ is singulated together with the embedding layer 418 in which the chip 1701 is embedded to form the photodetection element 1700 provided with the laminated structure of the chips 401, 402, and 1701. In this singulation, blade dicing may be used.

As described above, in the 19th embodiment described above, the functional films 1712 and 1713 different from each other are formed on the bottom surface, the side surface, and the front surface of the embedded member 1711 embedded in the semiconductor substrate 413 of the chip 1701 embedded in the embedding layer 418. As a result, it is possible to secure the suitability of the embedded member 1711 while alleviating non-uniformity of stress applied to the chip 1701 due to the through electrode 427, and it is possible to improve the characteristics and reliability of the chip 1701.

Note that in the 12th to 19th embodiments described above, the chip 403 embedded in the embedding layer 418 in which the through electrode 427 is embedded is laminated on the chip 402, and the chip 402 is laminated on the chip 401. The configuration in which the embedded member 1011 is embedded in the chip 403 embedded in the embedding layer 418 in which the through electrode 427 is embedded may be applied to a photodetection element without the chips 401 and 402.

### 20. 20th Embodiment

In the sixth embodiment described above, the through electrodes 427 and 457 are extended to the outside via the embedding layer 418 in which the chips 403 and 404 mounted face down on the back surface wiring layer 446 of the chip 402 laminated on the chip 401 are embedded. In a 20th embodiment, a part of a through electrode embedded in an embedding layer 418 in which chips 403 and 404 are embedded is configured by a pillar electrode.

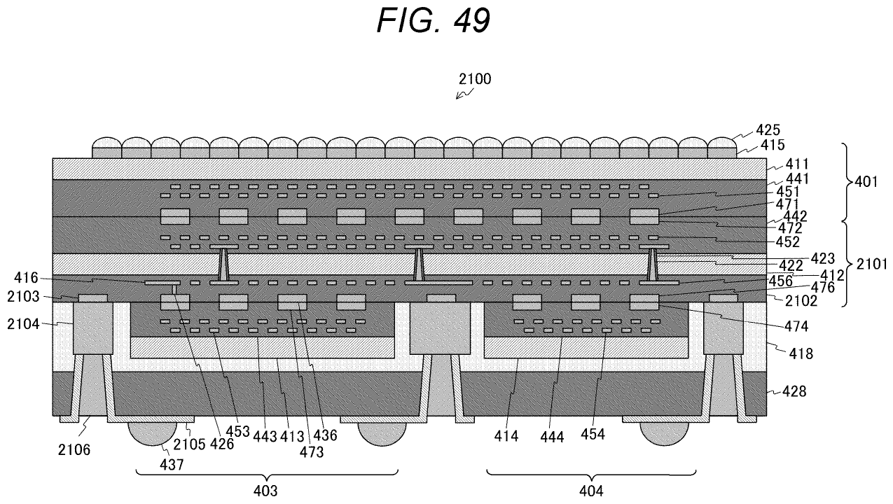

FIG. 49 is a cross-sectional view illustrating a configuration example of a photodetection element according to the 20th embodiment.

In FIG. 49, a photodetection element 2100 includes a chip 2101 instead of the chip 402 of the sixth embodiment described above. In addition, the photodetection element 2100 includes a wiring 2105 and a through electrode 2106 instead of the wirings 417 and 447 and the through electrodes 427 and 457 of the sixth embodiment described above. In addition, in the photodetection element 2100, a pillar electrode 2104 is added to the photodetection element 400 of the sixth embodiment described above. Therefore, warpage or the like due to a difference in thermal expansion coefficient in the laminated structure of the photodetection element 2100 can be more favorably curbed. Other configurations of the photodetection element 2100 of the 20th embodiment are similar to the configurations of the photodetection element 400 of the sixth embodiment described above.

The chip 2101 includes a back surface wiring layer 2102 instead of the back surface wiring layer 446 of the sixth embodiment described above. Other configurations of the chip 2101 are similar to the configurations of the chip 402 of the sixth embodiment described above.

In the back surface wiring layer 2102, a pad electrode 2103 is added to the back surface wiring layer 446 of the sixth embodiment described above. Other configurations of the back surface wiring layer 2102 are similar to the configurations of the back surface wiring layer 446 of the sixth embodiment described above.

The pad electrode 2103 is bonded to the pillar electrode 2104. The pad electrode 2103 can include the same material as a pad electrode 474. At this time, the pad electrode 2103 and the pillar electrode 2104 can be bonded simultaneously with the bonding between the pad electrode 436 and a pad electrode 437. For example, the pad electrode 2103 and the pillar electrode 2104 may be directly bonded on the basis of Cu—Cu bonding.

The pillar electrode 2104 is embedded in the embedding layer 418 so as to be separated from the chips 403 and 404. At this time, the pillar electrode 2104 can be bonded to the pad electrode 2103. The height of the pillar electrode 2104 can be made smaller than the thickness of the embedding layer 418. As a result, it is possible to prevent the pillar electrode 2104 from being exposed from the embedding layer 418 at the time of planarizing the embedding layer 418, and it is possible to prevent metal contamination by the pillar electrode 2104. As a material of the pillar electrode 2104, for example, Cu can be used. The pillar electrode 2104 can be formed before formation of the embedding layer 418. Therefore, the need for processing of the embedding layer 418 to form the pillar electrode 2104 can be eliminated.

The through electrode 2106 penetrates the embedding layer 418 and the support substrate 428 at the position of the pillar electrode 2104, and is electrically connected to the back surface wiring layer 2102 via the pillar electrode 2104. At this time, the depth of the through hole of the embedding layer 418 through which the through electrode 2106 penetrates can be made smaller than the thickness of the embedding layer 418.

The wiring 2105 is formed on the support substrate 428. The wiring 2105 is connected to the through electrode 2106. At this time, the wiring 2105 can be formed on the support substrate 428 so as to cover the side surface of the through hole in which the through electrode 2106 is embedded.

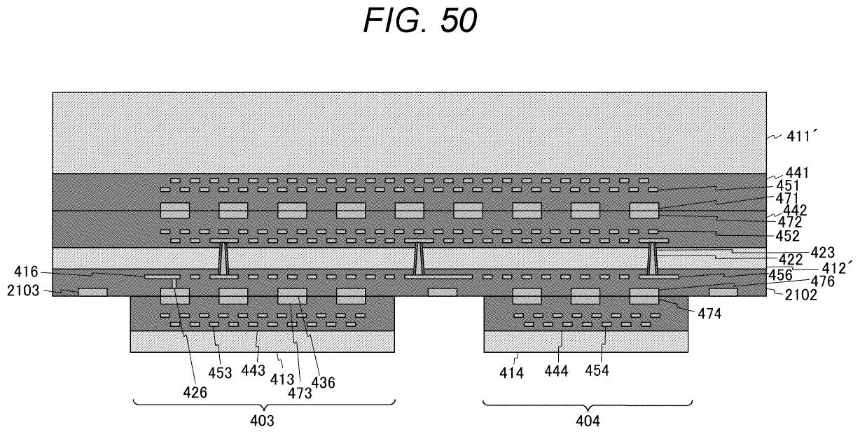

FIGS. 50 to 58 are cross-sectional views illustrating an example of a method of manufacturing the photodetection element according to the 20th embodiment.

In FIG. 50, a pixel array unit and peripheral circuits are formed on a semiconductor wafer 411′ for each section into which a chip 401 is cut out. Next, a wiring layer 441 provided with a wiring 451 and a pad electrode 471 is formed on the semiconductor wafer 411′.

In addition, a semiconductor element such as a transistor is formed on a semiconductor wafer 412′ for each section into which a chip 2101 is cut out. Next, a wiring layer 442 provided with a wiring 452 and a pad electrode 472 is formed on the semiconductor wafer 412′.

Next, the wiring layer 441 and the wiring layer 442 are directly bonded such that pad electrodes 471 and 472 face each other.

Next, the semiconductor wafer 412′ is thinned from the back surface side. Then, a through via 422 is embedded in the semiconductor wafer 412′ so as to be electrically connected to the wiring 452. An insulating layer 423 may cover the periphery of the through via 422 to insulate the through via 422 from the semiconductor wafer 412′.

Next, a back surface wiring layer 2102 provided with a back surface wiring 416, pad electrodes 436 and 2103, and back surface wirings 416 and 456 is formed on the back surface side of the semiconductor wafer 412′. At this time, the through via 422 can be electrically connected to the back surface wiring 456.

Next, a semiconductor wafer divided into the individual chips 403 and 404 is prepared. Then, wiring layers 443 and 444 are directly bonded to the back surface wiring layer 2102 such that the wiring layers 443 and 444 face the back surface wiring layer 2102. Then, the semiconductor wafer directly bonded to the back surface wiring layer 2102 is divided into individual chips 403 and 404.

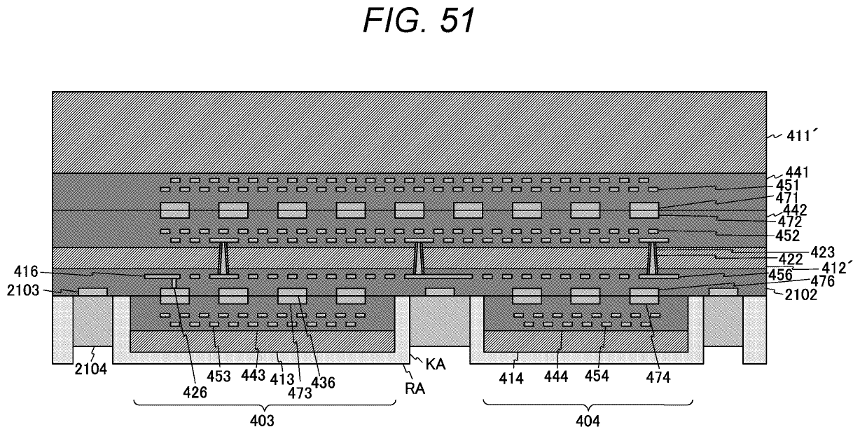

Next, as illustrated in FIG. 51, a resist pattern RA provided with an opening KA is formed on the back surface wiring layer 2102 on the basis of a photolithography technique. The opening KA can be arranged at a position where the pillar electrode 2104 is formed. Then, the pillar electrode 2104 is formed in the opening KA by a method such as plating. At this time, the pillar electrode 2104 may be formed by a semi-additive method.

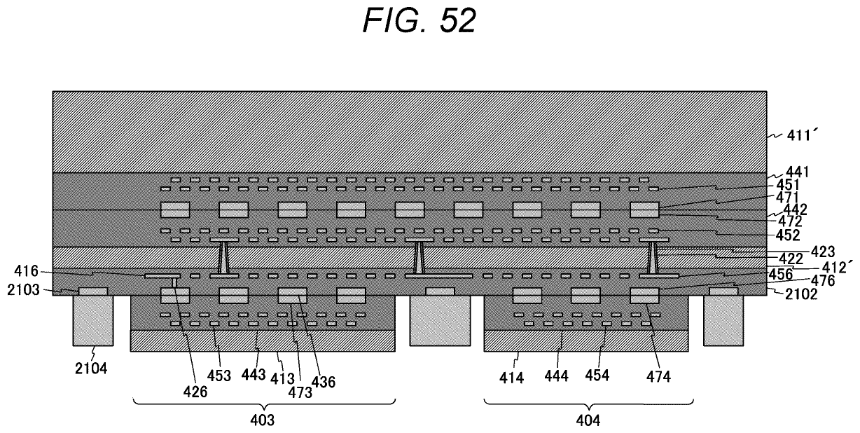

Next, as illustrated in FIG. 52, the resist pattern RA is removed from the back surface wiring layer 2102 by a method such as ashing.

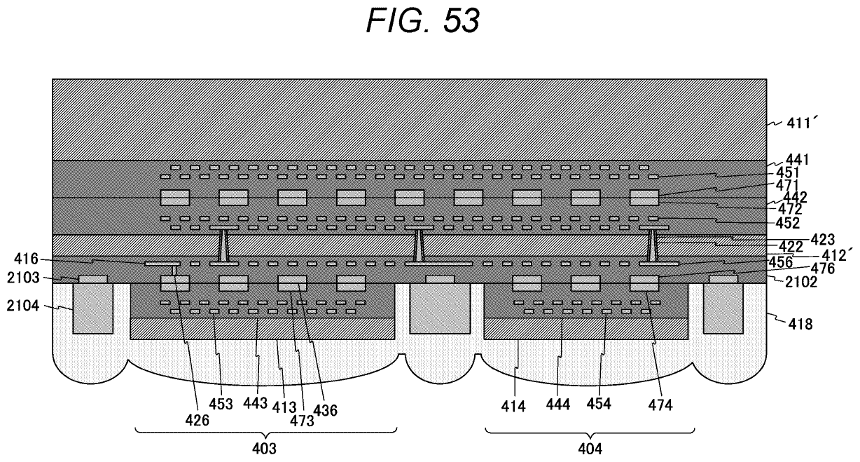

Next, as illustrated in FIG. 53, the embedding layer 418 is deposited on the back surface wiring layer 2102 so that the chips 403, 404 and the pillar electrodes 2104 are covered by a method such as CVD.

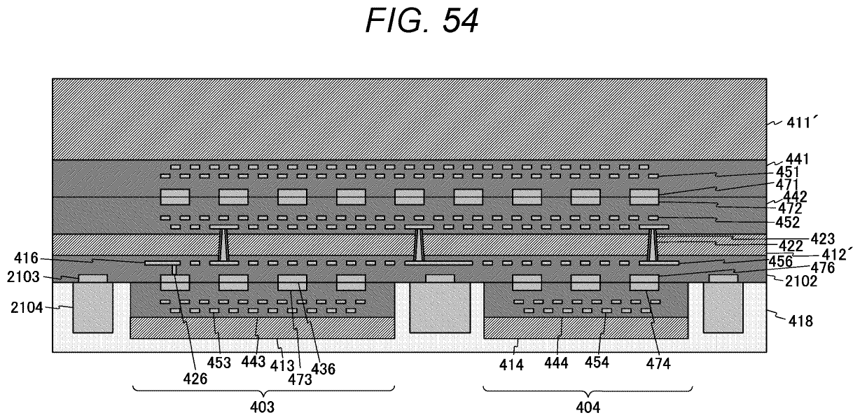

Next, as illustrated in FIG. 54, the embedding layer 418 is thinned by a method such as CMP so that the embedding layer 418 is planarized.

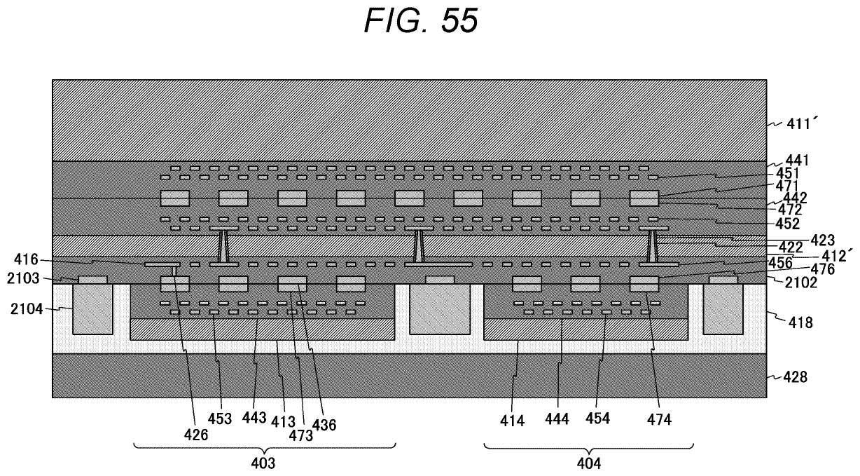

Next, as illustrated in FIG. 55, the support substrate 428 is bonded onto the embedding layer 418. An adhesive may be used for bonding the support substrate 428.

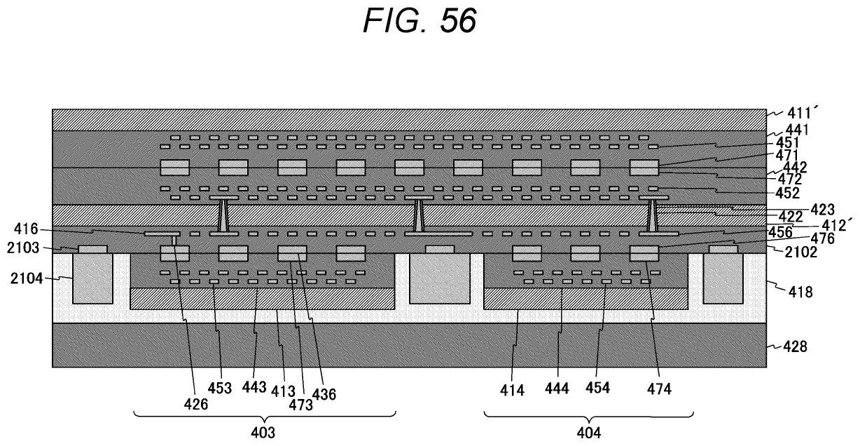

Next, as illustrated in FIG. 56, the semiconductor wafer 411′ is thinned by a method such as CMP.

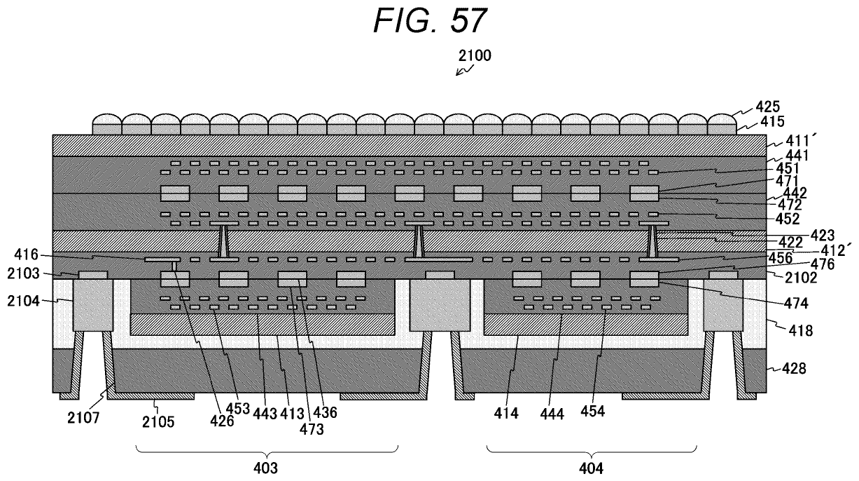

Next, as illustrated in FIG. 57, a color filter 415 is formed for each pixel on the back surface side of the semiconductor wafer 411′. Moreover, an on-chip lens 425 is formed on the color filter 415 for each pixel.

Then, a through hole 2107 reaching the pillar electrode 2104 is formed in the support substrate 428 and the embedding layer 418. The through hole 2107 can be formed at a position where the through electrode 2106 is embedded. Then, the wiring 2105 is formed on the support substrate 428 so as to cover the side surface of the through hole 2107.

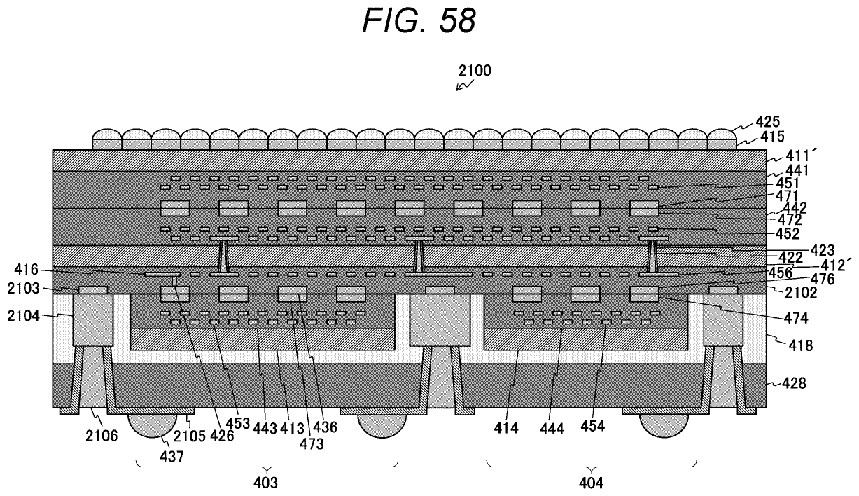

Next, as illustrated in FIG. 58, the through electrode 2106 that penetrates the support substrate 428 and the embedding layer 418 and is connected to the pillar electrode 2104 is formed in the through hole 2107. Then, a bump electrode 437 connected to the wiring 2105 is formed on the support substrate 428.

Next, as illustrated in FIG. 49, the laminated wafer of the semiconductor wafers 411′ and 412′ is singulated together with the embedding layer 418 in which the chips 403 and 404 are embedded to form the photodetection element 2100 provided with the laminated structure of the chips 401, 2101, 403, and 404. In this singulation, blade dicing may be used.

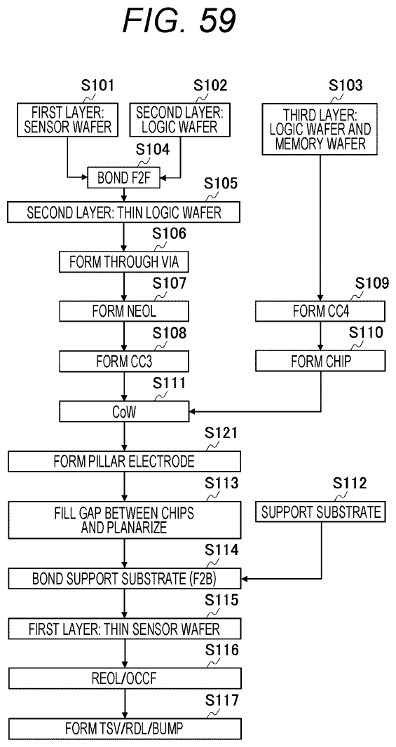

FIG. 59 is a flowchart illustrating an example of a method of manufacturing the photodetection element according to the 20th embodiment. Note that in the following description, an example is illustrated in which the chip 401 is a sensor chip, the chips 2101 and 403 are logic chips, and the chip 404 is a memory chip.

In FIG. 59, a sensor wafer of a first layer, a logic wafer of a second layer, a logic wafer and a memory wafer of a third layer, are prepared (S101 to S103). In addition, a support substrate is prepared (S112). In the sensor wafer, a sensor is formed for each chip. In the logic wafer, a logic circuit is formed for each chip. In the memory wafer, a memory is formed for each chip.

Next, the sensor wafer of the first layer and the logic wafer of the second layer are F2F bonded (S104). In the F2F bonding, the front surface of the sensor wafer and the front surface of the logic wafer are bonded.

Next, the logic wafer of the second layer is thinned from the back surface side (S105).

Next, a through via penetrating the semiconductor layer of the logic wafer of the second layer is formed (S106).

Next, NEOL formation is performed (S107). In the NEOL formation, a wiring layer connected to the through via formed in the logic wafer of the second layer is formed on the back surface side of the logic wafer (S107).

Next, CC3 formation is performed (S108). In the CC3 formation, a Cu electrode used for Cu—Cu bonding with the logic wafer and the memory wafer of the third layer is formed on the logic wafer of the second layer.

Additionally, CC4 formation is performed (S109). In the CC4 formation, a Cu electrode used for Cu—Cu bonding with the logic wafer of the second layer is formed on the logic wafer and the memory wafer of the third layer.

Next, the logic wafer and the memory wafer of the third layer are formed into chips, and a logic chip and a memory chip of the third layer are formed (S110).

Next, CoW is performed (S111). In the Cow, the logic chip and the memory chip of the third layer are bonded to the logic wafer of the second layer.

Next, a pillar electrode is formed on the logic wafer of the second layer so as to be separated from the logic chip and the memory chip of the third layer (S121).

Next, an embedding layer is formed on the logic wafer of the second layer so that the logic chip and the memory chip of the third layer are embedded therein, and the embedding layer is planarized (S113).

Next, a support substrate is bonded to the embedding layer in which the logic chip and the memory chip of the third layer are embedded (S114).

Next, the sensor wafer of the first layer is thinned from the back surface side (S115).

Next, REOL/OCCF is performed (S116). In the REOL/OCCF, a pixel separation layer or the like is formed on the back surface side of the sensor wafer. Thereafter, after a color filter is formed for each pixel on the back surface side of the sensor wafer, an on-chip lens is formed for each pixel on the color filter.

Next, TSV/RDL/bump formation is performed (S117). In the TSV/RDL/bump formation, a through electrode connected to a pillar electrode is formed in the embedding layer in which the logic chip and the memory chip of the third layer are embedded. Then, after a redistribution line connected to the through electrode is formed on the embedding layer, a bump electrode connected to the redistribution line is formed.

As described above, in the 20th embodiment described above, a part of the through electrode 2106 embedded in the embedding layer 418 in which the chips 403 and 404 are embedded is configured by the pillar electrode 2104. As a result, the depth of the through hole of the embedding layer 418 through which the through electrode 2106 penetrates can be made smaller than the thickness of the embedding layer 418, and the load on the formation of the through electrode 2106 can be reduced.

### 21. 21st Embodiment

In the 20th embodiment described above, a part of the through electrode 2106 embedded in the embedding layer 418 in which the chips 403 and 404 are embedded is configured by the pillar electrode 2104. In a 21st embodiment, a through electrode penetrating a dummy chip having a wiring layer embedded in the embedding layer 418 in which the chips 403 and 404 are embedded is provided.

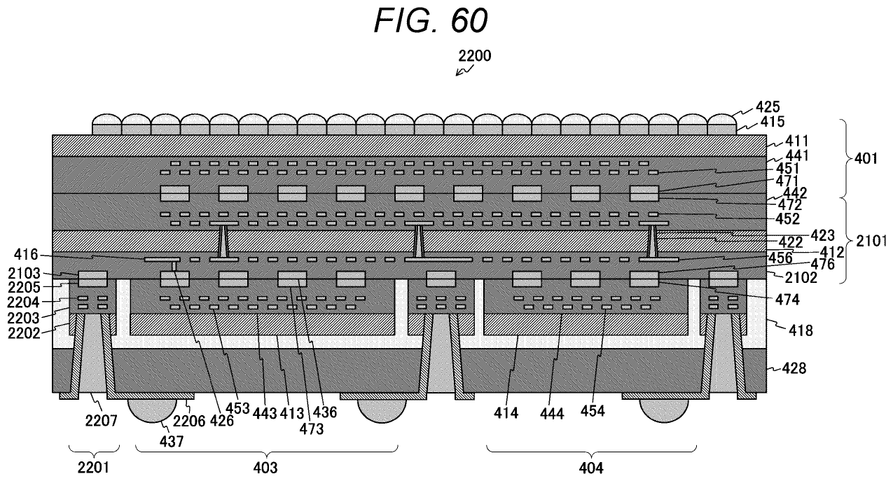

FIG. 60 is a cross-sectional view illustrating a configuration example of a photodetection element according to the 21st embodiment.

In FIG. 60, a photodetection element 2200 includes a dummy chip 2201 instead of the pillar electrode 2104 of the 20th embodiment described above. In addition, the photodetection element 2200 includes a wiring 2206 and a through electrode 2207 instead of the wiring 2105 and the through electrode 2106 of the 20th embodiment described above. Other configurations of the photodetection element 2200 of the 21st embodiment are similar to the configurations of the photodetection element 2100 of the 20th embodiment described above. Note that also in this case, as in the case of the photodetection element 2100, warpage or the like due to a difference in thermal expansion coefficient in the laminated structure of the photodetection element 2200 can be more favorably curbed.

The dummy chip 2201 is embedded in the embedding layer 418 so as to be separated from the chips 403 and 404. At this time, the dummy chip 2201 can be directly bonded to a back surface wiring layer 2102. Here, the dummy chip 2201 can be mounted face down on the back surface wiring layer 2102 of a chip 2101.

The dummy chip 2201 includes a dummy substrate 2202 and a dummy wiring layer 2203. The dummy wiring layer 2203 is formed on the front surface side of the dummy substrate 2202. The dummy wiring layer 2203 is provided with a dummy wiring 2204 embedded in the insulating layer and a pad electrode 2205. The pad electrode 2205 can be used for direct bonding of the front surface side of the dummy chip 2201. For example, the dummy chip 2201 may be directly bonded to the chip 2101 by hybrid bonding. At this time, the pad electrode 2205 can be bonded to the pad electrode 2103 on the basis of Cu—Cu bonding.

The through electrode 2207 penetrates the dummy substrate 2202, the embedding layer 418, and a support substrate 428 at the position of the dummy chip 2201 and is electrically connected to the dummy wiring layer 2203. At this time, the depth of the through hole of the embedding layer 418 through which the through electrode 2207 penetrates can be made smaller than the thickness of the embedding layer 418.

The wiring 2206 is formed on the support substrate 428. The wiring 2206 is connected to the through electrode 2207. At this time, the wiring 2206 can be formed on the support substrate 428 so as to cover the side surface of the through hole in which the through electrode 2207 is embedded.

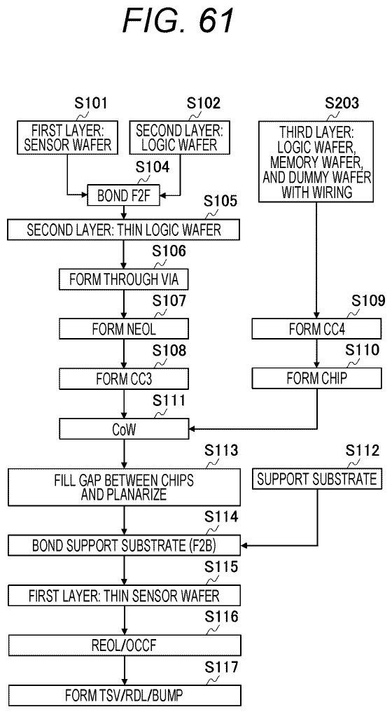

FIG. 61 is a flowchart illustrating an example of a method of manufacturing the photodetection element according to the 21st embodiment.

In FIG. 61, in this manufacturing method, step S203 is provided instead of step S103 of the 20th embodiment described above. In step S203, a dummy wafer with wiring is prepared in addition to the logic wafer and the memory wafer of the third layer. At this time, in step S109, the Cu electrode used for the Cu—Cu bonding with the logic wafer of the second layer is formed not only on the logic wafer and the memory wafer of the third layer but also on the dummy wafer with wiring. In addition, in step S110, not only the logic chip and the memory chip of the third layer but also the dummy chip with wiring is formed.

In addition, in this manufacturing method, step S121 of the 20th embodiment described above is omitted. At this time, in step S117, a through electrode connected to the wiring of the dummy chip with wiring is formed in the embedding layer in which the logic chip and the memory chip of the third layer are embedded and the semiconductor layer of the dummy chip with wiring.

As described above, in the 21st embodiment described above, the through electrode 2207 that penetrates the dummy substrate 2202 of the dummy chip 2201 having the dummy wiring layer 2203 embedded in the embedding layer 418 is provided. As a result, the depth of the through hole of the embedding layer 418 through which the through electrode 2207 penetrates can be made smaller than the thickness of the embedding layer 418, and the load on the formation of the through electrode 2207 can be reduced.

### 22. 22nd Embodiment

In the 21st embodiment described above, the through electrode 2207 penetrating the semiconductor layer 2202 of the dummy chip 2201 having the dummy wiring layer 2203 embedded in the embedding layer 418 is provided. In a 22nd embodiment, a through electrode penetrating a dummy chip having no wiring layer embedded in an embedding layer 418 is provided.

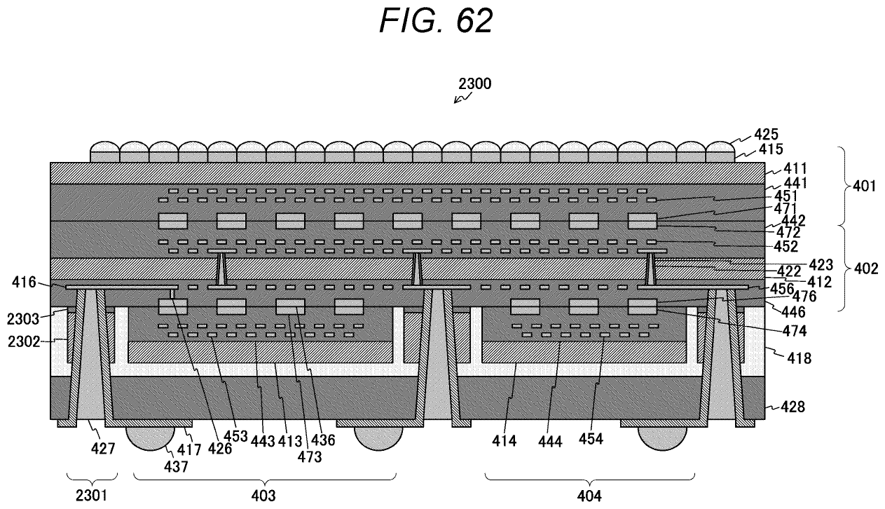

FIG. 62 is a cross-sectional view illustrating a configuration example of a photodetection element according to the 22nd embodiment.

In FIG. 62, in a photodetection element 2300, a dummy chip 2301 is added to the photodetection element 400 of the sixth embodiment described above. Other configurations of the photodetection element 2300 of the 22nd embodiment are similar to the configurations of the photodetection element 400 of the sixth embodiment described above. Note that also in this case, as in the case of the photodetection element 2100, warpage or the like due to a difference in thermal expansion coefficient in the laminated structure of the photodetection element 2300 can be more favorably curbed.

The dummy chip 2301 is embedded in the embedding layer 418 so as to be separated from the chips 403 and 404. At this time, the dummy chip 2301 can be directly bonded to a back surface wiring layer 446.

The dummy chip 2301 includes a semiconductor layer 2302 and an insulating layer 2303. The insulating layer 2303 can be used for direct bonding of the front surface side of the dummy chip 2301.

A through electrode 427 penetrates the dummy chip 2301, the embedding layer 418, and a support substrate 428, and is electrically connected to the wiring layer 446. At this time, the depth of the through hole of the embedding layer 418 through which the through electrode 427 penetrates can be made smaller than the thickness of the embedding layer 418.

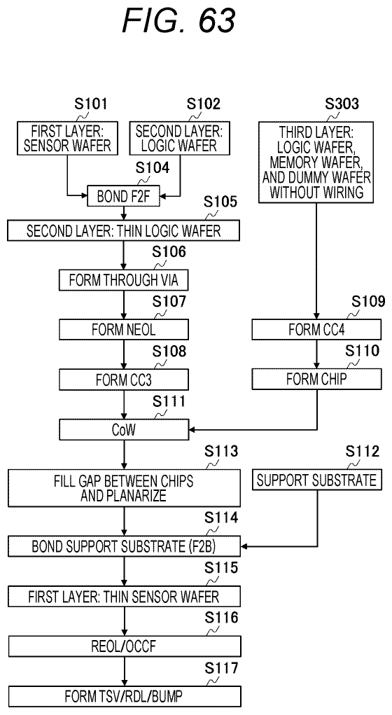

FIG. 63 is a flowchart illustrating an example of a method of manufacturing the photodetection element according to the 22nd embodiment.

In FIG. 63, in this manufacturing method, step S303 is provided instead of step S103 of the 20th embodiment described above. In step S303, a dummy wafer without wiring is prepared in addition to the logic wafer and the memory wafer of the third layer. At this time, in step S109, the Cu electrode used for the Cu—Cu bonding with the logic wafer of the second layer is formed not only on the logic wafer and the memory wafer of the third layer but also on the dummy wafer without wiring. In addition, in step S110, not only the logic chip and the memory chip of the third layer but also the dummy chip without wiring is formed. In addition, in step S117, a through electrode connected to the logic chip of the second layer is formed in the embedding layer in which the logic chip and the memory chip of the third layer are embedded and the dummy chip without wiring.

As described above, in the 22nd embodiment described above, the through electrode 427 penetrating the dummy chip 2301 having no wiring layer embedded in the embedding layer 418 is provided. As a result, the depth of the through hole formed in the embedding layer 418 can be made smaller than the thickness of the embedding layer 418, and the load on the processing of the embedding layer 418 can be reduced. At this time, the dry etching time for forming the through hole in the embedding layer 418 can be shortened. In addition, it is not necessary to form a wiring layer on the dummy chip 2301, and the manufacturing cost of the dummy chip 2301 can be reduced.

### 23. 23rd Embodiment

In the 22nd embodiment described above, the through electrode 427 penetrating the dummy chip 2301 having no wiring layer embedded in the embedding layer 418 is provided. In a 23rd embodiment, a through electrode penetrating a dummy chip embedded in an embedding layer also penetrates a semiconductor layer of a chip laminated on the embedding layer and is connected to a wiring layer.

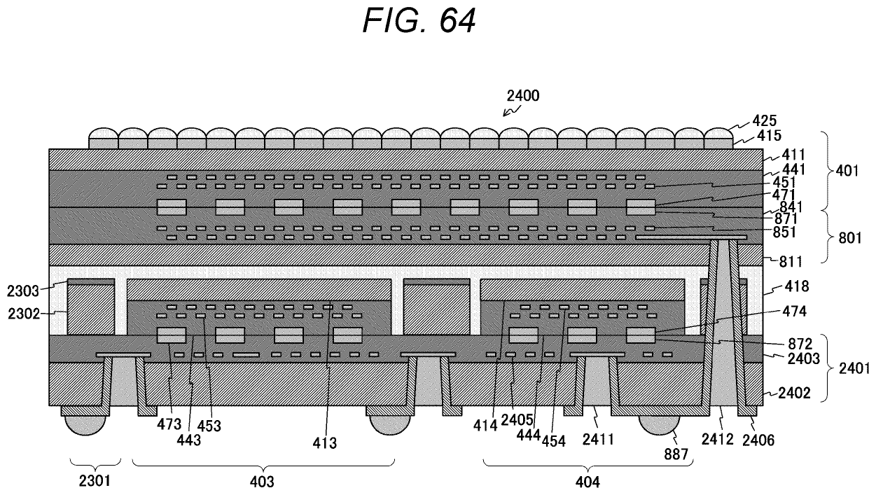

FIG. 64 is a cross-sectional view illustrating a configuration example of a photodetection element according to the 23rd embodiment.

In FIG. 64, a photodetection element 2400 includes a chip 2401 instead of the chip 802 of the 10th embodiment described above. In addition, in the photodetection element 2400, a dummy chip 2301 is added to the photodetection element 800 of the 10th embodiment described above. Other configurations of the photodetection element 2400 of the 24th embodiment are similar to the configurations of the photodetection element 800 of the 10th embodiment described above.

The chip 2401 is arranged in the lowermost layer of the photodetection element 2400. The planar size and shape of the chip 2401 can be equal to those of a chip 401. The chip 2401 includes a semiconductor layer 2402 and a wiring layer 2403.

The wiring layer 2403 is formed on the front surface side of the semiconductor layer 2402. In the wiring layer 2403, a wiring 2405 is formed instead of the wiring 852 of the 10th embodiment described above. Other configurations of the wiring layer 2403 are similar to the configurations of the wiring layer 842 of the 10th embodiment described above.

The dummy chip 2301 is bonded onto the wiring layer 2403. The dummy chip 2301 may be directly bonded onto the wiring layer 2403. Further, on the wiring layer 2403, an embedding layer 418 is laminated so that chips 403 and 404 are embedded therein. The dummy chip 2301 is embedded in the embedding layer 418.

A through electrode 2411 penetrates the semiconductor layer 2402, is electrically connected to the wiring layer 2403, and is extended to the back surface side of the chip 2401. In order to insulate the through electrode 2411 from the semiconductor layer 2402, an insulating layer may be formed so as to surround the outer periphery of the through electrode 2411. Here, by providing the through electrode 2411, a wiring path for connecting the chips 403 and 404 to the external terminal can be shortened, and data transmission can be speeded up.

The length of a through electrode 2412 is longer than the length of the through electrode 2411. At this time, the through electrode 2412 penetrates the chip 2401, the dummy chip 2301, the embedding layer 418, and the semiconductor layer 811, is electrically connected to a wiring layer 841, and is extended to the back surface side of the chip 2401. In order to insulate the through electrode 2412 from the semiconductor layers 811 and 2402, an insulating layer may be formed so as to surround the outer periphery of the through electrode 2412. Here, by providing the through electrode 2412, a wiring path for connecting a chip 801 to the external terminal can be shortened, and data transmission can be speeded up.

On the back surface side of the semiconductor layer 2402, a wiring 2406 is formed via an insulating layer. The wiring 2406 is connected to the through electrodes 2411 and 2412. At this time, the wiring 2406 may be formed so as to surround the outer periphery of each of the through electrodes 2411 and 2412. A bump electrode 887 is formed on the wiring 2406.

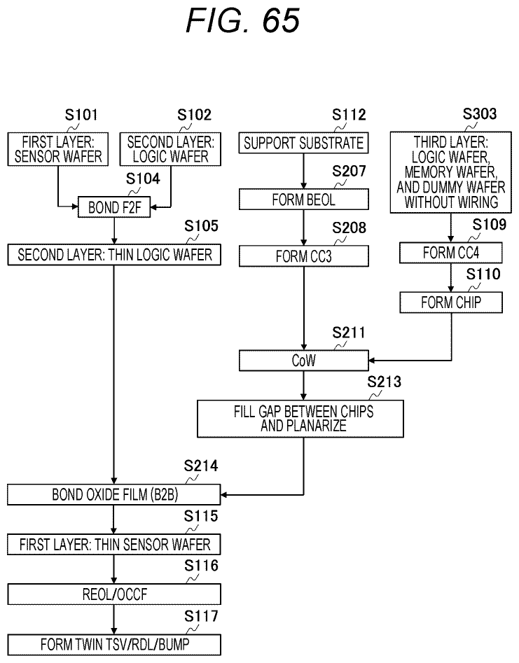

FIG. 65 is a flowchart illustrating an example of a method of manufacturing the photodetection element according to the 23rd embodiment.

In FIG. 65, in this manufacturing method, steps S207, S208, S211, S213, and S214 are provided instead of steps S106, S107, S108, S111, S113, and S114 of the 22nd embodiment described above.

In step S207, BEOL formation is performed (S107). In the BEOL formation, a wiring layer is formed on the support substrate.

Next, CC3 formation is performed (S208). In the CC3 formation, a Cu electrode used for Cu—Cu bonding with the logic wafer and the memory wafer of the third layer is formed on the wiring layer of the support substrate.

Next, CoW is performed (S211). In the Cow, the logic chip and the memory chip of the third layer are bonded to the support substrate.

Next, an embedding layer is formed on the wiring layer of the support substrate so that the logic chip and the memory chip of the third layer are embedded, and the embedding layer is planarized (S213).

Next, the logic wafer of the second layer is bonded to the embedding layer in which the logic chip and the memory chip of the third layer are embedded (S214), and the process proceeds to step S115. In such bonding, oxide film bonding may be used. In the oxide film bonding, bonding can be performed via an oxide film provided on the bonding surface.

As described above, in the 23rd embodiment described above, the through electrode 2412 penetrating the dummy chip 2301 embedded in the embedding layer 418 also penetrates the semiconductor layer 811 laminated on the embedding layer 418 and is connected to the wiring layer 841. As a result, the depth of the through hole formed in the embedding layer 418 can be made smaller than the thickness of the embedding layer 418, and the load on the processing of the embedding layer 418 can be reduced. At this time, the dry etching time for forming the through hole in the embedding layer 418 can be shortened.

### 24. 24th Embodiment

In the 23rd embodiment described above, the through electrode 2412 penetrating the dummy chip 2301 embedded in the embedding layer 418 also penetrates the semiconductor layer 811 laminated on the embedding layer 418 and is connected to the wiring layer 841. In a 24th embodiment, a through electrode penetrating a dummy chip 2301 embedded in the embedding layer 418 is connected to the wiring layer 841 via a through via embedded in a chip laminated on the embedding layer 418.

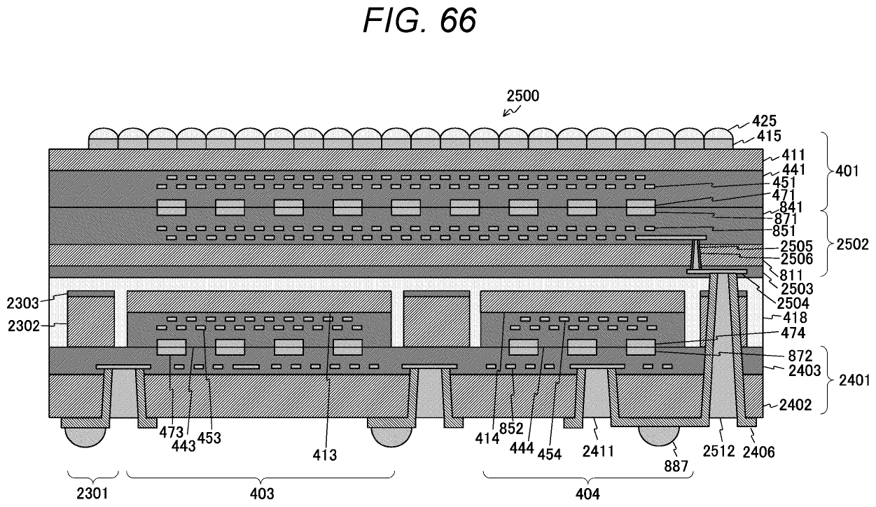

FIG. 66 is a cross-sectional view illustrating a configuration example of a photodetection element according to the 24th embodiment.

In FIG. 66, a photodetection element 2500 includes a chip 2502 instead of the chip 801 of the 23rd embodiment described above. Other configurations of the photodetection element 2500 of the 24th embodiment are similar to the configurations of the photodetection element 2400 of the 23rd embodiment described above.

The chip 2502 is laminated on the chip 401. The planar size and shape of the chip 2502 can be equal to those of the chip 401. In the chip 2502, a back surface wiring layer 2503 and a through via 2505 are added to the chip 801 of the 23rd embodiment described above.

The back surface wiring layer 2503 is formed on the back surface side of a semiconductor layer 811. A back surface wiring 2504 embedded in the insulating layer is provided on the back surface wiring layer 2503. At this time, a through electrode 2512 penetrates a chip 2401, the dummy chip 2301, and the embedding layer 418, is electrically connected to the back surface wiring layer 2503, and is extended to the back surface side of the chip 2401. In order to insulate the through electrode 2512 from a semiconductor layer 2402, an insulating layer may be formed so as to surround the outer periphery of the through electrode 2512.

The through via 2505 is embedded in the semiconductor layer 811. The through via 2505 penetrates the semiconductor layer 811 of the chip 2502 and can establish conduction between the wiring layer 841 and the back surface wiring layer 2503. In order to insulate the through via 2505 from the semiconductor layer 811, an insulating layer 2506 may be formed around the through via 2505. At this time, the through electrode 2512 is connected to the wiring layer 841 of the chip 2502 via the back surface wiring 2504 and the through via 2505.

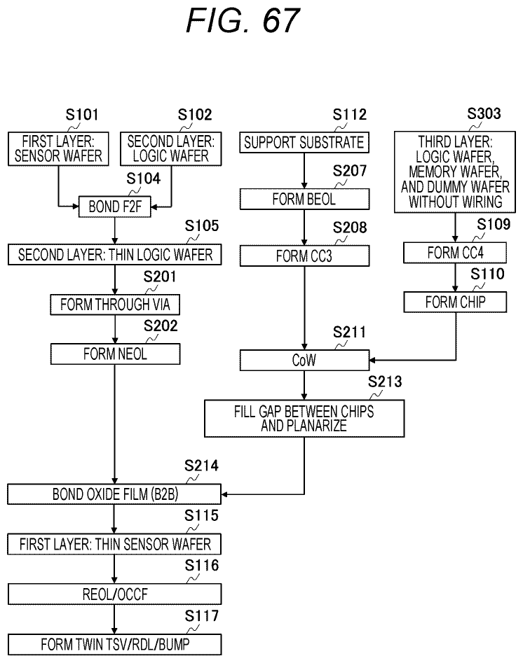

FIG. 67 is a flowchart illustrating an example of a method of manufacturing the photodetection element according to the 24th embodiment.

In FIG. 67, in this manufacturing method, steps S201 and S202 are added to the manufacturing method of the 23rd embodiment described above. In step S201, after the logic wafer of the second layer is thinned, a through via penetrating the semiconductor layer of the logic wafer of the second layer is formed.

Next, in step S202, NEOL formation is performed. In the NEOL formation, a back surface wiring layer connected to the through via formed in the logic wafer of the second layer is formed on the back surface side of the logic wafer, and the process proceeds to step S214.

As described above, in the 24th embodiment described above, the through electrode 2512 penetrating the dummy chip 2301 embedded in the embedding layer 418 is connected to the wiring layer 841 via the through via 2505 embedded in the chip 2502 on the embedding layer 418. As a result, the depth of the through hole formed in the embedding layer 418 can be made smaller than the thickness of the embedding layer 418, and the load on the processing of the embedding layer 418 can be reduced. At this time, the dry etching time for forming the through hole in the embedding layer 418 can be shortened. In addition, in order to connect the through electrode 2512 to the wiring layer 841 of the chip 2502, it is not necessary to embed the through electrode 2512 in the semiconductor layer 811. Therefore, it is possible to facilitate processing of the through hole of the through electrode 2512 and to improve the stability of the shape of the through electrode 2512.

### 25. 25th Embodiment

In the 24th embodiment described above, the through electrode 2512 penetrating the dummy chip 2301 embedded in the embedding layer 418 is connected to the wiring layer 841 via the through via 2505 embedded in the chip 2502 on the embedding layer 418. In a 25th embodiment, a through electrode 2512 penetrating an embedding layer 418 is connected to a wiring layer 841 via a through via 2505 embedded in a chip 2502 on the embedding layer 418.

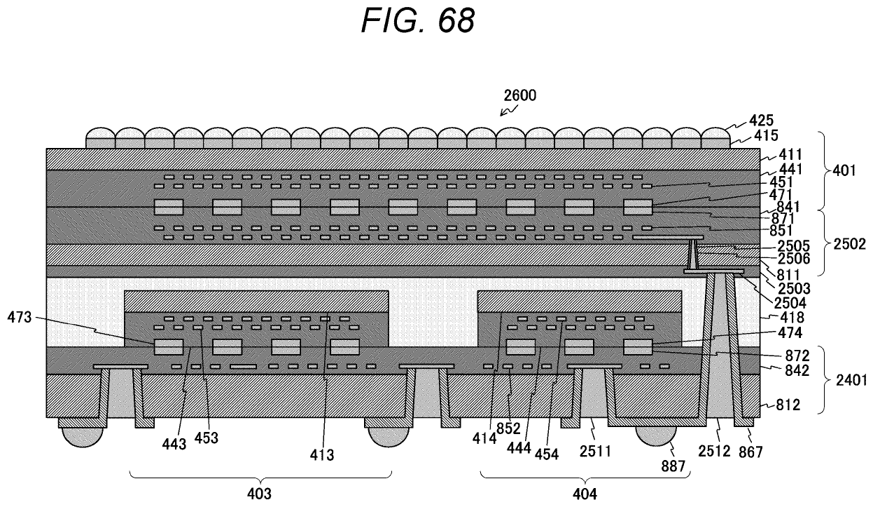

FIG. 68 is a cross-sectional view illustrating a configuration example of a photodetection element according to the 25th embodiment.

In FIG. 68, the dummy chip 2301 of the 24th embodiment described above is removed from a photodetection element 2600. At this time, the through electrode 2512 penetrates a chip 2401 and the embedding layer 418 and is connected to the wiring layer 841 of the chip 2502 via a back surface wiring 2504 and the through via 2505. Other configurations of the photodetection element 2600 of the 25th embodiment are similar to the configurations of the photodetection element 2500 of the 24th embodiment described above.

As described above, in the 25th embodiment described above, the through electrode 2512 penetrating the embedding layer 418 is connected to the wiring layer 841 via the through via 2505 embedded in the chip 2502 on the embedding layer 418. This eliminates the need to embed the through electrode 2512 in the semiconductor layer 811 in order to connect the through electrode 2512 to the wiring layer 841 of the chip 2502. Therefore, it is possible to facilitate processing of the through hole of the through electrode 2512 and to improve the stability of the shape of the through electrode 2512.

### 26. Example of Application to Mobile Object

The technology according to the present disclosure (present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

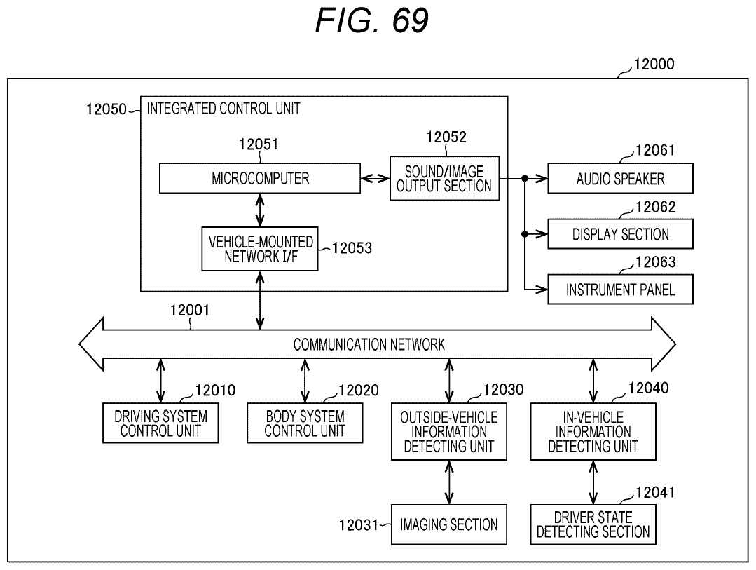

FIG. 69 is a block diagram illustrating a schematic configuration example of a vehicle control system as an example of a mobile object control system to which the technology according to the present disclosure can be applied.

The vehicle control system 12000 includes a plurality of electronic control units connected to each other via a communication network 12001. In the example illustrated in FIG. 69, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 69, an audio speaker 12061, a display section 12062, and an instrument panel 12063 are illustrated as the output device. The display section 12062 may, for example, include at least one of an on-board display and a head-up display.

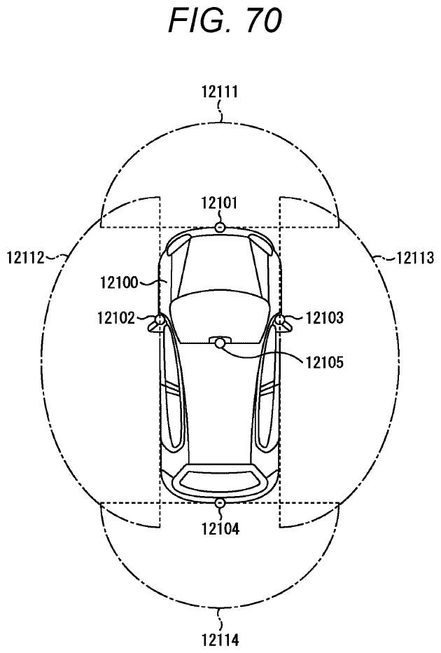

FIG. 70 is a diagram illustrating an example of the installation position of the imaging section 12031.

In FIG. 70, the imaging section 12031 includes imaging sections 12101, 12102, 12103, 12104, and 12105.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 70 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is not only applicable to the imaging section 12031 and the driver state detecting section 12041 in the above-described configuration, but can also realize at least some functions of the electronic control unit. Specifically, for example, the above-described photodetection elements 100 and 600 and the like can realize at least some functions of the electronic control unit while being applied to the imaging section 12031. By applying the technology according to the present disclosure to the vehicle control system 12000, it is possible to obtain a captured image while curbing an increase in the mounting area, and to realize at least some functions of vehicle control.

Note that the embodiments described above show examples for embodying the present technology, and the matters in the embodiments and the matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the gist of the present technology. In addition, effects described in the present specification are merely examples and are not limited, and other effects may be provided.

Note that the present technology may also have the following configurations.

(1) A photodetection element including:
a first chip on which a first wiring layer is formed;
a second chip that is laminated on the first chip and on which a second wiring layer is formed;
a third chip that is arranged side by side with the second chip at an interval and laminated on the first chip, a third wiring layer being formed on the third chip;
an embedding layer that is laminated on the first chip so that the second chip and the third chip are embedded in the embedding layer; and
a through electrode that is located between the second chip and the third chip, penetrates the embedding layer, and is connected to the first wiring layer.

(2) The photodetection element according to (1), in which
the first wiring layer is directly bonded to the second wiring layer and the third wiring layer.

(3) The photodetection element according to (1) or (2), further including a support substrate provided on the embedding layer, in which
the through electrode penetrates the support substrate and the embedding layer and is connected to the first wiring layer.

(4) The photodetection element according to any one of (1) to (3), further including a sensor chip on which the first chip is laminated, and having a fourth wiring layer formed on a front surface side and a pixel formed on a back surface side.

(5) The photodetection element according to (4), in which:
the first wiring layer includes
a front surface wiring layer formed on a front surface side of the first chip, and
a back surface wiring layer formed on a back surface side of the first chip;
the front surface wiring layer is directly bonded to the fourth wiring layer;
the back surface wiring layer is directly bonded to the second wiring layer and the third wiring layer; and
the through electrode penetrates the embedding layer and is connected to the back surface wiring layer.

(6) The photodetection element according to (5), further including a transparent substrate provided on the sensor chip.

(7) The photodetection element according to (6), further including a cavity that separates an imaging region of the sensor chip from the transparent substrate.

(8) A photodetection element including:
a first chip on which a first wiring layer is formed;
a second chip that is laminated on the first chip and on which a second wiring layer is formed;
an embedding layer that is laminated on the first chip so that the second chip is embedded in the embedding layer;
a redistribution layer that is formed on the embedding layer; and
a through electrode that penetrates the embedding layer and connects the redistribution layer and the first wiring layer.

(9) A photodetection element including:
a first chip on which a first wiring layer is formed;
a second chip that is mounted face down on the first wiring layer and on which a second wiring layer is formed;
an embedding layer that is laminated on the first chip so that the second chip is embedded in the embedding layer; and
a first through electrode that penetrates the embedding layer and is connected to the second wiring layer via the first wiring layer.

(10) The photodetection element according to (9), further including a second through electrode that penetrates the embedding layer and is connected to the first wiring layer without interposing the second wiring layer.

(11) The photodetection element according to (9) or (10), in which
the first wiring layer is directly bonded to the second wiring layer.

(12) The photodetection element according to any one of (9) to (11), further including a sensor chip on which the first chip is laminated, and having a third wiring layer formed on a front surface side and a pixel formed on a back surface side.

(13) The photodetection element according to (12), in which:
the first wiring layer includes
a front surface wiring layer formed on a front surface side of the first chip, and
a back surface wiring layer formed on a back surface side of the first chip;
the front surface wiring layer is directly bonded to the third wiring layer;
the back surface wiring layer is directly bonded to the second wiring layer; and
the first through electrode penetrates the embedding layer and is connected to the second wiring layer via the back surface wiring layer.

(14) The photodetection element according to (13), further including a fourth chip that is laminated between the sensor chip and the first chip and on which a fourth wiring layer is formed.

(15) A photodetection element including:
a first chip on which a first wiring layer is formed;
a second chip that forms a laminated structure with the first chip and on which a second wiring layer is formed;
a third chip that forms a laminated structure with the first chip and the second chip and on which a third wiring layer is formed;
an embedding layer that forms a laminated structure with the first chip and the second chip so that the third chip is embedded in the embedding layer; and
a first through electrode that penetrates the embedding layer and is connected to the second wiring layer.

(16) The photodetection element according to (15), in which:
the first chip is located in a first layer, the second chip is located in a second layer, and the third chip is located in a third layer; and
the photodetection element further includes a second through electrode that penetrates the embedding layer, is connected to the third wiring layer, and is shorter in length than the first through electrode.

(17) The photodetection element according to (15), in which:
the first chip is located in a first layer, the second chip is located in a third layer, and the third chip is located in a second layer;
the photodetection element further includes a second through electrode that penetrates a semiconductor layer of the second chip, is connected to the second wiring layer, and is shorter in length than the first through electrode; and
the first through electrode penetrates the semiconductor layer of the second chip and the embedding layer and is connected to the second wiring layer.

(18) The photodetection element according to any one of (15) to (17), in which
at least a part of the first through electrode includes a pillar electrode.

(19) The photodetection element according to any one of (15) to (17), in which:
the second chip includes
a semiconductor layer on which the second wiring layer is formed, and
a through via that penetrates the semiconductor layer and is connected to the second wiring layer; and
the first through electrode penetrates the embedding layer and is connected to the second wiring layer via the through via.

(20) The photodetection element according to any one of (15) to (17), further including a dummy chip embedded in the embedding layer, in which
the first through electrode penetrates the embedding layer and the dummy chip, and is connected to the second wiring layer.

(21) The photodetection element according to any one of (15) to (17), in which
the second chip includes a semiconductor layer on which the second wiring layer is formed, and
the first through electrode penetrates the embedding layer, the dummy chip, and the semiconductor layer and is connected to the second wiring layer.

(22) The photodetection element according to any one of (15) to (17), in which:
the second chip includes
a semiconductor layer on which the second wiring layer is formed, and
a through via that penetrates the semiconductor layer and is connected to the second wiring layer; and
the first through electrode penetrates the embedding layer and the dummy chip, and is connected to the second wiring layer via the through via.

(23) The photodetection element according to any one of (15) to (17), further including a dummy chip embedded in the embedding layer and having a dummy wiring layer formed on a dummy substrate, in which
the first through electrode penetrates the embedding layer and the dummy substrate, and is connected to the second wiring layer via the dummy wiring layer.

(24) The photodetection element according to any one of (15) to (23), further including a support substrate that supports an embedding layer in which the third chip is embedded, in which
the first through electrode penetrates the support substrate.

(25) A photodetection element including:
a first chip in which a first wiring layer is formed on a first semiconductor substrate;
an embedding layer in which the first chip is embedded;
a through electrode that penetrates the embedding layer; and
an embedded member that is embedded in the first semiconductor substrate at a position insulated from the first wiring layer.

(26) The photodetection element according to (25), further including a second chip that forms a laminated structure with the first chip, and on which a second wiring layer extending onto the embedding layer is formed, in which
the embedding layer forms a laminated structure with the second chip so that the first chip is embedded in the embedding layer.

(27) The photodetection element according to (25) or (26), further including a support substrate that supports the embedding layer in which the first chip is embedded, in which
the through electrode penetrates the support substrate.

(28) The photodetection element according to any one of (25) to (27), in which
in the first semiconductor substrate, an area density of the embedded member in a region close to the through electrode is smaller than an area density of the embedded member in a region far from the through electrode.

(29) The photodetection element according to any one of (25) to (28), in which
an area density of the embedded member in a region up to 200 μm from an end of the first semiconductor substrate on the through electrode side is smaller than an area density of the embedded member in a region exceeding 200 μm from the end of the first semiconductor substrate.

(30) The photodetection element according to any one of (23) to (29), in which
any one of a heat dissipation film, a protective film, a warpage correction film, and a laminated film obtained by combining these films is formed on the back surface side of a first chip.

(31) A method of manufacturing a photodetection element, the method including:
a step of forming a laminated wafer in which a second wafer to be divided into second chips is laminated on a first wafer to be divided into first chips;
a step of laminating a third chip on the laminated wafer;
a step of forming an embedding layer laminated on the laminated wafer so that the third chip is embedded in the embedding layer;
a step of forming a through electrode electrically connected to the second chip via the embedding layer; and
a step of forming a photodetection element in which the laminated wafer is singulated together with the embedding layer in which the third chip is embedded.

(32) The method of manufacturing a photodetection element according to (31), further including a step of laminating a support substrate wafer on the embedding layer, in which
the through electrode penetrates the support substrate wafer, and
the laminated wafer and the support substrate wafer are singulated along the same cut surface together with the embedding layer in which the third chip is embedded.

(33) The method of manufacturing a photodetection element according to (31), in which:
the first chip includes a sensor chip having a wiring layer formed on a front surface side and a pixel formed on a back surface side;
the method further includes a step of laminating a transparent substrate wafer on the side of the pixel formation surface; and
the laminated wafer and the transparent substrate wafer are singulated along the same cut surface together with the embedding layer in which the third chip is embedded.

### REFERENCE SIGNS LIST

100 Photodetection element
101 to 104 Chip
111 to 114 Semiconductor layer
121 Pixel
131 Pixel transistor
115 Color filter
125 On-chip lens
135 Transparent resin
145 Transparent substrate
141 to 144 Wiring layer
151 to 154 Wiring
161 Barrier metal film
171 to 174, 176 Pad electrode
126, 136 Through via
181 to 184, 186 Via
146 Back surface wiring layer
156 Back surface wiring
116 Protective film
196 Insulating layer
117 Embedding layer
127 Through electrode
137 Bump electrode

What is claimed is:

1. A photodetection element comprising:
a first chip on which a first wiring layer is formed;
a second chip that is laminated on the first chip and on which a second wiring layer is formed;
a third chip that is arranged side by side with the second chip at an interval and laminated on the first chip, a third wiring layer being formed on the third chip;
an embedding layer that is laminated on the first chip so that the second chip and the third chip are embedded in the embedding layer; and
a through electrode that is located between the second chip and the third chip, penetrates the embedding layer, and is connected to the first wiring layer.

2. The photodetection element according to claim 1, wherein
the first wiring layer is directly bonded to the second wiring layer and the third wiring layer.

3. The photodetection element according to claim 1, further comprising a support substrate provided on the embedding layer, wherein
the through electrode penetrates the support substrate and the embedding layer and is connected to the first wiring layer.

4. The photodetection element according to claim 1, further comprising a sensor chip on which the first chip is laminated, and having a fourth wiring layer formed on a front surface side and a pixel formed on a back surface side.

5. The photodetection element according to claim 4, wherein:
the first wiring layer includes
a front surface wiring layer formed on a front surface side of the first chip, and
a back surface wiring layer formed on a back surface side of the first chip;
the front surface wiring layer is directly bonded to the fourth wiring layer;
the back surface wiring layer is directly bonded to the second wiring layer and the third wiring layer; and
the through electrode penetrates the embedding layer and is connected to the back surface wiring layer.

6. The photodetection element according to claim 5, further comprising a transparent substrate provided on the sensor chip.

7. The photodetection element according to claim 6, further comprising a cavity that separates an imaging region of the sensor chip from the transparent substrate.

8. A photodetection element comprising:
a first chip on which a first wiring layer is formed;
a second chip that is laminated on the first chip and on which a second wiring layer is formed;
an embedding layer that is laminated on the first chip so that the second chip is embedded in the embedding layer;
a redistribution layer that is formed on the embedding layer; and
a through electrode that penetrates the embedding layer and connects the redistribution layer and the first wiring layer.

9. A photodetection element comprising:
a first chip on which a first wiring layer is formed;
a second chip that is mounted face down on the first wiring layer and on which a second wiring layer is formed;
an embedding layer that is laminated on the first chip so that the second chip is embedded in the embedding layer; and
a first through electrode that penetrates the embedding layer and is connected to the second wiring layer via the first wiring layer.

10. The photodetection element according to claim 9, further comprising a second through electrode that penetrates the embedding layer and is connected to the first wiring layer without interposing the second wiring layer.

11. The photodetection element according to claim 9, wherein
the first wiring layer is directly bonded to the second wiring layer.

12. The photodetection element according to claim 9, further comprising a sensor chip on which the first chip is laminated, and having a third wiring layer formed on a front surface side and a pixel formed on a back surface side.

13. The photodetection element according to claim 12, wherein
the first wiring layer includes
a front surface wiring layer formed on a front surface side of the first chip, and
a back surface wiring layer formed on a back surface side of the first chip;
the front surface wiring layer is directly bonded to the third wiring layer;
the back surface wiring layer is directly bonded to the second wiring layer; and
the first through electrode penetrates the embedding layer and is connected to the second wiring layer via the back surface wiring layer.

14. The photodetection element according to claim 13, further comprising a fourth chip that is laminated between the sensor chip and the first chip and on which a fourth wiring layer is formed.

15. A photodetection element comprising:
a first chip on which a first wiring layer is formed;
a second chip that forms a laminated structure with the first chip and on which a second wiring layer is formed;
a third chip that forms a laminated structure with the first chip and the second chip and on which a third wiring layer is formed;
an embedding layer that forms a laminated structure with the first chip and the second chip so that the third chip is embedded in the embedding layer; and
a first through electrode that penetrates the embedding layer and is connected to the second wiring layer.

16. The photodetection element according to claim 15, wherein:
the first chip is located in a first layer, the second chip is located in a second layer, and the third chip is located in a third layer; and
the photodetection element further comprises a second through electrode that penetrates the embedding layer, is connected to the third wiring layer, and is shorter in length than the first through electrode.

17. The photodetection element according to claim 15, wherein:
the first chip is located in a first layer, the second chip is located in a third layer, and the third chip is located in a second layer;
the photodetection element further comprises a second through electrode that penetrates a semiconductor layer of the second chip, is connected to the second wiring layer, and is shorter in length than the first through electrode; and
the first through electrode penetrates the semiconductor layer of the second chip and the embedding layer and is connected to the second wiring layer.

18. The photodetection element according to claim 15, wherein
at least a part of the first through electrode includes a pillar electrode.

19. The photodetection element according to claim 15, wherein:
the second chip includes
a semiconductor layer on which the second wiring layer is formed, and
a through via that penetrates the semiconductor layer and is connected to the second wiring layer; and
the first through electrode penetrates the embedding layer and is connected to the second wiring layer via the through via.

20. The photodetection element according to claim 15, further comprising a dummy chip embedded in the embedding layer, wherein
the first through electrode penetrates the embedding layer and the dummy chip, and is connected to the second wiring layer.

21. The photodetection element according to claim 15, wherein
the second chip includes a semiconductor layer on which the second wiring layer is formed, and
the first through electrode penetrates the embedding layer, the dummy chip, and the semiconductor layer and is connected to the second wiring layer.

22. The photodetection element according to claim 15, wherein:
the second chip includes
a semiconductor layer on which the second wiring layer is formed, and
a through via that penetrates the semiconductor layer and is connected to the second wiring layer; and
the first through electrode penetrates the embedding layer and the dummy chip, and is connected to the second wiring layer via the through via.

23. The photodetection element according to claim 15, further comprising a dummy chip embedded in the embedding layer and having a dummy wiring layer formed on a dummy substrate, wherein
the first through electrode penetrates the embedding layer and the dummy substrate, and is connected to the second wiring layer via the dummy wiring layer.

24. The photodetection element according to claim 15, further comprising a support substrate that supports an embedding layer in which the third chip is embedded, wherein
the first through electrode penetrates the support substrate.

25. A photodetection element comprising:
a first chip in which a first wiring layer is formed on a first semiconductor substrate;
an embedding layer in which the first chip is embedded;
a through electrode that penetrates the embedding layer; and
an embedded member that is embedded in the first semiconductor substrate at a position insulated from the first wiring layer.

26. The photodetection element according to claim 23, further comprising a second chip that forms a laminated structure with the first chip, and on which a second wiring layer extending onto the embedding layer is formed, wherein
the embedding layer forms a laminated structure with the second chip so that the first chip is embedded in the embedding layer.

27. The photodetection element according to claim 23, further comprising a support substrate that supports the embedding layer in which the first chip is embedded, wherein
the through electrode penetrates the support substrate.

28. The photodetection element according to claim 23, wherein
in the first semiconductor substrate, an area density of the embedded member in a region close to the through electrode is smaller than an area density of the embedded member in a region far from the through electrode.

29. The photodetection element according to claim 23, wherein
an area density of the embedded member in a region up to 200 μm from an end of the first semiconductor substrate on the through electrode side is smaller than an area density of the embedded member in a region exceeding 200 μm from the end of the first semiconductor substrate.

30. The photodetection element according to claim 23, wherein
any one of a heat dissipation film, a protective film, a warpage correction film, and a laminated film obtained by combining these films is formed on a back surface side of a first chip.

31. A method of manufacturing a photodetection element, the method comprising:
a step of forming a laminated wafer in which a second wafer to be divided into second chips is laminated on a first wafer to be divided into first chips;
a step of laminating a third chip on the laminated wafer;
a step of forming an embedding layer laminated on the laminated wafer so that the third chip is embedded in the embedding layer;
a step of forming a through electrode electrically connected to the second chip via the embedding layer; and
a step of forming a photodetection element in which the laminated wafer is singulated together with the embedding layer in which the third chip is embedded.

32. The method of manufacturing a photodetection element according to claim 31, further comprising a step of laminating a support substrate wafer on the embedding layer, wherein
the through electrode penetrates the support substrate wafer, and
the laminated wafer and the support substrate wafer are singulated along a same cut surface together with the embedding layer in which the third chip is embedded.

33. The method of manufacturing a photodetection element according to claim 31, wherein:
the first chip includes a sensor chip having a wiring layer formed on a front surface side and a pixel formed on a back surface side;
the method further comprises a step of laminating a transparent substrate wafer on the side of the pixel formation surface; and
the laminated wafer and the transparent substrate wafer are singulated along a same cut surface together with the embedding layer in which the third chip is embedded.
